(19) United States
(12) Patent Application Publication
(10) Pub. No.: US 2026/0343976 A1
(43) Pub. Date: Oct. 29, 2026

(54) SEMICONDUCTOR DEVICE

(71) Applicant: ROHM CO., LTD., Kyoto-shi (JP)

(72) Inventors: Rogosu WAGURI, Kyoto-shi (JP); Seigo MORI, Kyoto-shi (JP)

(73) Assignee: ROHM CO., LTD., Kyoto-shi (JP)

(21) Appl. No.: 19/716,359

(22) Filed: Jun. 23, 2026

Related U.S. Application Data
(63) Continuation of application No. PCT/JP2024/046436, filed on Dec. 27, 2024.

(30) Foreign Application Priority Data
Dec. 27, 2023 (JP) 2023-221773

(51) Int. Cl. H10D 62/60; H10D 30/66; H10D 62/10; H10D 62/832; H10D 84/00

(52) U.S. Cl. CPC H10D 62/60; H10D 30/668; H10D 62/126; H10D 62/8325; H10D 30/665; H10D 62/107; H10D 84/143; H10D 84/146

(57) ABSTRACT

A semiconductor device includes a semiconductor layer of a first conductivity type including an SiC monocrystal and having a main surface, a gate structure of a trench type formed in the main surface, and a well region of a second conductivity type formed in a region below the gate structure in the semiconductor layer and extending along an axis channel of the SiC monocrystal.

### CROSS-REFERENCE TO RELATED APPLICATIONS

The present application is a bypass continuation of International Patent Application No. PCT/JP2024/046436 filed on Dec. 27, 2024, which claims priority to Japanese Patent Application No. 2023-221773 filed on Dec. 27, 2023 in the Japan Patent Office, and the entire contents of these applications are hereby incorporated herein by reference.

### BACKGROUND

### 1. Field of the Disclosure

The present disclosure relates to a semiconductor device.

### 2. Description of the Related Art

US2003/0227051A1 discloses a semiconductor device including an active groove formed in a semiconductor layer of an n-type. An embedded region of a p-type is arranged on a bottom portion side of the active groove, and a gate electrode is arranged on an opening side of the active groove via a gate insulating film.

### BRIEF DESCRIPTION OF THE DRAWINGS

FIG. 1 is a plan view illustrating a semiconductor device according to a first embodiment.

FIG. 2 is a sectional view taken along line II-II illustrated in FIG. 1.

FIG. 3 is a plan view illustrating a layout example of a first main surface.

FIG. 4 is an enlarged plan view illustrating one main portion of an active region.

FIG. 5 is an enlarged plan view illustrating another main portion of the active region.

FIG. 6 is a sectional view taken along line VI-VI illustrated in FIG. 4.

FIG. 7 is a sectional view taken along line VII-VII illustrated in FIG. 4.

FIG. 8 is a sectional view taken along line VIII-VIII illustrated in FIG. 5.

FIG. 9 is an enlarged sectional view illustrating one main portion of the active region.

FIG. 10 is a sectional perspective view illustrating one main portion of the active region.

FIG. 11 is a sectional perspective view illustrating one main portion of the active region.

FIG. 12 is a graph illustrating an impurity concentration of a well region.

FIG. 13 is a graph illustrating an impurity concentration of a high concentration region.

FIG. 14 is a graph illustrating an impurity concentration of a body region.

FIG. 15 is a sectional perspective view for describing an operation in a case where a drain-source voltage is applied in an off state of a gate structure.

FIG. 16 is a sectional perspective view illustrating a first modification example of the semiconductor device.

FIG. 17 is a sectional perspective view illustrating a second modification example of the semiconductor device.

FIG. 18 is a sectional perspective view illustrating a third modification example of the semiconductor device.

FIG. 19 is a sectional perspective view illustrating a fourth modification example of the semiconductor device.

FIG. 20 is a sectional perspective view illustrating a fifth modification example of the semiconductor device.

FIG. 21 is a sectional perspective view illustrating a sixth modification example of the semiconductor device.

FIG. 22 is a sectional perspective view illustrating a seventh modification example of the semiconductor device.

FIG. 23 is a sectional perspective view illustrating an eighth modification example of the semiconductor device.

FIG. 24 is a sectional perspective view illustrating a ninth modification example of the semiconductor device.

FIG. 25 is a sectional perspective view illustrating a tenth modification example of the semiconductor device.

FIG. 26 is a sectional perspective view illustrating an eleventh modification example of the semiconductor device.

FIG. 27 is a sectional perspective view illustrating a twelfth modification example of the semiconductor device.

FIG. 28 is a sectional perspective view illustrating a thirteenth modification example of the semiconductor device.

FIG. 29 is a sectional perspective view illustrating a fourteenth modification example of the semiconductor device.

FIG. 30 is a sectional perspective view illustrating a fifteenth modification example of the semiconductor device.

FIG. 31 is a sectional perspective view illustrating a sixteenth modification example of the semiconductor device.

FIG. 32 is a sectional perspective view illustrating a semiconductor device according to a second embodiment.

FIG. 33 is a graph illustrating an impurity concentration of the well region.

FIG. 34 is a graph illustrating the impurity concentration of the high concentration region.

FIG. 35 is a plan view illustrating a semiconductor device according to a third embodiment.

FIG. 36 is an enlarged plan view illustrating one main portion of the active region illustrated in FIG. 35.

FIG. 37 is a sectional view taken along line XXXVII-XXXVII illustrated in FIG. 36.

FIG. 38 is a plan view illustrating a semiconductor device according to a fourth embodiment.

FIG. 39 is a sectional view taken along line XXXIX-XXXIX illustrated in FIG. 38.

FIG. 40 is an enlarged sectional view illustrating one main portion of the active region illustrated in FIG. 39.

### DETAILED DESCRIPTION OF THE PREFERRED EMBODIMENTS

Hereinafter, specific embodiments shall be described in detail with reference to attached drawings. The attached drawings are all schematic views and are not strictly illustrated, and relative positional relationships, scales, proportions, angles and the like thereof do not always match. Identical reference signs are given to corresponding structures among the attached drawings, and duplicate descriptions thereof shall be omitted or simplified. For the structures whose description have been omitted or simplified, the description given before the omission or simplification shall apply.

In this description, open languages such as “including” and “having” are described as concepts that encompass closed languages such as “consisting of.” When the wording “substantially equal” is used in this description, the wording includes a numerical value (shape) equal to a numerical value (shape) of a comparison target and also includes numerical errors (shape errors) in a range of ±10% on a basis of the numerical value (shape) of the comparison target.

Although the wordings “first,” “second,” “third,” etc., are used in this description, these are symbols attached to names of respective structures in order to clarify the order of description and are not attached with an intention of restricting the names of the respective structures.

In this description, a conductivity type of a semiconductor (an impurity) is indicated using “p-type” or “n-type” and the “p-type” may be referred to as a “first conductivity type” and the “n-type” may be referred to as a “second conductivity type.” The “n-type” may be referred to as the “first conductivity type” and the “p-type” may be referred to as the “second conductivity type” instead.

The “p-type” is a conductivity type due to a trivalent element and the “n-type” is a conductivity type due to a pentavalent element. The trivalent element is at least one type among boron, aluminum, gallium, and indium. The pentavalent element is at least one type among nitrogen, phosphorus, arsenic, antimony, and bismuth.

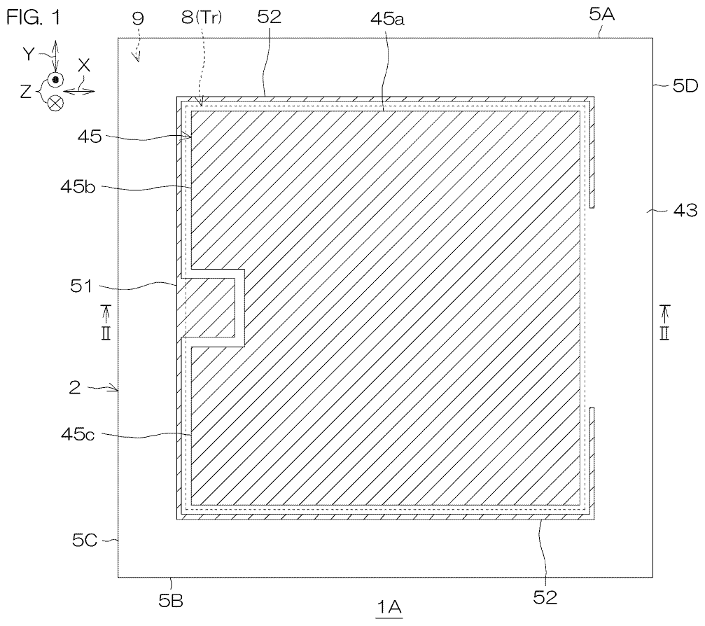

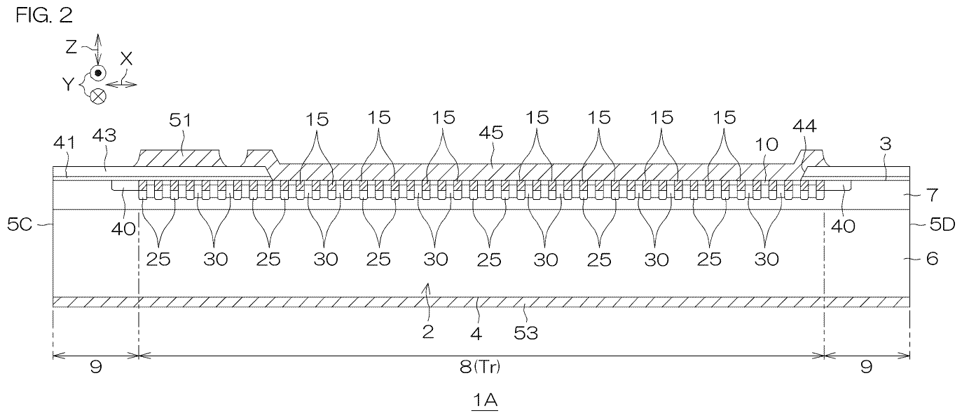

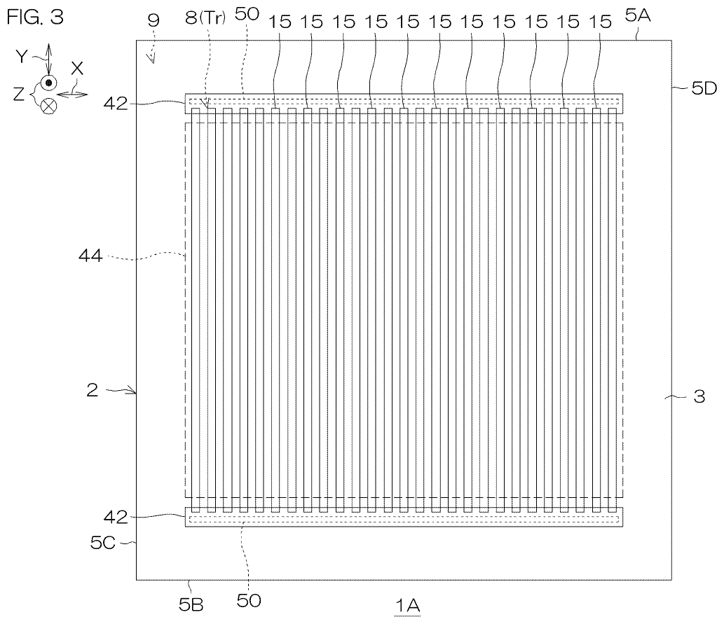

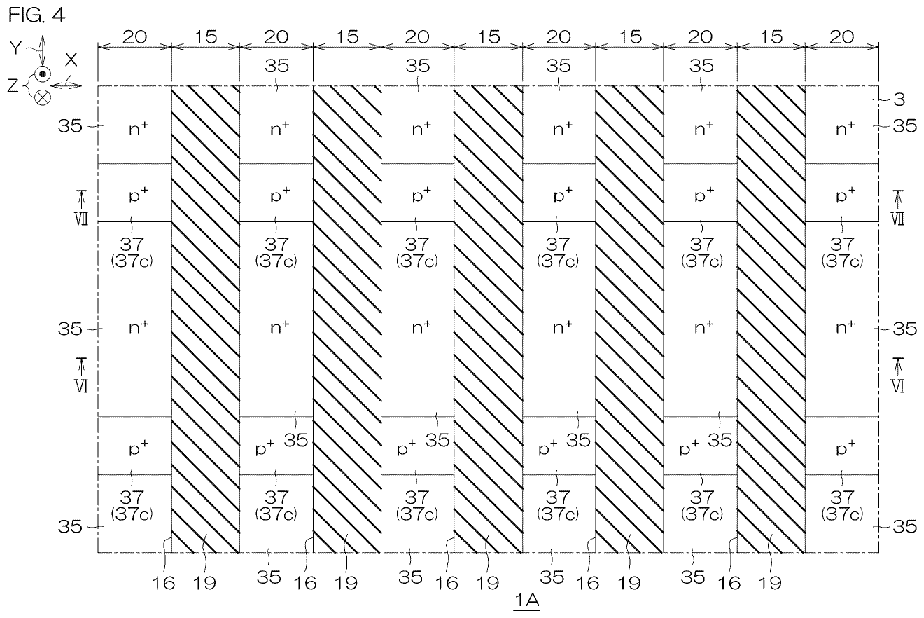

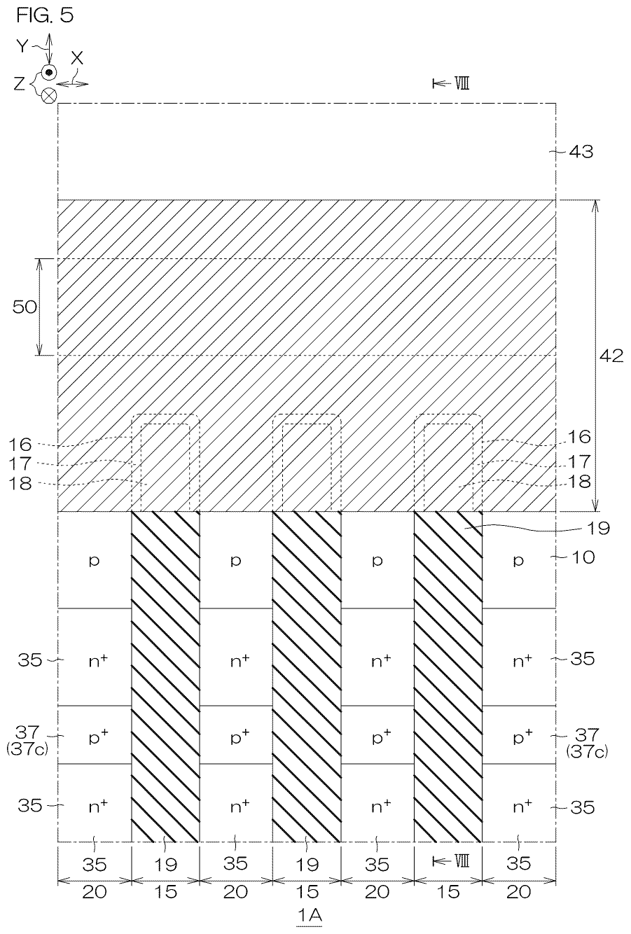

FIG. 1 is a plan view illustrating a semiconductor device 1A according to a first embodiment. FIG. 2 is a sectional view taken along line II-II illustrated in FIG. 1. FIG. 3 is a plan view illustrating a layout example of a first main surface 3. FIG. 4 is an enlarged plan view illustrating one main portion of an active region 8. FIG. 5 is an enlarged plan view illustrating another main portion of the active region 8.

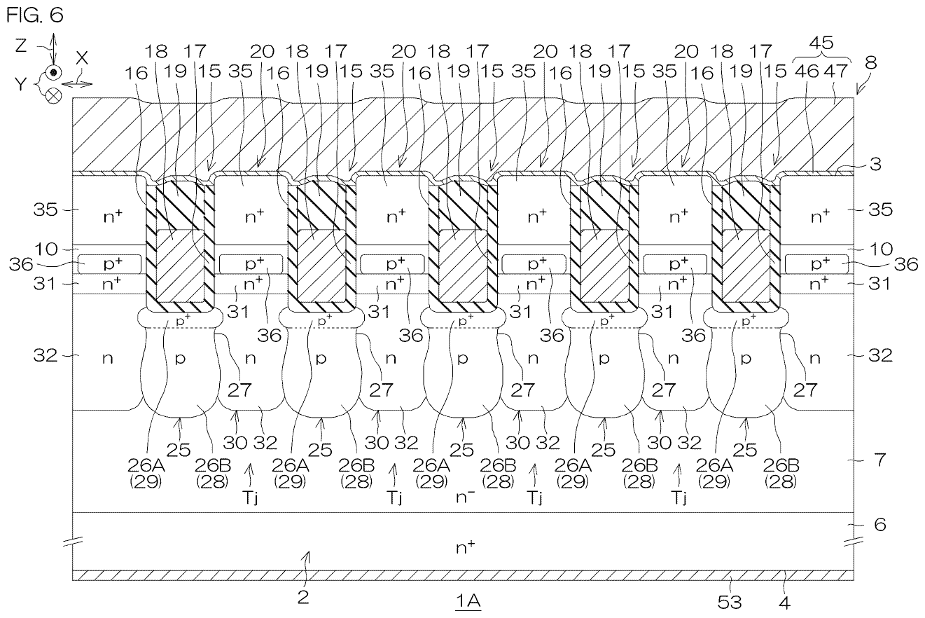

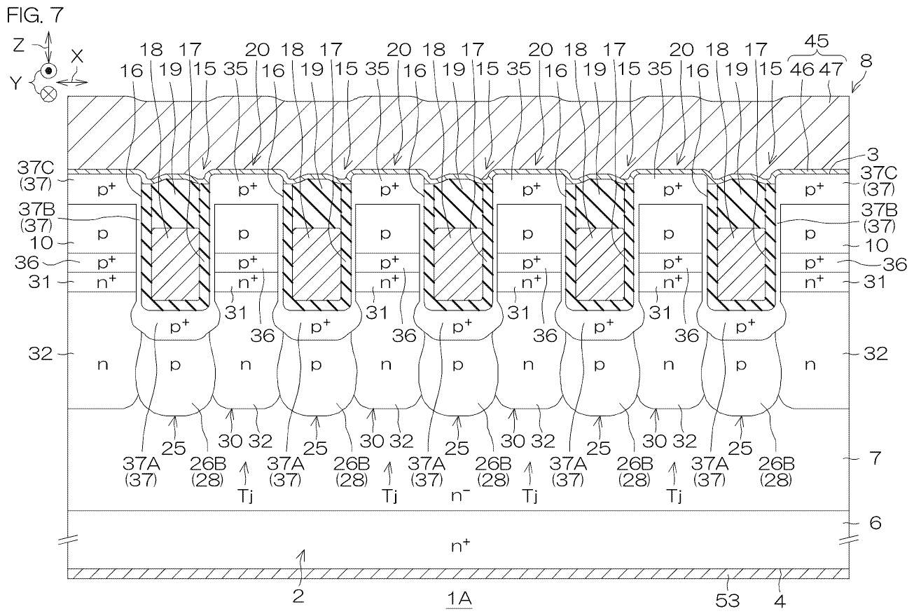

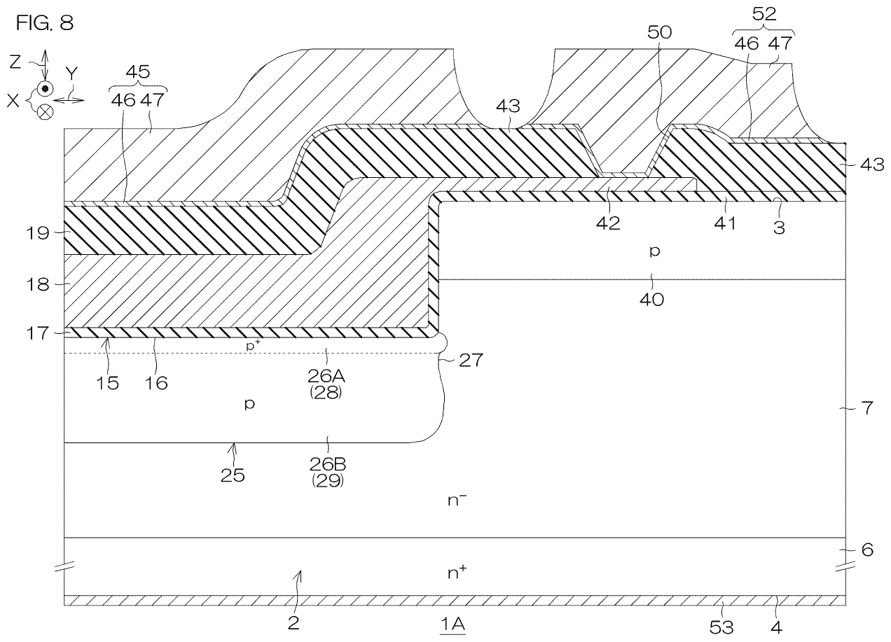

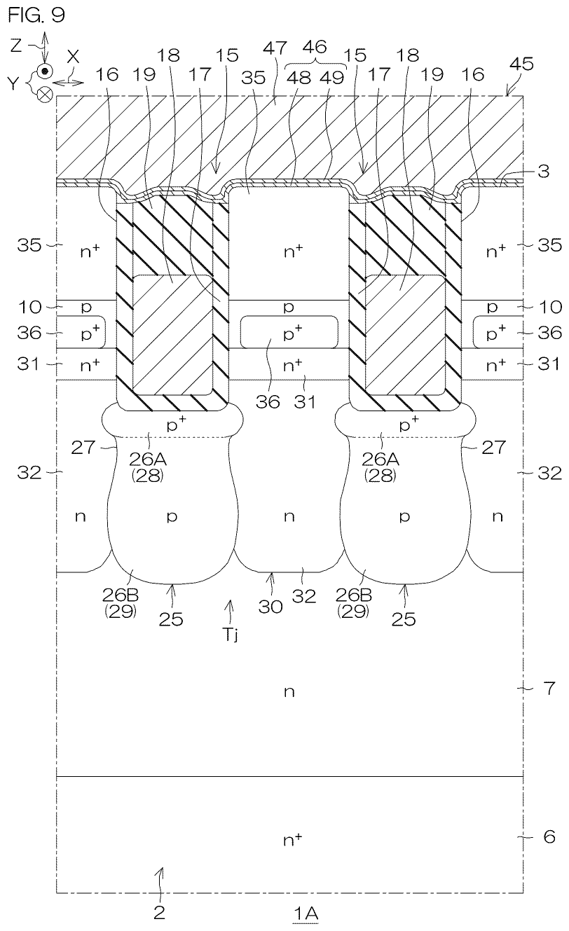

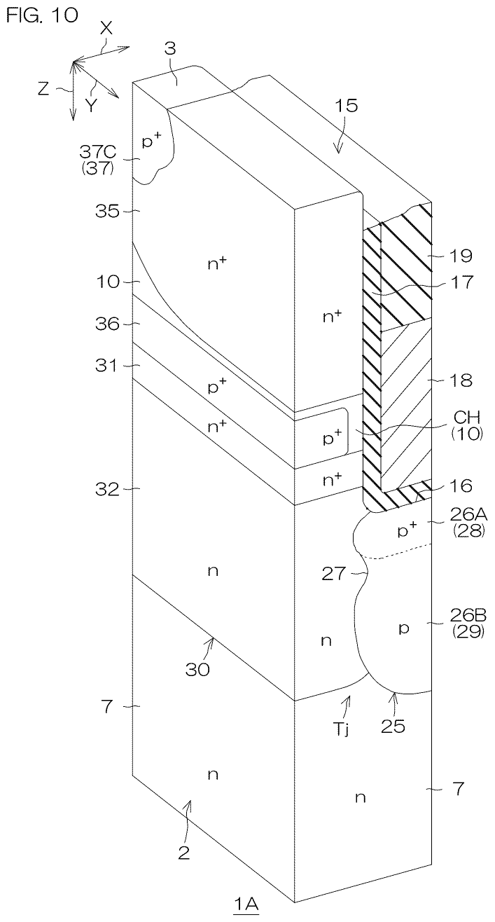

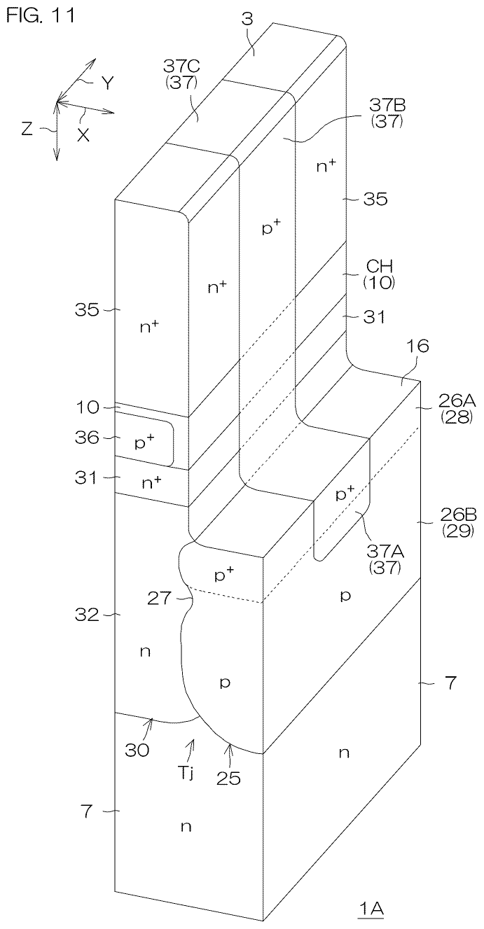

FIG. 6 is a sectional view taken along line VI-VI illustrated in FIG. 4. FIG. 7 is a sectional view taken along line VII-VII illustrated in FIG. 4. FIG. 8 is a sectional view taken along line VIII-VIII illustrated in FIG. 5. FIG. 9 is an enlarged sectional view illustrating one main portion of the active region 8. FIG. 10 is a sectional perspective view illustrating one main portion of the active region 8. FIG. 11 is a sectional perspective view illustrating one main portion of the active region 8.

With reference to FIGS. 1 to 11, the semiconductor device 1A is a semiconductor switching device that has a transistor structure Tr of an insulated gate type as an example of a device structure. The transistor structure Tr has a trench gate type vertical structure.

The semiconductor device 1A includes a chip 2 formed in a hexahedron shape (specifically, a rectangular parallelepiped shape). In this embodiment, the chip 2 includes a monocrystal of a wide bandgap semiconductor. That is, the semiconductor device 1A is a “wide bandgap semiconductor device.” The chip 2 may be referred to as a “semiconductor chip” or a “wide bandgap semiconductor chip,” etc.

The wide bandgap semiconductor is a semiconductor that has a bandgap exceeding a bandgap of Si (silicon). GaN (gallium nitride), SiC (silicon carbide), C (diamond), etc., can be given as examples of the wide bandgap semiconductor. In this embodiment, the chip 2 is an “SiC chip” that includes, as an example of the wide bandgap semiconductor, an SiC monocrystal that is a hexagonal crystal. That is, the semiconductor device 1A is an “SiC semiconductor device.”

The SiC monocrystal that is a hexagonal crystal has multiple polytypes including a 2H (hexagonal)-SiC monocrystal, a 4H-SiC monocrystal, a 6H-SiC monocrystal, etc. In this embodiment, an example in which the chip 2 includes the 4H-SiC monocrystal is given, but the chip 2 may include another polytype.

The chip 2 has the first main surface 3 on one side, a second main surface 4 on the other side, and first to fourth side surfaces 5A to 5D connected to the first main surface 3 and the second main surface 4. In plan view as viewed from a vertical direction Z (hereinafter referred to simply as “plan view”), the first main surface 3 and the second main surface 4 are formed in quadrangular shapes. The vertical direction Z is also a thickness direction of the chip 2.

The first main surface 3 and the second main surface 4 are preferably formed by c-planes of the SiC monocrystal. In this case, preferably, the first main surface 3 is formed by a silicon plane (a (0001) plane) of the SiC monocrystal and the second main surface 4 is formed by a carbon plane (a (000-1) plane) of the SiC monocrystal.

The first side surface 5A and the second side surface 5B extend in a first direction X along the first main surface 3 and are opposed to each other in a second direction Y that intersects the first direction X along the first main surface 3. Specifically, the second direction Y is orthogonal to the first direction X. The third side surface 5C and the fourth side surface 5D extend in the second direction Y and are opposed to each other in the first direction X.

In this embodiment, the first direction X is an m-axis direction (a [1-100] direction) of the SiC monocrystal and the second direction Y is an a-axis direction (a [11-20] direction) of the SiC monocrystal. The first direction X may instead be the a-axis direction of the SiC monocrystal and the second direction Y may instead be the m-axis direction of the SiC monocrystal. In the following, directions extending along the first main surface 3 are expressed at times as “horizontal directions.” The horizontal directions are also an XY plane (horizontal plane) formed by the first direction X and the second direction Y and are orthogonal to the vertical direction Z.

The chip 2 (the first main surface 3 and the second main surface 4) has the off angle inclined at the predetermined angle in the predetermined off direction with respect to the c-plane of the SiC monocrystal. That is, a c-axis (a (0001) axis) of the SiC monocrystal is inclined by just the off angle toward the off direction from a vertical line along the vertical direction Z. Also, the c-plane of the SiC monocrystal is inclined by just the off angle with respect to the horizontal plane.

The off direction is preferably the a-axis direction (the second direction Y in this embodiment) of the SiC monocrystal. The off angle may exceed 0° and be not more than 10°. The off angle may have a value belonging to at least one range among exceeding 0° and being not more than 1°, not less than 1° and not more than 2.5°, not less than 2.5° and not more than 5°, not less than 5° and not more than 7.5°, and not less than 7.5° and not more than 10°.

The off angle is preferably not more than 5°. The off angle is particularly preferably not less than 2° and not more than 4.5°. The off angle is typically set in a range of 4°±0.1°. This description does not exclude an embodiment in which the off angle is 0° (that is, an embodiment in which the first main surface 3 is a just surface with respect to the c-plane).

The semiconductor device 1A includes a first semiconductor layer 6 of an n-type formed in a surface layer portion of the second main surface 4. A drain potential is to be applied as a first potential (high potential) to the first semiconductor layer 6. The first semiconductor layer 6 may be referred to as a “semiconductor region (layer),” a “base region (layer),” a “drain region (layer),” etc.

The first semiconductor layer 6 extends in a layer shape along the second main surface 4 and is exposed from the second main surface 4 and the first to fourth side surfaces 5A to 5D. In this embodiment, the first semiconductor layer 6 consisting of a semiconductor layer of the n-type. Specifically, the first semiconductor layer 6 is consisting of a substrate (an SiC substrate) that includes an SiC monocrystal (a semiconductor monocrystal) and forms the second main surface 4 and the first to fourth side surfaces 5A to 5D. The first semiconductor layer 6 (substrate) has the off direction and the off angle described above.

The first semiconductor layer 6 is adjusted in concentration by a base element (base impurity) consisting of a pentavalent element. The base element may include at least one among nitrogen, phosphorus, and arsenic. The first semiconductor layer 6 is preferably adjusted in concentration by a single base element. The base element may be nitrogen. The first semiconductor layer 6 has a substantially uniform n-type impurity concentration (substantially fixed n-type impurity concentration) in a thickness direction.

The first semiconductor layer 6 may have a thickness of not less than 10 μm and not more than 500 μm. The thickness of the first semiconductor layer 6 may have a value belonging to at least one range among not less than 10 μm and not more than 50 μm, not less than 50 μm and not more than 100 μm, not less than 100 μm and not more than 150 μm, not less than 150 μm and not more than 200 μm, not less than 200 μm and not more than 300 μm, not less than 300 μm and not more than 400 μm, and not less than 400 μm and not more than 500 μm.

The semiconductor device 1A includes a second semiconductor layer 7 of the n-type formed in a surface layer portion of the first main surface 3. The second semiconductor layer 7 may be referred to as a “semiconductor region (layer),” a “drift region (layer),” etc. The second semiconductor layer 7 has an n-type impurity concentration lower than the n-type impurity concentration of the first semiconductor layer 6.

The second semiconductor layer 7 is adjusted in concentration by a first element (first impurity) consisting of a pentavalent element. The first element may include at least one among nitrogen, phosphorus, and arsenic. The second semiconductor layer 7 is preferably adjusted in concentration by a single first element. The first element may be nitrogen. The second semiconductor layer 7 has a substantially uniform n-type impurity concentration (substantially fixed n-type impurity concentration) in the thickness direction.

The second semiconductor layer 7 is formed in a region on the first main surface 3 side with respect to the first semiconductor layer 6 in sectional view, and is electrically connected to the first semiconductor layer 6. The second semiconductor layer 7 extends in a layer shape along the first main surface 3 and is exposed from the first main surface 3 and the first to fourth side surfaces 5A to 5D. In this embodiment, the second semiconductor layer 7 is consisting of a semiconductor layer of the n-type.

Specifically, the second semiconductor layer 7 is consisting of an epitaxial layer (SiC epitaxial layer) including the SiC monocrystal (semiconductor monocrystal), and has the first main surface 3 and the first to fourth side surfaces 5A to 5D. The second semiconductor layer 7 (epitaxial layer) has the off direction and the off angle described above. The second semiconductor layer 7 preferably has a thickness less than a thickness of the first semiconductor layer 6. The thickness of the second semiconductor layer 7 may be greater than the thickness of the first semiconductor layer 6.

The thickness of the second semiconductor layer 7 may be not less than 5 μm and not more than 25 μm. The thickness of the second semiconductor layer 7 may have a value belonging to at least one range among not less than 5 μm and not more than 7. 5 μm, not less than 7.5 μm and not more than 10 μm, not less than 10μm and not more than 12.5 μm, not less than 12.5 μm and not more than 15 μm, not less than 15 μm and not more than 17.5 μm, not less than 17.5 μm and not more than 20 μm, not less than 20 μm and not more than 22.5 μm, and not less than 22.5 μm and not more than 25 μm.

The semiconductor device 1A includes the active region 8 set in the chip 2. The active region 8 includes the device structure (the transistor structure Tr) and is a region in which an output current (drain current) is generated. The active region 8 is set in an inner portion of the chip 2 at an interval from a peripheral edge (the first to fourth side surfaces 5A to 5D) of the first main surface 3.

The active region 8 is set in a polygonal shape (a quadrangular shape in this embodiment) having four sides parallel to a peripheral edge of the chip 2 in plan view. A ratio (an area ratio) of a planar area of the active region 8 to a planar area of the first main surface 3 may be not less than 0.5 and not more than 0.95. The area ratio may have a value belonging to at least one range among not less than 0.5 and not more than 0.6, not less than 0.6 and not more than 0.7, not less than 0.7 and not more than 0.8, not less than 0.8 and not more than 0.9, and not less than 0.9 and not more than 0.95.

The semiconductor device 1A includes an outer peripheral region 9 that, in the chip 2, is set outside the active region 8. The outer peripheral region 9 is a region not including the device structure (the transistor structure Tr). The outer peripheral region 9 is set in a peripheral edge portion of the chip 2. That is, the outer peripheral region 9 is provided in a region between the peripheral edge of the chip 2 and the active region 8 in plan view. The outer peripheral region 9 extends as a band along the active region 8 and is set to a polygonal annular shape (a quadrilateral annular shape in this embodiment) that surrounds the active region 8 in plan view.

The semiconductor device 1A includes the transistor structure Tr formed in the active region 8. Hereinafter, a configuration in the active region 8 as a configuration of the transistor structure Tr shall be described.

The semiconductor device 1A includes a body region 10 of a p-type formed in the surface layer portion of the first main surface 3 in the active region 8 (an inner portion of the first main surface 3). The body region 10 may be referred to as a “channel region,” etc. A source potential may be applied to the body region 10. The source potential may be a reference potential serving as a reference of circuit operation. The reference potential may be a ground potential.

The body region 10 has a p-type impurity concentration higher than the n-type impurity concentration of the second semiconductor layer 7. The p-type impurity (trivalent element) of the body region 10 may be either or both of boron and aluminum.

The body region 10 is formed in the inner portion of the first main surface 3 at an interval from the peripheral edge (the first to fourth side surfaces 5A to 5D) of the first main surface 3, and is not formed in the outer peripheral region 9. In this embodiment, the body region 10 is formed in an entire region of the active region 8. The body region 10 is formed in a surface layer portion of the second semiconductor layer 7, and extends in a layer shape along the first main surface 3.

The body region 10 is formed at an interval toward the first main surface 3 side from a bottom portion of the second semiconductor layer 7 (the first semiconductor layer 6), and opposes the first semiconductor layer 6 with a portion of the second semiconductor layer 7 interposed therebetween. The body region 10 is formed at an interval toward the first main surface 3 side from a depth position of an intermediate portion of the second semiconductor layer 7.

The body region 10 is formed in a region on the first main surface 3 side with respect to the second semiconductor layer 7 in sectional view, and is electrically connected to the second semiconductor layer 7. The body region 10 forms a pn-junction portion (body diode) with the second semiconductor layer 7. The body region 10 spreads a depletion layer in the second semiconductor layer 7 when a reverse bias voltage is applied. The depletion layer with the body region 10 as a starting point spreads in the horizontal direction and the thickness direction within the second semiconductor layer 7.

The semiconductor device 1A includes a plurality of gate structures 15 of a trench type (a trench electrode type) that are formed in the inner portion of the active region 8 (the inner portion of the first main surface 3). The gate structure 15 may be referred to as a “trench structure,” a “trench gate structure,” etc. A gate potential (gate signal) as a control potential is to be applied to the plurality of gate structures 15. The plurality of gate structures 15 control the inversion and non-inversion of a channel CH in the body region 10 in response to the gate potential (refer to FIG. 10).

The plurality of gate structures 15 are formed in the active region 8 at an interval from the peripheral edge (the first to fourth side surfaces 5A to 5D) of the first main surface 3, and are not formed in the outer peripheral region 9. The plurality of gate structures 15 are aligned at intervals in the first direction X (=m-axis direction) in plan view, and each extend in a band shape in the second direction Y (=a-axis direction). The plurality of gate structures 15 are aligned in a stripe shape extending in the second direction Y in plan view.

An extension direction of the plurality of gate structures 15 coincides with the off direction of the SiC monocrystal. In the second direction Y, both end portions of the plurality of gate structures 15 are positioned further inward than a peripheral edge of the body region 10. The both end portions of the plurality of gate structures 15 may be positioned further outward than the peripheral edge of the body region 10. The plurality of gate structures 15 may be aligned at intervals in the second direction Y in plan view, and each may extend in a band shape in the first direction X.

The plurality of gate structures 15 penetrate through the body region 10 so as to reach the second semiconductor layer 7. The plurality of gate structures 15 are formed at an interval toward the first main surface 3 side from a depth position of the bottom portion of the second semiconductor layer 7, and oppose the first semiconductor layer 6 with a portion of the second semiconductor layer 7 interposed therebetween.

The plurality of gate structures 15 may be formed at an interval toward the first main surface 3 side from the depth position of the intermediate portion of the second semiconductor layer 7, or may be positioned on the bottom portion side of the second semiconductor layer 7 (the second main surface 4 side) with respect to the depth position of the intermediate portion of the second semiconductor layer 7. The plurality of gate structures 15 are formed substantially perpendicular to the first main surface 3. The plurality of gate structures 15 may be formed in a shape tapering toward the bottom portion of the second semiconductor layer 7.

Side walls (long sides) of the plurality of gate structures 15 are formed by an m-plane ((1-100) plane) of SiC monocrystal. The side walls (long sides) of the plurality of gate structures 15 may be formed by the a-plane ((11-20) plane) of the SiC monocrystal in accordance with the extension direction of the gate structure 15. The side walls of the plurality of gate structures 15 demarcate opening ends curved in an arc shape (arcuate shape) together with the first main surface 3.

Bottom walls of the plurality of gate structures 15 are formed by a c-plane (Si plane) of SiC monocrystal. The bottom walls of the plurality of gate structures 15 preferably extend substantially flat along the horizontal direction. The bottom walls of the plurality of gate structures 15 may be curved in an arcuate shape toward the second main surface 4.

An inclination angle (absolute value) of the side wall (long side) of the gate structures 15 on a basis of a vertical line may be not less than 85° and not more than 95°. The inclination angle may have a value belonging to at least one range among not less than 85° and not more than 87.5°, not less than 87.5° and not more than 90°, not less than 90° and not more than 92.5°, and not less than 92.5° and not more than 95°. The inclination angle is preferably not less than 87° and not more than 93°.

The gate structure 15 may have a width of not less than 0.1 μm and not more than 2 μm. The width of the gate structure 15 may have a value belonging to at least one range among not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, and not less than 1.75 μm and not more than 2 μm. The width of the gate structure 15 is preferably not more than 1 μm.

The gate structure 15 may have a depth of not less than 0.1 μm and not more than 3 μm. The depth of the gate structure 15 is a depth on a basis of the first main surface 3. The depth of the gate structure 15 may have a value belonging to at least one range among not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, and not less than 2.5 μm and not more than 3 μm. The depth of the gate structure 15 is preferably not less than 0.5 μm and not more than 1.5 μm.

The gate structure 15 may have an aspect ratio of not less than 1 and not more than 3. The aspect ratio of the gate structure 15 is the ratio of the depth of the gate structure 15 to the width of the gate structure 15. The aspect ratio may have a value belonging to at least one range among not less than 1 and not more than 1.25, not less than 1.25 and not more than 1.5, not less than 1.5 and not more than 1.75, not less than 1.75 and not more than 2, not less than 2 and not more than 2.25, not less than 2.25 and not more than 2.5, not less than 2.5 and not more than 2.75, and not less than 2.75 and not more than 3. The aspect ratio is preferably not less than 1.5 and not more than 2.5.

The plurality of gate structures 15 may be aligned at a pitch of not less than 0.1 μm and not more than 2 μm. The pitch is a distance in the horizontal direction (the first direction X) between the plurality of gate structures 15. The pitch may have a value belonging to at least one range among not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, and not less than 1.75 μm and not more than 2 μm. The pitch is preferably not more than 1 μm.

The plurality of gate structures 15 include a trench 16, an insulating film 17, an embedded electrode 18, and an embedded insulator 19, respectively. The trench 16 may be referred to as a “gate trench,” the insulating film 17 may be referred to as a “gate insulating film,” the embedded electrode 18 may be referred to as a “gate electrode,” and the embedded insulator 19 may be referred to as a “cap insulator (film).” The trench 16 is formed in the first main surface 3 and demarcates the wall surface (the side wall and the bottom wall) of the gate structure 15.

The insulating film 17 may include at least one among a silicon oxide film, a silicon nitride film, and a silicon oxynitride film. In this embodiment, the insulating film 17 has a single layer structure consisting of the silicon oxide film. The insulating film 17 particularly preferably includes a silicon oxide film consisting of an oxide of the chip 2.

The insulating film 17 covers a wall surface of the trench 16. In this embodiment, the insulating film 17 has an upper end portion positioned on a bottom wall side of the trench 16 with respect to a height position of the first main surface 3, and exposes a portion of the chip 2 from a wall surface of an opening end of the trench 16. The upper end portion of the insulating film 17 is preferably positioned on the opening side of the trench 16 with respect to a depth position of an intermediate portion of the trench 16.

The insulating film 17 includes a first film portion and a second film portion. The first film portion covers side walls of the trench 16 in a film shape. The second film portion covers the bottom wall of the trench 16 in a film shape and is continuous to the first film portion. The second film portion has a thickness greater than the thickness of the first film portion. The thickness of the second film portion may instead be substantially equal to the thickness of the first film portion.

The insulating film 17 may have a thickness of not less than 10 nm and not more than 150 nm. The thickness of the insulating film 17 may have a value belonging to at least one range among not less than 10 nm and not more than 25 nm, not less than 25 nm and not more than 50 nm, not less than 50 nm and not more than 75 nm, not less than 75 nm and not more than 100 nm, not less than 100 nm and not more than 125 nm, and not less than 125 nm and not more than 150 nm.

The embedded electrode 18 may contain either or both of a conductive polysilicon of the p-type and a conductive polysilicon of the n-type. The embedded electrode 18 preferably is consisting of conductive polysilicon of the n-type. The embedded electrode 18 is embedded in the trench 16 with the insulating film 17 interposed therebetween. The embedded electrode 18 opposes the second semiconductor layer 7 and the body region 10 with the insulating film 17 interposed therebetween.

The embedded electrode 18 has an electrode surface exposed from the trench 16. The electrode surface is positioned on the bottom wall side of the trench 16 at an interval from the height position of the first main surface 3. The electrode surface is positioned on the first main surface 3 side with respect to the depth position of the intermediate portion of the trench 16. The electrode surface may be positioned on the bottom wall side of the trench 16 with respect to the depth position of the intermediate portion of the trench 16.

The electrode surface is positioned further to the bottom wall side of the trench 16 than the upper end portion of the insulating film 17, and exposes a portion (the first film portion) of the insulating film 17 covering a side wall on the opening side of the trench 16. The electrode surface may be positioned further to the first main surface 3 side than the upper end portion of the insulating film 17. The electrode surface demarcates, in the trench 16, a recess space with the side walls (the first film portion of the insulating film 17) of the trench 16.

The embedded insulator 19 may include at least one among a silicon oxide film, a silicon nitride film, and a silicon oxynitride film. The embedded insulator 19 may include an insulating material different from the insulating material of the insulating film 17 or may include the same type of insulating material as that of the insulating film 17. In this embodiment, the embedded insulator 19 includes a silicon oxide film having properties different from properties of the insulating film 17.

The embedded insulator 19 may have a single layer structure or a laminated structure including at least one among an undoped silicon oxide film, a silicon oxide film containing phosphorus, and a silicon oxide film containing both phosphorus and boron. The undoped silicon oxide film may be referred to as an NSG film (a nondoped silicon glass film), the silicon oxide film containing phosphorus may be referred to as a PSG film (a phosphorus silicon glass film), and the silicon oxide film containing both phosphorus and boron may be referred to as a BPSG film (a boron phosphorus silicon glass film).

The embedded insulator 19 preferably has a single layer structure or a laminated structure including at least the NSG film. The embedded insulator 19 may have a laminated structure including the NSG film and the PSG film laminated in that order from the chip 2 side. The embedded insulator 19 may have a laminated structure including the NSG film, the PSG film, and a BPSG film laminated in that order from the chip 2 side. The embedded insulator 19 may have a single layer structure or a laminated structure including a silicon oxide film including an oxide of the embedded electrode 18.

The embedded insulator 19 is embedded on the embedded electrode 18 in the trench 16 and covers the embedded electrode 18. In this embodiment, the embedded insulator 19 is embedded in the trench 16 with the insulating film 17 interposed therebetween, and is in contact with the insulating film 17 and the embedded electrode 18 in the trench 16.

The embedded insulator 19 has a portion opposing the chip 2 in the horizontal direction with the insulating film 17 interposed therebetween, and exposes the first main surface 3. The embedded insulator 19 is embedded in the trench 16 at an interval toward the bottom wall side of the trench 16 from the height position of the first main surface 3, and a portion of the chip 2 is exposed from the opening end of the trench 16.

The embedded insulator 19 has an insulating surface exposed from the trench 16. The insulating surface is positioned on the bottom wall side of the trench 16 with respect to the height position of the first main surface 3. The insulating surface is positioned on the opening side of the trench 16 with respect to the depth position of the intermediate portion of the trench 16. The insulating surface may be positioned on the bottom wall side of the trench 16 with respect to the depth position of the intermediate portion of the trench 16.

The insulating surface exposes the upper end portion of the insulating film 17. In this embodiment, the insulating surface is flatly continuous to the upper end portion of the insulating film 17. That is, the insulating surface is formed to be flush with the upper end portion of the insulating film 17. The insulating surface may be positioned further to the first main surface 3 side than the upper end portion of the insulating film 17, or may be positioned further to the bottom wall side of the trench 16 than the upper end portion of the insulating film 17. The insulating surface may be formed to be flush with the first main surface 3 together with the upper end portion of the insulating film 17.

In this embodiment, the insulating surface has a raised portion raised from the side wall of the trench 16 toward an inner side of the trench 16. The raised portion of the insulating surface is positioned on the bottom wall side of the trench 16 with respect to the height position of the first main surface 3. The raised portion of the insulating surface may project further upward than the height position of the first main surface 3. The insulating surface may have a recess portion sinking from the side wall of the trench 16 toward an inner side of the trench 16 instead of the raised portion. The insulating surface may be formed to be flush with the first main surface 3.

In this embodiment, the embedded insulator 19 has a thickness greater than the thickness of the first film portion of the insulating film 17. The thickness of the embedded insulator 19 may be less than the thickness of the first film portion of the insulating film 17. In this embodiment, the thickness of the embedded insulator 19 is greater than the thickness of the second film portion of the insulating film 17. The thickness of the embedded insulator 19 may be less than a thickness of the second film portion of the insulating film 17.

The thickness of the embedded insulator 19 is preferably less than the thickness of the embedded electrode 18. The ratio of the thickness of the embedded insulator 19 to the depth of the trench 16 may exceed 0 and not more than 0.5. The ratio of the thickness may have a value belonging to at least one range among exceeding 0 and not more than 0.1, not less than 0.1 and not more than 0.2, not less than 0.2 and not more than 0.3, not less than 0.3 and not more than 0.4, and not less than 0.4 and not more than 0.5.

The semiconductor device 1A includes a plurality of mesa portions 20 demarcated in the first main surface 3 in the active region 8 (the inner portion of the first main surface 3). The plurality of mesa portions 20 are respectively demarcated into regions between the plurality of adjacent gate structures 15.

The plurality of mesa portions 20 are demarcated at intervals in the first direction X in conformance to the layout of the plurality of gate structures 15, and each extend in a band shape in the second direction Y. That is, the plurality of mesa portions 20 extend in a stripe shape in the second direction Y. The width of each mesa portion 20 corresponds to the pitch of the plurality of gate structures 15. The plurality of mesa portions 20 may extend in the first direction X in accordance with the extension direction of the plurality of gate structures 15.

The semiconductor device 1A includes a plurality of well regions 25 of the p-type formed in the chip 2 (the second semiconductor layer 7). The plurality of well regions 25 have a p-type impurity concentration higher than the n-type impurity concentration of the second semiconductor layer 7, and replace the conductivity type of the second semiconductor layer 7 from the n-type to the p-type. The source potential is to be applied to the plurality of well regions 25.

The plurality of well regions 25 are respectively formed within the second semiconductor layer 7 in regions below (specifically, directly below) the plurality of gate structures 15 at intervals in the horizontal direction (the first direction X). The plurality of well regions 25 are respectively formed in a thickness range between the bottom portion of the second semiconductor layer 7 and the bottom walls of the plurality of gate structures 15, and overlap the plurality of gate structures 15 in a one-to-one correspondence in the thickness direction.

Each of the plurality of well regions 25 extends in a band shape in the second direction Y in conformance to the extension direction of the corresponding gate structure 15 in plan view. That is, the plurality of well regions 25 are aligned in a stripe shape extending in the second direction Y in plan view. An extension direction of the plurality of well regions 25 coincides with the off direction of the SiC monocrystal.

In regard to the second direction Y, both end portions of the plurality of well regions 25 may be positioned on an inner side of the active region 8 with respect to the both end portions of the plurality of gate structures 15, or may be positioned on a peripheral edge side of the active region 8. The plurality of well regions 25 may extend in the first direction X in accordance with the extension direction of the plurality of gate structures 15. In this case, the plurality of well regions 25 intersect (specifically, are orthogonal to) the off direction.

The plurality of well regions 25 are formed at an interval toward the bottom wall side of the plurality of gate structures 15 from the bottom portion of the second semiconductor layer 7, and oppose the first semiconductor layer 6 with a portion of the second semiconductor layer 7 interposed therebetween. The plurality of well regions 25 each has an upper end portion positioned on the bottom wall side of the corresponding gate structure 15 and a bottom portion positioned on the bottom portion side of the second semiconductor layer 7.

The upper end portions of the plurality of well regions 25 are formed at an interval toward the bottom wall side from a bottom portion of the body region 10 of the corresponding gate structure 15. The upper end portion of each of the plurality of well regions 25 may be connected to the bottom wall of the corresponding gate structure 15. The upper end portions of the plurality of well regions 25 may have a portion along the side wall of the corresponding gate structure 15. The upper end portions of the plurality of well regions 25 may be formed at an interval toward the bottom portion side of the second semiconductor layer 7 from the bottom wall of the corresponding gate structure 15.

The bottom portions of the plurality of well regions 25 may be positioned on the bottom wall side of the plurality of gate structures 15 with respect to the depth position of the intermediate portion of the second semiconductor layer 7, or may be positioned on the bottom portion side of the second semiconductor layer 7 (the second main surface 4 side) with respect to the depth position of the intermediate portion of the second semiconductor layer 7. The bottom portions of the plurality of well regions 25 are directly connected to the second semiconductor layer 7. The plurality of well regions 25 form a JFET region Tj (junction field-effect transistor region) together with the second semiconductor layer 7 in a region below the gate structure 15.

On a basis of the bottom wall of the gate structure 15, the well region 25 may have a depth of not less than 0.5 μm and not more than 5 μm. The depth of the well region 25 may have a value belonging to at least one range among not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The plurality of well regions 25 each has one or a plurality of (two in this embodiment) bulging regions 26 and one or a plurality of (one in this embodiment) constricted regions 27 in a thickness direction of the second semiconductor layer 7.

The plurality of bulging regions 26 are formed at mutually different depth positions in the thickness direction of the chip 2. The plurality of bulging regions 26 include a first bulging region 26A positioned on the bottom wall side of the gate structure 15 and a second bulging region 26B positioned on the bottom portion side of the second semiconductor layer 7. The first bulging region 26A is positioned on the bottom wall side of the gate structure 15 with respect to a depth position of an intermediate portion of the well region 25 and forms the upper end portion of the well region 25.

The first bulging region 26A extends in a band shape in the second direction Y in conformance to the extension direction of the gate structure 15. In regard to the second direction Y, both end portions of the first bulging region 26A may be positioned on the inner side of the active region 8 with respect to the both end portions of the gate structure 15, or may be positioned on the peripheral edge side of the active region 8.

The first bulging region 26A protrudes in the horizontal direction from a region directly below the corresponding gate structure 15 to both sides of the corresponding gate structure 15. Specifically, the first bulging region 26A protrudes in an arc shape (circular arc shape) in the horizontal direction with respect to the side walls of the corresponding gate structure 15 and overlaps the bottom portion of the body region 10 in the thickness direction of the second semiconductor layer 7. The first bulging region 26A is formed at an interval toward the corresponding gate structure 15 side from an intermediate position between the two adjacent gate structures 15.

A first protrusion amount of the first bulging region 26A on a basis of the side wall of the gate structure 15 may be greater than 0 nm and not more than 200 nm. The first protrusion amount may have a value belonging to at least one range among greater than 0 nm and not more than 25 nm, not less than 25 nm and not more than 50 nm, not less than 50 nm and not more than 75 nm, not less than 75 nm and not more than 100 nm, not less than 100 nm and not more than 125 nm, not less than 125 nm and not more than 150 nm, not less than 150 nm and not more than 175 nm, and not less than 175 nm and not more than 200 nm.

The first bulging region 26A may have a width of not less than 0.1 μm and not more than 2.5 μm. The width of the first bulging region 26A may have a value belonging to at least one range among not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, not less than 1.75 μm and not more than 2 μm, not less than 2 μm and not more than 2.25 μm, and not less than 2.25 μm and not more than 2.5 μm.

The ratio of the depth of the first bulging region 26A to a depth of the well region 25 (first depth ratio) may be greater than 0 and not more than 0.5. The depth of the first bulging region 26A is a depth on a basis of the bottom wall of the gate structure 15. The first depth ratio may have a value belonging to at least one range among greater than 0 and not more than 0.1, not less than 0.1 and not more than 0.2, not less than 0.2 and not more than 0.3, not less than 0.3 and not more than 0.4, and not less than 0.4 and not more than 0.5. The first depth ratio is preferably less than 0.5.

The depth of the first bulging region 26A is smaller than a depth of the gate structure 15 on a basis of the first main surface 3. The depth of the first bulging region 26A may be greater than 0 μm and not more than 1 μm. The depth of the first bulging region 26A may have a value belonging to at least one range among greater than 0μm and not more than 0.1 μm, not less than 0.1 μm and not more than 0.2 μm, not less than 0.2 μm and not more than 0.3 μm, not less than 0.3 μm and not more than 0.4 μm, not less than 0.5 μm and not more than 0.6 μm, not less than 0.6 μm and not more than 0.7 μm, not less than 0.7 μm and not more than 0.8 μm, not less than 0.8 μm and not more than 0.9 μm, and not less than 0.9 μm and not more than 1 μm. The depth of the first bulging region 26A is preferably not more than 0.5 μm.

The second bulging region 26B is positioned on the bottom portion side of the second semiconductor layer 7 with respect to the first bulging region 26A and forms a bottom portion of the well region 25. The second bulging region 26B extends in a band shape in the second direction Y in conformance to the extension direction of the gate structure 15. In regard to the second direction Y, both end portions of the second bulging region 26B may be positioned on the inner side of the active region 8 with respect to the both end portions of the gate structure 15, or may be positioned on the peripheral edge side of the active region 8.

In this embodiment, the second bulging region 26B has a portion positioned on the bottom wall side of the corresponding gate structure 15 with respect to the depth position of the intermediate portion of the well region 25 and a portion positioned on the bottom portion side of the second semiconductor layer 7 with respect to the depth position of the intermediate portion of the well region 25.

The second bulging region 26B protrudes in the horizontal direction from a region directly below the corresponding gate structure 15 to both sides of the corresponding gate structure 15. Specifically, the second bulging region 26B protrudes in an arc shape (circular arc shape) in the horizontal direction with respect to the side walls of the corresponding gate structure 15 and overlaps the bottom portion of the body region 10 in the thickness direction of the second semiconductor layer 7. A curvature of the second bulging region 26B may be less than a curvature of the first bulging region 26A.

The second bulging region 26B is formed at an interval toward the corresponding gate structure 15 side from the intermediate position between the two adjacent gate structures 15. A second protrusion amount of the second bulging region 26B on a basis of the side wall of the gate structure 15 is smaller than the first protrusion amount of the first bulging region 26A. The second protrusion amount may be substantially equal to the first protrusion amount or may be greater than the first protrusion amount.

The second protrusion amount may exceed 0 nm and not more than 200 nm. The second protrusion amount may have a value belonging to at least one range among exceeding 0 nm and not more than 25 nm, not less than 25 nm and not more than 50 nm, not less than 50 nm and not more than 75 nm, not less than 75 nm and not more than 100 nm, not less than 100 nm and not more than 125 nm, not less than 125 nm and not more than 150 nm, not less than 150 nm and not more than 175 nm, and not less than 175 nm and not more than 200 nm.

The second bulging region 26B may have a width of not less than 0.1 μm and not more than 2.5 μm. The width of the second bulging region 26B may have a value belonging to at least one range among not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, not less than 1.75 μm and not more than 2 μm, not less than 2 μm and not more than 2.25 μm, and not less than 2.25 μm and not more than 2.5 μm.

The second bulging region 26B does not necessarily have to protrude further outward than the side wall of the gate structure 15. Accordingly, the second bulging region 26B may be positioned in a region below the bottom wall of the gate structure 15 with respect to the side wall of the gate structure 15.

The ratio of the depth of the second bulging region 26B to a depth of the well region 25 (second depth ratio) is calculated by “1—the first depth ratio.” The depth of the second bulging region 26B is a depth on a basis of the bottom wall of the gate structure 15. The second depth ratio is preferably not less than 0.5. The second depth ratio is particularly preferably greater than 0.5.

The depth of the second bulging region 26B is obtained by subtracting the depth of the first bulging region 26A from the depth of the well region 25. In this embodiment, the depth of the second bulging region 26B is smaller than the depth of the gate structure 15 on a basis of the first main surface 3. The depth of the second bulging region 26B may be greater than the depth of the gate structure 15 on a basis of the first main surface 3.

The depth of the second bulging region 26B may be not less than 0.5 μm and not more than 5 μm. The depth of the second bulging region 26B may have a value belonging to at least one range among not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The constricted region 27 is recessed, below the first bulging region 26A, with respect to the first bulging region 26A in the horizontal direction along the first main surface 3. The constricted region 27 may be regarded as a lower end portion of the first bulging region 26A. Specifically, the constricted region 27 forms a connection portion of the first bulging region 26A and the second bulging region 26B in a region between the first bulging region 26A and the second bulging region 26B, and is recessed in an arc shape inward in the horizontal direction from the first bulging region 26A and the second bulging region 26B.

The constricted region 27 may be positioned in a region below the bottom wall of the gate structure 15 and may oppose the bottom wall of the gate structure 15 in a thickness direction. The constricted region 27 may be positioned further outward than the side wall of the gate structure 15. The constricted region 27 may be positioned in a region on the bottom wall side of the gate structure 15 with respect to the depth position of the intermediate portion of the well region 25. The constricted region 27 may be positioned in a region on the bottom portion side of the second semiconductor layer 7 with respect to the depth position of the intermediate portion of the well region 25.

The constricted region 27 has a width less than the width of the first bulging region 26A. The width of the constricted region 27 is less than the width of the second bulging region 26B. The width of the constricted region 27 may be greater than the width of the gate structure 15, or may be less than the width of the gate structure 15.

The constricted region 27 may have a width of not less than 0.1 μm and not more than 2 μm. The width of the constricted region 27 may have a value belonging to at least one range among not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, and not less than 1.75 μm and not more than 2 μm.

The plurality of well regions 25 include a first well region 28 forming the first bulging region 26A and a second well region 29 forming the second bulging region 26B, respectively. The configuration of the first well region 28 is obtained by replacing the “first bulging region 26A” with the “first well region 28” in the above description. The configuration of the second well region 29 is obtained by replacing the “second bulging region 26B” with the “second well region 29” in the above description. The first well region 28 may be regarded as including the first bulging region 26A, and the second well region 29 may be regarded as including the second bulging region 26B.

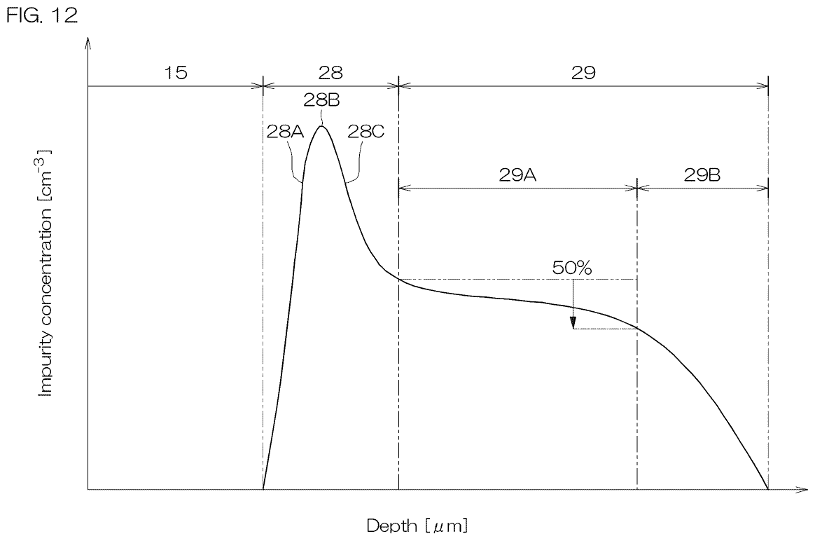

Hereinafter, a concentration gradient of the well region 25 shall be described with reference to FIG. 12. FIG. 12 is a graph illustrating an impurity concentration of the well region 25. In FIG. 12, the ordinate indicates a p-type impurity concentration of the well region 25, and the abscissa indicates a depth.

With reference to FIG. 12, the first well region 28 is a well high concentration region having a relatively high p-type impurity concentration and is formed by introducing a p-type impurity (trivalent element) into the second semiconductor layer 7. The first well region 28 has a p-type impurity concentration higher than the n-type impurity concentration of the second semiconductor layer 7, and replaces the conductivity type of the second semiconductor layer 7 from the n-type to the p-type.

The p-type impurity concentration of the first well region 28 is higher than the p-type impurity concentration of the body region 10. The first well region 28 contains a second element consisting of a trivalent element in addition to a pentavalent element (that is, the first element, nitrogen in this embodiment) of the second semiconductor layer 7. The second element may include at least one type among boron and aluminum. The first well region 28 is preferably adjusted in concentration by a single second element. The second element is preferably aluminum.

The first well region 28 is consisting of a random region in which a large amount of trivalent elements are dispersed in a random direction of the SiC monocrystal (the second semiconductor layer 7), and has a concentration gradient that increases/decreases downward from the bottom wall of the gate structure 15. The random direction is a direction other than an axis channel of the SiC monocrystal (the second semiconductor layer 7). The random direction is, for example, a direction intersecting the axis channel (for example, the vertical direction Z).

The axis channel is constituted of regions (channels) that are of relatively wide interatomic distance (atomic interval) in the SiC monocrystal (the second semiconductor layer 7), and are surrounded by atomic rows constituting a crystal axis extending in a thickness direction (crystal growth direction). That is, the axis channel is constituted of regions that are sparse in atomic rows and extend in the thickness direction and are regions in which atomic rows (interatomic distance/atomic density) in the horizontal directions are sparse in plan view.

The axis channel is preferably constituted of regions surrounded by atomic rows oriented along a low index crystal axis among crystal axes. A low index crystal axis is, in terms of Miller indices (a1, a2, a3, and c), a crystal axis expressed by absolute values of “a1,” “a2,” “a3,” and “c” all being not less than 0 and not more than 2 (preferably not more than 1).

In this embodiment, the axis channel is consisting of regions surrounded by atomic rows oriented along the c-axis (the (0001) axis) of the SiC monocrystal. That is, the axis channel extends along the c-axis and has the off direction and the off angle described above. In other words, the axis channel is inclined by just the off angle toward the off direction from the vertical axis.

The concentration gradient of the first well region 28 includes an increasing portion 28A, a peak portion 28B, and a decreasing portion 28C in a thickness range of the first well region 28. The increasing portion 28A is a region in which the p-type impurity concentration steeply increases downward from the bottom wall of the gate structure 15.

The peak portion 28B is a region in which the p-type impurity concentration becomes maximum. The peak portion 28B is formed at a depth position of an intermediate portion of the first well region 28. The decreasing portion 28C is a region in which the p-type impurity concentration steeply decreases downward from the peak portion 28B.

The second well region 29 is a well low concentration region having a p-type impurity concentration lower than the p-type impurity concentration of the first well region 28, and is formed by introducing a p-type impurity (trivalent element) into the second semiconductor layer 7. The second well region 29 has a p-type impurity concentration higher than the n-type impurity concentration of the second semiconductor layer 7, and replaces the conductivity type of the second semiconductor layer 7 from the n-type to the p-type.

The p-type impurity concentration of the second well region 29 may be higher than the p-type impurity concentration of the body region 10, or may be lower than the p-type impurity concentration of the body region 10. The second well region 29 contains a third element consisting of a trivalent element in addition to a pentavalent element (that is, the first element, nitrogen in this embodiment) of the second semiconductor layer 7.

The third element may include at least one type among boron and aluminum. The third element (trivalent element) of the second well region 29 may be of a different type from or of the same type as the second element (trivalent element) of the first well region 28. The second well region 29 is preferably adjusted in concentration by a single third element. The third element is preferably aluminum.

The second well region 29 has a concentration gradient different from the concentration gradient of the first well region 28. The second well region 29 is consisting of a channeling region in which a large amount of trivalent elements are dispersed along the axis channel of the SiC monocrystal (the second semiconductor layer 7), and has a concentration gradient that decreases (monotonically decreases in this embodiment) downward from the bottom wall of the gate structure 15. That is, in this embodiment, the second well region 29 extends along a c-axis of the SiC monocrystal and is inclined at the above-described off direction and off angle.

The channeling region is formed by introducing impurity ions into the second semiconductor layer 7 along the axis channel. Since the impurity ions are introduced into the second semiconductor layer 7 while repeating small angle scattering due to a channeling effect, a collision probability with respect to the atomic rows of the SiC monocrystal is reduced. Thereby, a channeling region in which a relatively high impurity concentration is maintained up to a relatively deep target position is formed. The depth of the channeling region is adjusted by an implantation energy of the impurity ions.

The second well region 29 has a concentration gradient that gradually decreases from the bottom wall of the gate structure 15 toward a bottom portion. The concentration gradient of the second well region 29 is preferably monotonically decreasing toward the bottom portion. The concentration gradient of the second well region 29 includes a gently sloping portion 29A and a decreasing portion 29B downward from a bottom portion (lower end portion) of the first well region 28.

The gently sloping portion 29A has a concentration decrease rate smaller than a concentration decrease rate of the decreasing portion 28C of the first well region 28, and is a portion that maintains a fixed p-type impurity concentration over a fixed depth range. The bottom portion (lower end portion) of the first well region 28 and an upper end portion of the second well region 29 are formed by a concentration transition portion between the decreasing portion 28C of the first well region 28 and the gently sloping portion 29A of the second well region 29.

The p-type impurity concentration of the gently sloping portion 29A gradually decreases gently in a concentration range lower than the p-type impurity concentration of the decreasing portion 29C of the first well region 28. That is, the gently sloping portion 29A (the second well region 29) does not have a concentration gradient that steeply increases with the first well region 28 (the decreasing portion 28C) as a starting point.

The gently sloping portion 29A may have a concentration decrease rate of not more than 50% over a depth range of at least 0.25 μm. The gently sloping portion 29A may have a concentration decrease rate of not more than 50% over a depth range of at least 0.5 μm. The gently sloping portion 29A may have a concentration decrease rate of not more than 50% over a thickness range of 25% of the well region 25.

The decreasing portion 29B is a portion forming the bottom portion of the well region 25 (the second well region 29). The decreasing portion 29B has a concentration decrease rate greater than a concentration decrease rate of the gently sloping portion 29A and is a portion in which the p-type impurity concentration steeply decreases from the gently sloping portion 29A toward the bottom portion. The p-type impurity concentration of the decreasing portion 29B monotonically decreases toward the bottom portion. The concentration decrease rate per unit depth of the decreasing portion 29B is greater than a concentration decrease rate per unit depth of the gently sloping portion 29A.

In the well region 25 (the second well region 29), the bottom portion having the lowest p-type impurity concentration is directly connected to the second semiconductor layer 7 having a relatively low n-type impurity concentration. That is, the bottom portion of the well region 25 (the second well region 29) appropriately forms the JFET region Tj together with the second semiconductor layer 7.

The semiconductor device 1A includes a plurality of high concentration regions 30 of the n-type respectively formed in regions lateral to the plurality of gate structures 15 in the chip 2 (the second semiconductor layer 7). The plurality of high concentration regions 30 have an n-type impurity concentration higher than the n-type impurity concentration of the second semiconductor layer 7 and are regions in which the n-type impurity concentration of the second semiconductor layer 7 is increased.

The plurality of high concentration regions 30 may be regarded as high concentration portions of the second semiconductor layer 7. The n-type impurity concentration of the plurality of high concentration regions 30 may be appropriately compared by comparison with the n-type impurity concentration on the bottom portion side of the second semiconductor layer 7. The high concentration regions 30 may be referred to as “high concentration drift regions.”

The plurality of high concentration regions 30 are respectively formed in regions on both sides of the plurality of gate structures 15. Specifically, the plurality of high concentration regions 30 are respectively formed in regions between the plurality of gate structures 15. In this embodiment, the plurality of high concentration regions 30 are respectively formed in a one-to-one correspondence with the plurality of mesa portions 20.

The plurality of high concentration regions 30 each extend in a band shape in the second direction Y in plan view in conformance to the extension direction of the plurality of gate structures 15. That is, the plurality of high concentration regions 30 extend in a stripe shape in the second direction Y in plan view. The plurality of high concentration regions 30 may be respectively formed in a multiple-to-one correspondence with the plurality of mesa portions 20. In this case, the plurality of high concentration regions 30 may be formed at intervals in the second direction Y in the corresponding mesa portions 20.

The plurality of high concentration regions 30 are formed in regions on the bottom wall side of the plurality of gate structures 15 with respect to the bottom portion of the body region 10 so as to be positioned at least in a thickness range between the bottom portion of the body region 10 and the bottom walls of the plurality of gate structures 15.

In this embodiment, the plurality of high concentration regions 30 have portions positioned on the bottom portion side of the second semiconductor layer 7 with respect to depth positions of the bottom walls of the plurality of gate structures 15. That is, the plurality of high concentration regions 30 are respectively formed in regions lateral to the plurality of well regions 25 in the chip 2 (the second semiconductor layer 7).

The plurality of high concentration regions 30 are respectively interposed in regions between the plurality of well regions 25 in regions below the plurality of gate structures 15. The plurality of high concentration regions 30 are connected to one or both (both in this embodiment) of adjacent plurality of the well regions 25. Specifically, the plurality of high concentration regions 30 respectively form pn-junction portions with the plurality of well regions 25.

The plurality of high concentration regions 30 may form a charge balance with the plurality of well regions 25. The charge balance means a state where depletion layers spreading from the pn-junction portions between the plurality of high concentration regions 30 and the plurality of well regions 25 are connected in the plurality of high concentration regions 30.

According to this configuration, the plurality of high concentration regions 30 form a super junction structure together with the plurality of well regions 25. The plurality of high concentration regions 30 do not necessarily have to form a super junction structure with the plurality of well regions 25, and may suffice to form just a body diode structure.

In this embodiment, the plurality of high concentration regions 30 respectively include an upper end portion positioned on the first main surface 3 side with respect to the bottom walls of the plurality of gate structures 15, and a bottom portion positioned on the bottom portion side of the second semiconductor layer 7 with respect to the bottom walls of the plurality of gate structures 15. The bottom portions of the plurality of high concentration regions 30 are defined by concentration transition portions in which the n-type impurity concentration gradually decreases toward the bottom portion side of the second semiconductor layer 7.

The upper end portions of the plurality of high concentration regions 30 are electrically connected to the body region 10. The upper end portions of the plurality of high concentration regions 30 are connected to one or both (both in this embodiment) of the adjacent plurality of gate structures 15. The upper end portions of the plurality of high concentration regions 30 have portions opposing the embedded electrodes 18 of the corresponding gate structures 15 with the insulating films 17 of the corresponding gate structures 15 interposed therebetween.

The upper end portions of the plurality of high concentration regions 30 are formed in a thickness range between the bottom portion of the body region 10 and the upper end portions of the plurality of well regions 25. The plurality of high concentration regions 30 suppress an increase in p-type impurity concentration of portions along the side walls of the plurality of gate structures 15 and separate the plurality of well regions 25 from the body region 10.

The bottom portions of the plurality of high concentration regions 30 are formed at an interval toward the first main surface 3 side from the bottom portion of the second semiconductor layer 7, and oppose the first semiconductor layer 6 with a portion of the second semiconductor layer 7 interposed therebetween. The bottom portions of the plurality of high concentration regions 30 may be formed at an interval toward the first main surface 3 side from the depth position of the intermediate portion of the second semiconductor layer 7, or may be positioned on the bottom portion side of the second semiconductor layer 7 with respect to the depth position of the intermediate portion of the second semiconductor layer 7.

In this embodiment, the bottom portions of the plurality of high concentration regions 30 are positioned on the first main surface 3 side with respect to depth positions of bottom portions of the plurality of well regions 25 (the second well regions 29). That is, the bottom portions of the plurality of high concentration regions 30 are formed at an interval toward the first main surface 3 side from the bottom portions of the well regions 25 (the second well regions 29), and maintain a configuration in which the well regions 25 (the second well regions 29) are directly connected to the second semiconductor layer 7.

The bottom portions of the plurality of high concentration regions 30 are connected to the well regions 25 in regions on the bottom portion side with respect to depth positions of the intermediate portions of the plurality of well regions 25. Specifically, the bottom portions of the plurality of high concentration regions 30 are connected to regions on the bottom portion side of the second well regions 29.

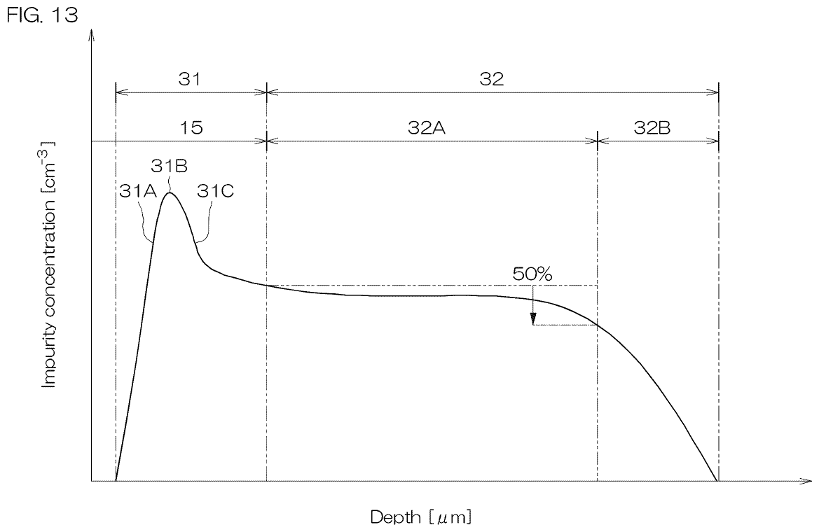

Hereinafter, a specific configuration of the high concentration regions 30 shall be described with reference also to FIG. 13. FIG. 13 is a graph illustrating an impurity concentration of the high concentration regions 30. In FIG. 13, the ordinate indicates an n-type impurity concentration of the high concentration regions 30, and the abscissa indicates a depth.

The plurality of high concentration regions 30 each include a first high concentration region 31 positioned on the first main surface 3 side with respect to the bottom wall of the gate structure 15, and a second high concentration region 32 positioned on the bottom portion side of the second semiconductor layer 7 with respect to the bottom wall of the gate structure 15.

The first high concentration region 31 forms the upper end portion of the high concentration region 30. The first high concentration region 31 extends in a band shape in the second direction Y in conformance to the extension direction of the gate structure 15. In regard to the second direction Y, both end portions of the first high concentration region 31 may be positioned on an inner side of the gate structure 15 with respect to the both end portions of the gate structure 15, or may be positioned on the peripheral edge side of the active region 8.

The first high concentration region 31 is positioned in a thickness range between the bottom portion of the body region 10 and the upper end portion of the well region 25 (the bottom wall of the gate structure 15), and separates the plurality of well regions 25 from the body region 10. In this embodiment, the first high concentration region 31 has a thickness smaller than a thickness between the bottom portion of the body region 10 and the bottom wall of the gate structure 15 (the upper end portion of the well region 25), and is positioned on the bottom portion side of the body region 10 with respect to the bottom wall of the gate structure 15. The first high concentration region 31 opposes the embedded electrode 18 with the insulating film 17 interposed therebetween.

The first high concentration region 31 may have a thickness greater than a thickness between the bottom portion of the body region 10 and the bottom wall of the gate structure 15 (the upper end portion of the well region 25), and may have a portion positioned on a bottom portion side of the second semiconductor region 7 with respect to the depth position of the bottom wall of the gate structure 15. In this case, the first high concentration region 31 may have a portion connected to the well region 25.

The first high concentration region 31 is a region having a relatively high n-type impurity concentration and is formed by introducing an n-type impurity (pentavalent element) into the second semiconductor layer 7. The n-type impurity concentration of the first high concentration region 31 is higher than the p-type impurity concentration of the body region 10. The n-type impurity concentration of the first high concentration region 31 may be lower than the p-type impurity concentration of the body region 10. The n-type impurity concentration of the first high concentration region 31 may be lower than the p-type impurity concentration of the first well region 28.

The first high concentration region 31 contains a fourth element consisting of a pentavalent element in addition to a pentavalent element (that is, a first element, nitrogen in this embodiment) of the second semiconductor layer 7. The fourth element is an additional pentavalent element with respect to the first element of the second semiconductor layer 7. The fourth element may include at least one type among nitrogen, phosphorus, and arsenic.

The fourth element of the first high concentration region 31 may be of the same type as the first element of the second semiconductor layer 7 or may be of a different type from the first element of the second semiconductor layer 7. The fourth element is preferably different from the first element. That is, the first high concentration region 31 preferably contains a plurality of types of pentavalent elements. The first high concentration region 31 is preferably adjusted in concentration by a single fourth element. The fourth element is preferably phosphorus. That is, the first high concentration region 31 is preferably adjusted in concentration by nitrogen and phosphorus.

The impurity concentration of the first high concentration region 31 is separated from both the impurity concentration of the first well region 28 and the impurity concentration of the second well region 29. A concentration of the second element (trivalent element) of the first well region 28 in the first high concentration region 31 is lower than the concentration of the second element in the first well region 28. A concentration of the third element (trivalent element) of the second well region 29 in the first high concentration region 31 is lower than the concentration of the third element in the second well region 29.

The first high concentration region 31 does not contain the second element of the first well region 28 and the third element of the second well region 29. The phrase “the first high concentration region 31 does not contain the second element and the third element” means that a concentration of the second element and a concentration of the third element in an inner portion of the first high concentration region 31 are lower than a detection limit and are at a noise level even if detected.

Similarly, a concentration of the fourth element of the first high concentration region 31 in the first well region 28 is lower than the concentration of the fourth element in the first high concentration region 31. The first well region 28 does not contain the fourth element. The phrase “the first well region 28 does not contain the fourth element” means that a concentration of the fourth element in an inner portion of the first well region 28 is lower than a detection limit and is at a noise level even if detected.

Similarly, a concentration of the fourth element of the first high concentration region 31 in the second well region 29 is lower than the concentration of the fourth element in the first high concentration region 31. The second well region 29 does not contain the fourth element. The phrase “second well region 29 does not contain the fourth element” means that a concentration of the fourth element in an inner portion of the second well region 29 is lower than a detection limit and is at a noise level even if detected.

The first high concentration region 31 is consisting of a random region in which a large amount of additional pentavalent elements are dispersed in a random direction of the SiC monocrystal (the second semiconductor layer 7) in addition to the pentavalent element of the second semiconductor layer 7, and has a concentration gradient that increases/decreases downward from the bottom wall of the gate structure 15.

The concentration gradient of the first high concentration region 31 includes an increasing portion 31A, a peak portion 31B, and a decreasing portion 31C in a thickness range of the first high concentration region 31. The increasing portion 31A is a region in which the n-type impurity concentration steeply increases downward from the bottom portion of the body region 10. The peak portion 31B is a region in which the n-type impurity concentration becomes maximum. The peak portion 31B is formed at a depth position of an intermediate portion of the first high concentration region 31.

The decreasing portion 31C is a region in which the n-type impurity concentration steeply decreases downward from the peak portion 31B. The p-type impurity concentration of the decreasing portion 31C monotonically decreases toward the bottom portion. The n-type impurity concentrations of the increasing portion 31A, the peak portion 31B, and the decreasing portion 31C are all higher than the n-type impurity concentration on the bottom portion side of the second semiconductor layer 7.

The thickness of the first high concentration region 31 may be greater than 0 μm and not more than 1 μm. The thickness of the first high concentration region 31 may have a value belonging to at least one range among greater than 0μm and not more than 0.1 μm, not less than 0.1 μm and not more than 0.2 μm, not less than 0.2 μm and not more than 0.3 μm, not less than 0.3 μm and not more than 0.4 μm, not less than 0.4 μm and not more than 0.5 μm, not less than 0.5 μm and not more than 0.6 μm, not less than 0.6 μm and not more than 0.7 μm, not less than 0.7 μm and not more than 0.8 μm, not less than 0.8 μm and not more than 0.9 μm, and not less than 0.9 μm and not more than 1 μm.

For example, a distance between a bottom wall of the gate structure 15 and a lower end portion (bottom portion) of the first high concentration region 31 may be not less than 0 μm and not more than 0.5 μm. The distance may have a value belonging to at least one range among not less than 0 μm and not more than 0.1 μm, not less than 0.1 μm and not more than 0.2 μm, not less than 0.2 μm and not more than 0.3 μm, not less than 0.3 μm and not more than 0.4 μm, and not less than 0.4 μm and not more than 0.5 μm.

The second high concentration region 32 forms the bottom portion of the high concentration region 30. The second high concentration region 32 extends in a band shape in the second direction Y in conformance to the extension direction of the gate structure 15. In regard to the second direction Y, both end portions of the second high concentration region 32 may be positioned on the inner side of the gate structure 15 with respect to the both end portions of the gate structure 15, or may be positioned on the peripheral edge side of the active region 8.

The second high concentration region 32 has an n-type impurity concentration lower than the n-type impurity concentration of the first high concentration region 31 and is positioned below the first high concentration region 31. In this embodiment, the second high concentration region 32 has a portion interposed in a region between the plurality of gate structures 15 and a portion interposed in a region between the plurality of well regions 25.

The second high concentration region 32 is connected to the side walls of the plurality of gate structures 15 in a region higher than the bottom walls of the plurality of gate structures 15. The second high concentration region 32 opposes the embedded electrode 18 with the insulating film 17 interposed therebetween. The second high concentration region 32 is electrically connected to both the first well region 28 and the second well region 29 in a region lower than the bottom walls of the plurality of gate structures 15.

The second high concentration region 32 is formed by introducing an n-type impurity (pentavalent element) into the second semiconductor layer 7. The n-type impurity concentration of the second high concentration region 32 may be higher than the p-type impurity concentration of the body region 10, or may be lower than the p-type impurity concentration of the body region 10. The n-type impurity concentration of the second high concentration region 32 may be lower than the p-type impurity concentration of the first well region 28. The n-type impurity concentration of the second high concentration region 32 may be higher than the p-type impurity concentration of the second well region 29 or may be lower than the p-type impurity concentration of the first well region 28.

The second high concentration region 32 contains a fifth element consisting of a pentavalent element in addition to a pentavalent element (that is, a first element, nitrogen in this embodiment) of the second semiconductor layer 7. The fifth element is an additional pentavalent element with respect to the first element of the second semiconductor layer 7. The fifth element may include at least one type among nitrogen, phosphorus, and arsenic.

The fifth element of the second high concentration region 32 may be of the same type as the fourth element of the first high concentration region 31 or may be of a different type from the fourth element of the first high concentration region 31. The fifth element of the second high concentration region 32 may be of the same type as the first element of the second semiconductor layer 7 or may be of a different type from the first element of the second semiconductor layer 7.

The fifth element is preferably different from the first element. That is, the second high concentration region 32 preferably contains a plurality of types of pentavalent elements. The second high concentration region 32 is preferably adjusted in concentration by a single fifth element. The fifth element is preferably phosphorus. That is, the second high concentration region 32 is preferably adjusted in concentration by nitrogen and phosphorus.

The impurity concentration of the second high concentration region 32 is separated from both the impurity concentration of the first well region 28 and the impurity concentration of the second well region 29. The concentration of the second element (trivalent element) of the first well region 28 in the second high concentration region 32 is lower than the concentration of the second element in the first well region 28. The concentration of the third element (trivalent element) of the second well region 29 in the second high concentration region 32 is lower than the concentration of the third element in the second well region 29.

The second high concentration region 32 does not contain the second element of the first well region 28 and the third element of the second well region 29. The phrase “the second high concentration region 32 does not contain the second element and the third element” means that a concentration of the second element and a concentration of the third element in an inner portion of the second high concentration region 32 are lower than a detection limit and are at a noise level even if detected.

Similarly, a concentration of the fifth element of the second high concentration region 32 in the first well region 28 is lower than the concentration of the fifth element in the second high concentration region 32. The first well region 28 does not include the fifth element of the second high concentration region 32. The phrase “the first well region 28 does not contain the fifth element” means that a concentration of the fifth element in the inner portion of the first well region 28 is lower than a detection limit and is at a noise level even if detected.

That is, the first well region 28 may include a background concentration of the second semiconductor layer 7 (that is, a concentration of the first element, nitrogen concentration in this embodiment), but preferably does not include a concentration of a pentavalent element other than the background concentration of the second semiconductor layer 7.

Similarly, a concentration of the fifth element of the second high concentration region 32 in the second well region 29 is lower than the concentration of the fifth element in the second high concentration region 32. The second well region 29 does not contain the fifth element of the second high concentration region 32. The phrase “the second well region 29 does not contain the fifth element” means that the concentration of the fifth element in the inner portion of the second well region 29 is lower than a detection limit and is at a noise level even if detected.

That is, the second well region 29 may include a background concentration of the second semiconductor layer 7 (that is, a concentration of the first element, nitrogen concentration in this embodiment), but preferably does not include a concentration of a pentavalent element other than the background concentration of the second semiconductor layer 7.

The second high concentration region 32 has a concentration gradient different from the concentration gradient of the first high concentration region 31. The second high concentration region 32 is consisting of a channeling region in which a large amount of additional pentavalent elements are dispersed along the axis channel of the SiC monocrystal (the second semiconductor layer 7) in addition to the pentavalent element of the second semiconductor layer 7, and has a concentration gradient that decreases (monotonically decreases in this embodiment) downward from the first high concentration region 31. That is, in this embodiment, the second high concentration region 32 extends along a c-axis of the SiC monocrystal and is inclined at the above-described off direction and off angle.

The concentration gradient of the second high concentration region 32 includes a gently sloping portion 32A and a decreasing portion 32B downward from the bottom portion (lower end portion) of the first high concentration region 31. The gently sloping portion 32A has a concentration decrease rate smaller than a concentration decrease rate of the decreasing portion 31C of the first high concentration region 31 and is a portion that maintains a fixed n-type impurity concentration over a fixed depth range. The bottom portion (lower end portion) of the first high concentration region 31 and an upper end portion of the second high concentration region 32 are formed by a concentration transition portion between the decreasing portion 31C of the first high concentration region 31 and the gently sloping portion 32A of the second high concentration region 32.

The n-type impurity concentration of the gently sloping portion 32A gradually decreases gently in a concentration range lower than the n-type impurity concentration of the decreasing portion 31C of the first high concentration region 31. That is, the gently sloping portion 32A (the second high concentration region 32) does not have a concentration gradient that steeply increases with the first high concentration region 31 (decreasing portion 31C) as a starting point.

The gently sloping portion 32A may have a concentration decrease rate of not more than 50% over a depth range of at least 0.25 μm. The gently sloping portion 32A may have a concentration decrease rate of not more than 50% over a depth range of at least 0.5 μm. The gently sloping portion 32A may have a concentration decrease rate of not more than 50% over a thickness range of 25% of the well region 25.

The decreasing portion 32B is a portion forming the bottom portion of the high concentration region 30. The decreasing portion 32B has a concentration decrease rate greater than a concentration decrease rate of the gently sloping portion 32A and is a portion in which the n-type impurity concentration steeply decreases from the gently sloping portion 32A toward the bottom portion. The n-type impurity concentration of the decreasing portion 32B monotonically decreases toward the bottom portion. The concentration decrease rate per unit depth of the decreasing portion 32B is greater than a concentration decrease rate per unit depth of the gently sloping portion 32A.

The second high concentration region 32 has a depth greater than a depth of the first high concentration region 31. The depth of the second high concentration region 32 may be smaller than a depth of the second well region 29 or may be greater than a depth of the second well region 29.

On a basis of the bottom portion (lower end portion) of the first high concentration region 31, the depth of the second high concentration region 32 may be not less than 0.5 μm and not more than 5 μm. The depth of the second high concentration region 32 may have a value belonging to at least one range among not less than 0.5 μm and not more than 1 μm, not less than 1 μm and not more than 1.5 μm, not less than 1.5 μm and not more than 2 μm, not less than 2 μm and not more than 2.5 μm, not less than 2. 5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The semiconductor device 1A includes a plurality of source regions 35 of the n-type formed in the body region 10 in the active region 8. The source region 35 has an n-type impurity concentration higher than the p-type impurity concentration of the body region 10, and replaces the conductivity type of the body region 10 from the p-type to the n-type.

The n-type impurity concentration of the source region 35 is higher than the n-type impurity concentration of the second semiconductor layer 7. The n-type impurity concentration of the source regions 35 is higher than the n-type impurity concentration of the second high concentration region 32. The n-type impurity concentration of the source regions 35 is higher than the n-type impurity concentration of the first high concentration region 31.

The plurality of source regions 35 are respectively formed in the plurality of mesa portions 20 in a surface layer portion of the body region 10. In this embodiment, the plurality of source regions 35 are respectively formed in a multiple-to-one correspondence with the plurality of mesa portions 20.

The plurality of source regions 35 are formed at intervals in the second direction Y in the corresponding mesa portions 20 and are adjacent to the two gate structures 15 corresponding to the first direction X. In this embodiment, each of the plurality of source regions 35 extends in a band shape in the second direction Y in conformance to the extension direction of the plurality of gate structures 15 in plan view.

The plurality of source regions 35 on one side in the first direction X respectively oppose the plurality of source regions 35 on the other side in the first direction X with the one corresponding gate structure 15 interposed therebetween. That is, the plurality of source regions 35 are aligned in a single line in the first direction X in plan view. The plurality of source regions 35 are aligned in a matrix at intervals in the first direction X and the second direction Y in plan view.

The plurality of source regions 35 on one side in the first direction X may respectively oppose regions between the plurality of source regions 35 on the other side in the first direction X with the one corresponding gate structure 15 interposed therebetween. That is, the plurality of source regions 35 may be aligned in a staggered manner at intervals in the first direction X and the second direction Y in plan view.

The plurality of source regions 35 each has a thickness (depth) less than the thickness (depth) of the body region 10, and are formed at an interval toward the first main surface 3 side from the bottom portion of the body region 10. The plurality of source regions 35 oppose the second semiconductor layer 7 (the high concentration region 30) with a portion (bottom portion) of the body region 10 interposed therebetween.

The plurality of source regions 35 each has a bottom portion positioned on the bottom portion side of the body region 10 with respect to a height position of the electrode surface of the plurality of embedded electrodes 18. Specifically, the plurality of source regions 35 each has a portion positioned on the bottom wall side of the plurality of trenches 16 with respect to the electrode surfaces of the plurality of embedded electrodes 18, and a portion positioned on the first main surface 3 side with respect to the electrode surfaces of the plurality of embedded electrodes 18.

The plurality of source regions 35 each has a portion opposing the corresponding embedded electrode 18 with the corresponding insulating film 17 interposed therebetween, and a portion opposing the embedded insulator 19 with the corresponding insulating film 17 interposed therebetween. The plurality of source regions 35 each has a portion positioned on the bottom wall side of the plurality of trenches 16 with respect to the insulating surfaces of the plurality of embedded insulators 19, and a portion positioned on the first main surface 3 side with respect to the insulating surfaces of the plurality of embedded insulators 19. In this embodiment, the plurality of source regions 35 each has a portion exposed from the opening end of the corresponding trench 16.

The source region 35 has a thickness (depth) greater than the thickness between the bottom portion of the body region 10 and the bottom portion of the source region 35. The thickness of the source region 35 may be less than the thickness between the bottom portion of the body region 10 and the bottom portion of the source region 35. The thickness (depth) of the peripheral edge portion of the plurality of source regions 35 gradually decreases from the bottom portion side of the body region 10 toward the first main surface 3 side along the second direction Y. The plurality of source regions 35 together with the second semiconductor layer 7 (the high concentration region 30) demarcate, on the bottom portion side of the body region 10, the channel CH serving as a current path (refer to FIG. 10).

The channel CH may have a channel length of greater than 0 nm and not more than 300 nm. The channel length is the distance between the bottom portion of the body region 10 and the bottom portion of the source region 35. The channel length may have a value belonging to at least one of ranges of greater than 0 nm and not more than 50 nm, not less than 50 nm and not more than 100 nm, not less than 100 nm and not more than 150 nm, not less than 150 nm and not more than 200 nm, not less than 200 nm and not more than 250 nm, and not less than 250 nm and not more than 300 nm.

The semiconductor device 1A includes a plurality of body high concentration regions 36 of the p-type partially formed in the body region 10 in the active region 8. The body high concentration region 36 has a p-type impurity concentration higher than a p-type impurity concentration of the body region 10. The body high concentration regions 36 may be regarded as high concentration portions of the body region 10.

The p-type impurity (trivalent element) of the body high concentration regions 36 may be of the same type as the p-type impurity (trivalent element) of the body region 10 or may be different from the p-type impurity (trivalent element) of the body region 10. The p-type impurity (trivalent element) of the body high concentration region 36 may be either or both of boron and aluminum.

The p-type impurity concentration of the body high concentration regions 36 is higher than the n-type impurity concentration of the second semiconductor layer 7. The p-type impurity concentration of the body high concentration regions 36 is lower than the n-type impurity concentration of the source region 35. The p-type impurity concentration of the body high concentration regions 36 is lower than the p-type impurity concentration of the first well region 28. The p-type impurity concentration of the body high concentration regions 36 may be higher than the p-type impurity concentration of the second well region 29 or may be lower than the p-type impurity concentration of the second well region 29.

The p-type impurity concentration of the body high concentration regions 36 may be higher than the n-type impurity concentration of the first high concentration region 31 or may be lower than the n-type impurity concentration of the first high concentration region 31. The p-type impurity concentration of the body high concentration regions 36 may be higher than the n-type impurity concentration of the second high concentration region 32 or may be lower than the n-type impurity concentration of the second high concentration region 32.

In this embodiment, the plurality of body high concentration regions 36 are respectively formed in a one-to-one correspondence with the plurality of mesa portions 20. The plurality of body high concentration regions 36 each extend in a band shape in the second direction Y in the corresponding mesa portions 20 in conformance to the extension direction of the plurality of gate structures 15.

The plurality of body high concentration regions 36 are respectively formed at the bottom portions of the body region 10 in the plurality of mesa portions 20. Specifically, the plurality of body high concentration regions 36 are respectively formed in a thickness range between the bottom portions of the plurality of source regions 35 and the bottom portions of the body region 10.

In this embodiment, the plurality of body high concentration regions 36 are formed at an interval toward the bottom portion side of the body region 10 from the bottom portions of the plurality of source regions 35, and oppose the plurality of source regions 35 with a portion of the body region 10 interposed therebetween in a thickness direction. That is, the plurality of body high concentration regions 36 are not directly connected to the plurality of source regions 35. The plurality of body high concentration regions 36 may be connected to the plurality of source regions 35.

Bottom portions of the plurality of body high concentration regions 36 may be positioned further to the first main surface 3 side than the bottom portion of the body region 10, and may oppose the second semiconductor layer 7 (the high concentration region 30) with a portion of the body region 10 interposed therebetween. The bottom portions of the plurality of body high concentration regions 36 may be positioned on the bottom wall side of the gate structure 15 with respect to the bottom portion of the body region 10, and may be electrically connected to the second semiconductor layer 7 (the high concentration region 30). In this case, the bottom portions of the plurality of body high concentration regions 36 may be regarded as forming a portion of the bottom portion of the body region 10.

The plurality of body high concentration regions 36 are positioned on a bottom portion side of the body region 10 with respect to depth positions of the plurality of embedded insulators 19. In this embodiment, the plurality of body high concentration regions 36 are formed at an interval toward the bottom wall side of the plurality of gate structures 15 (the trenches 16) from depth positions of electrode surfaces of the plurality of embedded electrodes 18, and do not oppose the plurality of embedded insulators 19 in the horizontal direction. As a matter of course, the plurality of body high concentration regions 36 may be positioned on the first main surface 3 side with respect to the depth positions of electrode surfaces of the plurality of embedded electrodes 18 and may include portions opposing the plurality of embedded insulators 19 in the horizontal direction.

The plurality of body high concentration regions 36 may be positioned on a bottom wall side of the plurality of gate structures 15 with respect to depth positions of intermediate portions of the plurality of gate structures 15. The plurality of body high concentration regions 36 may have a portions positioned on the first main surface 3 side with respect to the depth positions of intermediate portions of the plurality of gate structures 15.

The plurality of body high concentration regions 36 are formed at intervals from the plurality of gate structures 15 in the horizontal direction, and oppose the plurality of gate structures 15 in the horizontal direction with a portion of the body region 10 interposed therebetween. That is, the plurality of body high concentration regions 36 demarcate a plurality of channels CH extending along the side walls of the plurality of gate structures 15 between the plurality of body high concentration regions 36 and the side walls of the plurality of gate structures 15 (see FIG. 10). As a matter of course, the body high concentration regions 36 may be connected to one or both of the adjacent gate structures 15 and may form one or both of the channels CH.

The plurality of body high concentration regions 36 each has a thickness (depth) less than a thickness (depth) of the plurality of source regions 35. In this embodiment, a depth of the body high concentration regions 36 is less than the channel length.

The ratio of a thickness of the body high concentration regions 36 to a thickness of the body region 10 may be greater than 0 and not more than 0.5. The thickness ratio may have a value belonging to at least one range among greater than 0 and not more than 0.1, not less than 0.1 and not more than 0.2, not less than 0.2 and not more than 0.3, not less than 0.3 and not more than 0.4, and not less than 0.4 and not more than 0.5.

A depth of the body high concentration regions 36 may be greater than 0 nm and not more than 300 nm. The depth of the body high concentration region 36 may have a value belonging to at least one of ranges of greater than 0 nm and not more than 50 nm, not less than 50 nm and not more than 100 nm, not less than 100 nm and not more than 150 nm, not less than 150 nm and not more than 200 nm, not less than 200 nm and not more than 250 nm, and not less than 250 nm and not more than 300 nm.

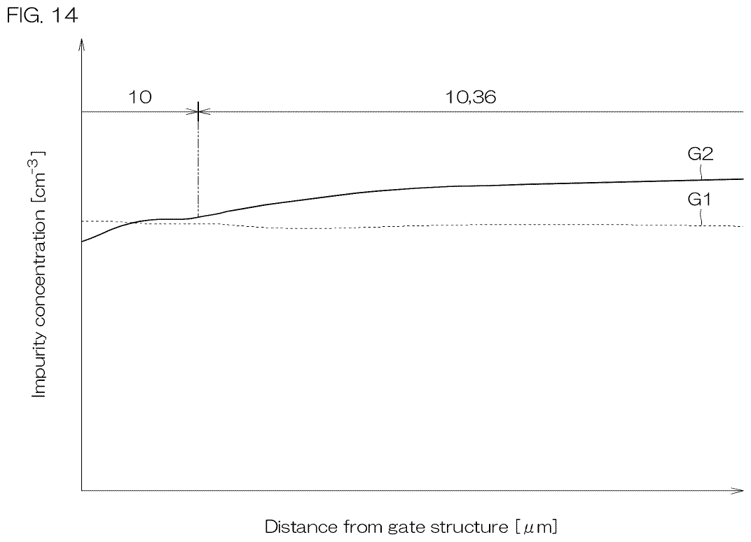

FIG. 14 is a graph illustrating an impurity concentration of the body region 10. In FIG. 14, the ordinate indicates a p-type impurity concentration, and the abscissa indicates a distance in the horizontal direction from the side wall of the gate structure 15 to an intermediate position of the mesa portion 20. In FIG. 14, the side wall of the gate structure 15 is set as a zero point.

In FIG. 14, a first concentration gradient G1 (see broken line) and a second concentration gradient G2 (see solid line) are illustrated. The first concentration gradient G1 is the concentration gradient of the p-type impurity concentration (the body region 10) when the body high concentration region 36 is not present. The second concentration gradient G2 is a concentration gradient of the p-type impurity concentration (the body region 10) when the body high concentration region 36 is present.

With reference to the first concentration gradient G1, the p-type impurity concentration has a substantially uniform concentration gradient in the horizontal direction with the side wall of the gate structure 15 as a starting point. On the other hand, with reference to the second concentration gradient G2, the p-type impurity concentration has a concentration gradient that increases (specifically, monotonically increases) in the horizontal direction with the side wall of the gate structure 15 as a starting point.

In regard to the horizontal direction, the second concentration gradient G2 has an end portion forming the minimum value and a central portion forming the maximum value. The minimum value of the second concentration gradient G2 is formed by the p-type impurity concentration of the body region 10, and the maximum value of the second concentration gradient G2 is formed by the p-type impurity concentration of the body high concentration regions 36.

The minimum value of the p-type impurity concentration is formed by a portion (the end portion) of the body region 10 that is in contact with a side wall of the gate structure 15. That is, the minimum value of the p-type impurity concentration is formed by the body region 10 alone. The maximum value of the p-type impurity concentration is a region including the body region 10 and the body high concentration regions 36, and is positioned at a central portion of the mesa portion 20.

A concentration ratio of the maximum value of the p-type impurity concentration to the minimum value of the p-type impurity concentration is greater than 1 and not more than 10. The concentration ratio may have a value belonging to at least one of ranges of greater than 1 and not more than 2, not less than 2 and not more than 3, not less than 3 and not more than 4, not less than 4 and not more than 5, not less than 5 and not more than 6, not less than 6 and not more than 7, not less than 7 and not more than 8, not less than 8 and not more than 9, and not less than 9 and not more than 10. The concentration ratio is preferably not more than 5.

The semiconductor device 1A includes a plurality of contact regions 37 formed in the chip 2 (the second semiconductor layer 7) in the active region 8. The source potential is to be applied to the contact region 37. The contact region 37 has a p-type impurity concentration higher than the n-type impurity concentration of the second semiconductor layer 7. The p-type impurity concentration of the contact region 37 is higher than the p-type impurity concentration of the body region 10. The p-type impurity concentration of the contact regions 37 is higher than a p-type impurity concentration of the body high concentration regions 36.

The p-type impurity concentration of the contact region 37 is higher than the p-type impurity concentration of the second well region 29. The p-type impurity concentration of the contact regions 37 may be higher than a p-type impurity concentration of the first well region 28 or may be lower than the p-type impurity concentration of the first well region 28. The p-type impurity concentration of the contact regions 37 may be higher than an n-type impurity concentration of the source region 35 or may be lower than the n-type impurity concentration of the source region 35.

The plurality of contact regions 37 are respectively formed in regions along the plurality of gate structures 15. The plurality of contact regions 37 are formed in a multiple-to-one correspondence with the plurality of gate structures 15. The plurality of contact regions 37 are formed at intervals in the second direction Y in conformance to the extension direction of the corresponding gate structure 15.

Specifically, each of the plurality of contact regions 37 is interposed in a region between the plurality of source regions 35. The plurality of contact regions 37 may be connected to the plurality of source regions 35 in the second direction Y. The plurality of contact regions 37 may be formed at intervals in the second direction Y from the plurality of source regions 35. In this case, the plurality of contact regions 37 may oppose the plurality of source regions 35 with a portion of body region 10 interposed therebetween.

In regard to the one and the other gate structures 15, the plurality of contact regions 37 along the one gate structure 15 oppose the plurality of contact regions 37 along the other gate structure 15 in the first direction X in plan view. That is, the plurality of contact regions 37 are aligned, as a whole, in a matrix at intervals in the first direction X and the second direction Y in plan view.

One of the plurality of contact regions 37 may oppose a region between the other of the plurality of contact regions 37 in the first direction X in plan view. That is, the plurality of contact regions 37 may be aligned, as a whole, in a staggered manner at intervals in the first direction X and the second direction Y in plan view.

The plurality of contact regions 37 may extend in a band shape in the second direction Y in conformance to the extension direction of the plurality of gate structures 15 in plan view. Lengths of the plurality of contact regions 37 in the second direction Y may be equal to each other or may be different from each other. The lengths of the plurality of contact regions 37 in the second direction Y are adjusted in accordance with a channel area to be formed.

The channel area is a total area of the portion exposed from the region between the plurality of gate structures 15 in the plurality of source regions 35. That is, the channel area decreases and increases in accordance with the increase/decrease of the ratio of a total planar area of the plurality of contact regions 37. The total planar area of the plurality of contact regions 37 is preferably less than the channel area.

That is, in the region between the plurality of gate structures 15, the total planar area of the plurality of contact regions 37 is preferably less than the planar area of the plurality of source regions 35. According to such a configuration, an increase in a resistance value (on-resistance) caused by a short channel is suppressed.

The length of the contact region 37 may be greater than the width of the gate structure 15, or may be smaller than the width of the gate structure 15. The length of the contact region 37 may be greater than the pitch of the plurality of gate structures 15 or may be smaller than the pitch of the plurality of gate structures 15.

The interval between the plurality of contact regions 37 may be greater than the width of the gate structure 15, or may be smaller than the width of the gate structure 15. The interval between the contact regions 37 may be greater than the pitch of the plurality of gate structures 15 or may be smaller than the pitch of the plurality of gate structures 15.

The plurality of contact regions 37 each has a first region 37A, a second region 37B, and a third region 37C. The first region 37A is a portion extending along the bottom wall of the corresponding gate structure 15. The first region 37A is interposed in the regions between the bottom portions of the corresponding gate structure 15 and the corresponding well region 25, and is connected to the bottom wall of the corresponding gate structure 15 and the corresponding well region 25.

The first region 37A has a thickness greater than the thickness of the first well region 28, and has a bottom portion positioned on the bottom portion side of the second well region 29 with respect to a depth position of the lower end portion (the bottom portion) of the first well region 28. The thickness of the first region 37A is the thickness of the first region 37A in the vertical direction Z on a basis of the bottom wall of the gate structure 15.

The bottom portion of the first region 37A is formed at an interval toward the bottom wall side of the gate structure 15 from the bottom portion of the second well region 29, and opposes the second semiconductor layer 7 with a portion of the second well region 29 interposed therebetween. The bottom portion of the first region 37A may be positioned on the bottom wall side of the gate structure 15 with respect to a depth position of an intermediate portion of the second well region 29. The bottom portion of the first region 37A may be positioned on the bottom portion side of the second well region 29 with respect to the depth position of the intermediate portion of the second well region 29.

The first region 37A is connected to the first well region 28 and the second well region 29, and increases the p-type impurity concentration of the first well region 28 and the p-type impurity concentration of the second well region 29. The first region 37A may have a thickness less than the thickness of the first well region 28, and may be formed at an interval toward the bottom wall side of the gate structure 15 from a depth position of the lower end portion of the first well region 28. In this case, the first region 37A may oppose the second well region 29 with a portion of the first well region 28 interposed therebetween.

The first region 37A has a width greater than the width of the gate structure 15, and protrudes in the horizontal direction from a region directly below the corresponding gate structure 15 to both sides of the corresponding gate structure 15. Specifically, the first region 37A protrudes in an arc shape (circular arc shape) in the horizontal direction with respect to the side wall of the corresponding gate structure 15, and opposes the body region 10 in the thickness direction. The first region 37A may oppose the body high concentration region 36 in the thickness direction.

A curvature of the first region 37A may be greater than the curvature of the first bulging region 26A or may be smaller than the curvature of the first bulging region 26A. The curvature of the first region 37A may be greater than a curvature of the second bulging region 26B or may be smaller than the curvature of the second bulging region 26B.

A protrusion amount of the first region 37A on a basis of the side wall of the gate structure 15 may be greater than the protrusion amount of the first bulging region 26A or may be smaller than the protrusion amount of the first bulging region 26A. The protrusion amount of the first region 37A may be greater than a protrusion amount of the second bulging region 26B or may be smaller than the protrusion amount of the second bulging region 26B.

The second region 37B is a portion extending along the side wall of the gate structure 15. The second region 37B is connected to the first region 37A on the bottom wall side of the gate structure 15, and is connected to the body region 10 on the first main surface 3 side. That is, the second region 37B electrically connects the corresponding well region 25 to the body region 10. Thereby, the well region 25 is suppressed from becoming an electrically floating state, and the electrical response characteristics of the well region 25 are improved.

The second region 37B may be connected to the body high concentration region 36 in the body region 10. The second region 37B may be formed at an interval from the body high concentration region 36. The second region 37B has a thickness less than the thickness of the first region 37A. The thickness of the second region 37B is the thickness of the second region 37B in the horizontal direction on a basis of the side wall of the gate structure 15.

The third region 37C is a portion extending in a layer shape along the first main surface 3 in the surface layer portion of the first main surface 3 and exposed from the first main surface 3. That is, the third region 37C forms an upper end portion of the contact region 37. In this embodiment, the upper end portion of the third region 37C is exposed from the side wall of the trench 16 at the opening end of the trench 16.

The third region 37C is integrally formed with the third region 37C of the adjacent contact region 37. That is, the plurality of contact regions 37 are electrically connected to each other via the plurality of third regions 37C.

The third region 37C has a thickness (depth) less than a thickness (depth) of the body region 10, and opposes the body high concentration region 36 with a portion (the bottom portion) of the body region 10 interposed therebetween. The thickness of the third region 37C is the thickness of the third region 37C in the vertical direction Z on a basis of the first main surface 3. The third region 37C opposes the second semiconductor layer 7 (the high concentration region 30) in the thickness direction.

The third region 37C has a bottom portion positioned on the bottom portion side of the body region 10 with respect to the height position of the electrode surfaces of the plurality of embedded electrodes 18. Specifically, the third region 37C has a portion positioned on the bottom wall side of the plurality of trenches 16 with respect to the electrode surfaces of the plurality of embedded electrodes 18, and a portion positioned on the first main surface 3 side with respect to the electrode surfaces of the plurality of embedded electrodes 18.

The third regions 37C each has a portion opposing the corresponding embedded electrode 18 with the corresponding insulating film 17 interposed therebetween, and a portion opposing the embedded insulator 19 with the corresponding insulating film 17 interposed therebetween. The third regions 37C each has a portion positioned on the bottom wall side of the plurality of trenches 16 with respect to the insulating surfaces of the plurality of embedded insulators 19, and a portion positioned on the first main surface 3 side with respect to the insulating surfaces of the plurality of embedded insulators 19. In this embodiment, the third regions 37C each has a portion exposed from the opening end of the corresponding trench 16.

The thickness of the third region 37C is greater than the thickness of the second region 37B. The thickness of the third region 37C may be substantially equal to the thickness of the first region 37A. The thickness of the third region 37C may be greater than the thickness of the first region 37A or may be smaller than the thickness of the first region 37A. The thickness of the third region 37C is less than a thickness (depth) of the source region 35. Accordingly, the third region 37C has a bottom portion positioned on the first main surface 3 side with respect to a bottom portion of the source region 35.

The thickness of the third region 37C may be greater than the thickness of the source region 35. The thickness of third region 37C is less than the thickness between the bottom portion of the body region 10 and the bottom portion of the third region 37C. The thickness of third region 37C may be less than the thickness between the bottom portion of the body region 10 and the bottom portion of the third region 37C.

The semiconductor device 1A includes an outer well region 40 of the p-type that is formed in the surface layer portion of the first main surface 3 in the outer peripheral region 9 (a peripheral edge portion of the first main surface 3). The source potential is to be applied to the outer well region 40. The outer well region 40 has a p-type impurity concentration higher than the n-type impurity concentration of the second semiconductor layer 7. The p-type impurity concentration of the outer well region 40 may be higher than the p-type impurity concentration of the body region 10, or may be lower than the p-type impurity concentration of the body region 10.

The p-type impurity concentration of the outer well region 40 is lower than the p-type impurity concentration of the contact region 37. The p-type impurity concentration of the outer well region 40 is lower than the p-type impurity concentration of the first well region 28. The p-type impurity concentration of the outer well region 40 may be higher than a p-type impurity concentration of the second well region 29 or may be lower than the p-type impurity concentration of the second well region 29.

The outer well region 40 is formed in a surface layer portion of the second semiconductor layer 7 and extends in a layer shape along the first main surface 3. The outer well region 40 is formed at an interval toward an inner side of the first main surface 3 (the active region 8 side) from a peripheral edge (the first to fourth side surfaces 5A to 5D) of the first main surface 3. The outer well region 40 extends in a band shape along the peripheral edge of the first main surface 3 (the peripheral edge of the active region 8) in plan view.

In this embodiment, the outer well region 40 is formed in a polygonal annular shape (a quadrilateral annular shape in this embodiment) having four sides parallel to the peripheral edge of the chip 2 in plan view, and surrounds the inner portion (the active region 8) of the first main surface 3. That is, the outer well region 40 collectively surrounds the plurality of gate structures 15. The outer well region 40 may have an edge portion connecting, in an arcuate shape (preferably, a quarter arcuate shape), a portion extending in the first direction X and a portion extending in the second direction Y.

The outer well region 40 has an inner edge portion on the inner side of the first main surface 3 (the active region 8 side) and an outer edge portion on the peripheral edge side of the first main surface 3. The inner edge portion of the outer well region 40 demarcates a boundary portion between the active region 8 and the outer peripheral region 9. The inner edge portion of the outer well region 40 is connected to the end portions of the plurality of gate structures 15 in a portion extending in the first direction X.

The inner edge portion of the outer well region 40 may be positioned further to an inner portion side of the plurality of gate structures 15 than the end portions of the plurality of gate structures 15. The inner edge portion of the outer well region 40 may have a portion positioned in a region between the plurality of gate structures 15 and be connected to the body region 10. The outer edge portion of the outer well region 40 is formed at an interval inward from the peripheral edge of the chip 2 and extends substantially parallel to the inner edge portion of the outer well region 40.

The outer well region 40 may have a width of greater than 0 μm and not more than 300 μm. The width of the outer well region 40 may have a value belonging to at least one range among greater than 0 μm and not more than 25 μm, not less than 25 μm and not more than 50 μm, not less than 50 μm and not more than 75 μm, not less than 75 μm and not more than 100 μm, not less than 100 μm and not more than 125 μm, not less than 125 μm and not more than 150 μm, not less than 150 μm and not more than 175 μm, not less than 175 μm and not more than 200 μm, not less than 200 μm and not more than 225 μm, not less than 225 μm and not more than 250 μm, not less than 250 μm and not more than 275 μm, and not less than 275 μm and not more than 300 μm.

The outer well region 40 is formed at an interval toward the first main surface 3 side from the bottom portion of the second semiconductor layer 7, and opposes the first semiconductor layer 6 with a portion of the second semiconductor layer 7 interposed therebetween. The outer well region 40 may be formed at an interval toward the first main surface 3 side from the depth position of the intermediate portion of the second semiconductor layer 7, or may be positioned on the bottom portion side of the second semiconductor layer 7 (the second main surface 4 side) with respect to the depth position of the intermediate portion of the second semiconductor layer 7.

In this embodiment, the outer well region 40 is formed at an interval toward the first main surface 3 side from the depth positions of the bottom walls of the plurality of gate structures 15. The outer well region 40 may be formed deeper than the body region 10 or may be formed shallower than the body region 10.

The outer well region 40 may have a portion positioned on the bottom portion side of the second semiconductor layer 7 with respect to the depth positions of the bottom walls of the plurality of gate structures 15. In this case, the outer well region 40 may be connected to one or both of the first well region 28 and the second well region 29.

The outer well region 40 forms a pn-junction portion with the second semiconductor layer 7. The outer well region 40 spreads a depletion layer in the second semiconductor layer 7 when a reverse bias voltage is applied. The depletion layer of the outer well region 40 spreads in the horizontal direction and the thickness direction, and is integrated with the depletion layer spreading from the body region 10 and the well region 25. The outer well region 40 expands the depletion layer spreading from the body region 10 and the well region 25 toward the peripheral edge side of the first main surface 3, and relaxes the electric field strength (concentration of electric field) in the peripheral edge portion (the outer peripheral region 9) of the first main surface 3.

The semiconductor device 1A includes a main surface insulating film 41 selectively covering the first main surface 3. The main surface insulating film 41 may include at least one among a silicon oxide film, a silicon nitride film, and a silicon oxynitride film. The main surface insulating film 41 preferably includes the same type of insulating material as the insulating material of the insulating film 17. In this embodiment, the main surface insulating film 41 has a single layer structure consisting of the silicon oxide film. The main surface insulating film 41 preferably includes the silicon oxide film consisting of the oxide of the chip 2.

The main surface insulating film 41 covers the first main surface 3 in a film shape in the outer peripheral region 9. Specifically, the main surface insulating film 41 covers the outer well region 40 in the outer peripheral region 9. The main surface insulating film 41 is led out from the outer peripheral region 9 toward the active region 8, is selectively connected to the insulating films 17 of the plurality of gate structures 15 in a peripheral edge portion of the active region 8, and exposes the embedded electrodes 18 of the plurality of gate structures 15.

In this embodiment, the main surface insulating film 41 is continuous to the first to fourth side surfaces 5A to 5D in the peripheral edge of the first main surface 3. The main surface insulating film 41 may be formed at an interval inward from the first to fourth side surfaces 5A to 5D, and may expose the peripheral edge portion of the first main surface 3.

The semiconductor device 1A includes one or a plurality (a plurality in this embodiment) of gate wirings 42 arranged on the first main surface 3 in the outer peripheral region 9. The plurality of gate wirings 42 apply the gate potential to the plurality of gate structures 15. The plurality of gate wirings 42 may contain either or both of a conductive polysilicon of the p-type and a conductive polysilicon of the n-type. The plurality of gate wirings 42 preferably have the same conductivity type as the conductivity type of the embedded electrodes 18 of the plurality of gate structures 15.

The plurality of gate wirings 42 are arranged on the main surface insulating film 41. The plurality of gate wirings 42 are selectively routed on the main surface insulating film 41 at an interval toward the active region 8 side from the peripheral edge of the first main surface 3, and oppose the outer well region 40 with the main surface insulating film 41 interposed therebetween.

The plurality of gate wirings 42 include the gate wiring 42 on one side in the second direction Y and the gate wiring 42 on the other side in the second direction Y. The one gate wiring 42 is formed in a band shape with ends extending in the first direction X so as to intersect (specifically, orthogonally) one end portions of the plurality of gate structures 15. The other gate wiring 42 is formed in a band shape with ends extending in the first direction X so as to intersect (specifically, orthogonally) other end portions of the plurality of gate structures 15.

The plurality of gate wirings 42 each has an inner edge portion on the inner side of the first main surface 3 (the active region 8 side) and an outer edge portion on a peripheral edge side of the first main surface 3. The inner edge portion of the plurality of gate wirings 42 covers one end portions or other end portions of the plurality of gate structures 15, and is mechanically and electrically connected to the plurality of gate structures 15. Specifically, the plurality of gate wirings 42 are mechanically and electrically connected to the plurality of embedded electrodes 18. In this embodiment, the plurality of gate wirings 42 are integrally formed with the plurality of embedded electrodes 18 as lead-out portions of the plurality of embedded electrodes 18.

In this embodiment, the outer edge portions of the plurality of gate wirings 42 are formed at an interval toward the active region 8 side from outer edge portions of the outer well region 40. The plurality of gate wirings 42 may have a portion led out further to the peripheral edge side of the first main surface 3 side than the outer edge portion of the outer well region 40 and opposing the second semiconductor layer 7 with the main surface insulating film 41 interposed therebetween.

The semiconductor device 1A may include the single gate wiring 42. In this case, the gate wiring 42 may have a portion extending in a band shape in the first direction X and a portion extending in a band shape in the second direction Y in plan view. For example, the gate wiring 42 may have a portion extending along the first side surface 5A, a portion extending along the second side surface 5B, and a portion extending along the third side surface 5C, and may intersect (specifically, orthogonally) both one end portion and another end portion of the plurality of gate structures 15.

In this case, the gate wiring 42 may have a portion extending along the fourth side surface 5D. Also, the gate wiring 42 may be mechanically and electrically connected to either one or both of the plurality of gate structures 15 (the embedded electrodes 18) arranged on both sides in the first direction X in a portion extending in the second direction Y.

The gate wiring 42 may be formed in a band shape with ends having four sides parallel to a peripheral edge of the first main surface 3, and may surround the plurality of gate structures 15 (the active region 8). The gate wiring 42 may be formed in an endless polygonal annular shape (for example, a quadrilateral annular shape) having four sides parallel to the peripheral edge of the first main surface 3 in plan view. The gate wiring 42 may have an edge portion connecting, in an arcuate shape (preferably, a quarter arcuate shape), a portion extending in the first direction X and a portion extending in the second direction Y in plan view.

The semiconductor device 1A includes an interlayer film 43 with an insulating property covering the main surface insulating film 41. The interlayer film 43 may be referred to as an “insulating film,” an “interlayer insulating film,” an “intermediate insulating film,” etc. The interlayer film 43 may include at least one among a silicon oxide film, a silicon nitride film, and a silicon oxynitride film. The interlayer film 43 preferably includes a silicon oxide film.

The interlayer film 43 may include an insulating material different from an insulating material of the main surface insulating film 41, or may include the same type of insulating material as the insulating material of the main surface insulating film 41. In this embodiment, the interlayer film 43 includes a silicon oxide film having properties different from those of the main surface insulating film 41. The interlayer film 43 may have a single layer structure or a laminated structure including at least one of an NSG film, a PSG film, and a BPSG film.

The interlayer film 43 preferably has a single layer structure or a laminated structure including at least an NSG film. The interlayer film 43 may have a laminated structure including the NSG film and the PSG film laminated in that order from the chip 2 side. The interlayer film 43 may have a laminated structure including the NSG film, the PSG film, and the BPSG film laminated in that order from the chip 2 side.

The interlayer film 43 covers the first main surface 3 in a film shape with the main surface insulating film 41 interposed therebetween. The interlayer film 43 covers the outer well region 40 with the main surface insulating film 41 interposed therebetween in the outer peripheral region 9. In this embodiment, the interlayer film 43 is continuous to the first to fourth side surfaces 5A to 5D in the peripheral edge of the first main surface 3. The interlayer film 43 may be formed at an interval inward from the first to fourth side surfaces 5A to 5D, and may expose the peripheral edge portion of the first main surface 3.

The interlayer film 43 covers the gate wiring 42 in the outer peripheral region 9. The interlayer film 43 is led out from the outer peripheral region 9 to the active region 8 and covers the both end portions of the plurality of gate structures 15 at a peripheral edge portion of the active region 8. Specifically, the interlayer film 43 covers the plurality of embedded electrodes 18 at the both end portions of the plurality of gate structures 15 and is connected to the plurality of embedded insulators 19.

The interlayer film 43 may have a thickness of not less than 0.5 μm and not more than 3 μm. The thickness of the interlayer film 43 may have a value belonging to at least one range among not less than 0.5 μm and not more than 1 μm, not less than 1 μm and not more than 1.5 μm, not less than 1.5 μm and not more than 2 μm, not less than 2 μm and not more than 2.5 μm, and not less than 2.5 μm and not more than 3 μm.

The semiconductor device 1A includes one or a plurality (one in this embodiment) of source openings 44 formed in the interlayer film 43. The source opening 44 collectively exposes the plurality of gate structures 15 and the plurality of mesa portions 20 in an inner portion of the active region 8.

The source openings 44 are formed at an interval toward the inner portion of the first main surface 3 from the both end portions of the plurality of gate structures 15, and exposes the inner portions of the plurality of gate structures 15 and inner portions of the plurality of mesa portions 20. In this embodiment, the source opening 44 is formed in a polygonal shape (a quadrangular shape in this embodiment) having four sides parallel to the peripheral edge of the first main surface 3 in plan view.

The semiconductor device 1A includes a source electrode 45 arranged on the first main surface 3. The source electrode 45 may be referred to as a “first main surface electrode,” a “first terminal (electrode),” a “first pad (electrode),” a “source pad (electrode), etc.” The source electrode 45 is arranged on the interlayer film 43.

In this embodiment, the source electrode 45 has a first pad portion 45a, a second pad portion 45b, and a third pad portion 45c. The first pad portion 45a has a relatively large planar area and forms a main body of the source electrode 45. In this embodiment, the first pad portion 45a is formed in a polygonal shape (a quadrangular shape in this embodiment) having four sides parallel to the peripheral edge of the chip 2 in plan view, and is shifted to the fourth side surface 5D side with respect to the central portion of the first main surface 3.

The second pad portion 45b has a planar area less than the planar area of the first pad portion 45a, and is led out in a band shape (quadrangular shape) from one end portion (the end portion on the first side surface 5A side) of the first pad portion 45a in the second direction Y toward the third side surface 5C. The third pad portion 45c has a planar area less than the planar area of the first pad portion 45a, is led out in a band shape (quadrangular shape) from the other end portion (the end portion on the second side surface 5B side) of the first pad portion 45a in the second direction Y toward the third side surface 5C, and opposes the second pad portion 45b in the second direction Y.

The planar area of the third pad portion 45c may be substantially equal to the planar area of the second pad portion 45b. The planar area of the third pad portion 45c may be greater than the planar area of the second pad portion 45b, or may be less than the planar area of the second pad portion 45b. Either or both of the second pad portion 45b and the third pad portion 45c may be used as a terminal portion for current monitoring.

The source electrode 45 does not necessarily have to have both the second pad portion 45b and the third pad portion 45c at the same time. The source electrode 45 may have only one of the second pad portion 45b and the third pad portion 45c. The source electrode 45 may be consisting of just the first pad portion 45a and does not have to have both the second pad portion 45b and the third pad portion 45c.

The source electrode 45 collectively covers, in a film shape, a region of the interlayer film 43 in which the source opening 44 is formed, and enters into the source opening 44 from above the interlayer film 43. The source electrode 45 has a portion covering the interlayer film 43 in a film shape, a portion covering the wall surface of the source opening 44 in a film shape, and a portion covering the first main surface 3 in a film shape in the source opening 44.

The source electrode 45 has a portion covering the plurality of gate structures 15 in the source opening 44 and a portion covering the plurality of mesa portions 20. The source electrode 45 directly covers the plurality of embedded insulators 19 in a portion covering the plurality of gate structures 15, and is electrically separated from the plurality of embedded electrodes 18 by the plurality of embedded insulators 19.

In this embodiment, the source electrode 45 enters into the plurality of trenches 16 from above the first main surface 3, and covers the plurality of embedded insulators 19 in the plurality of trenches 16. The source electrode 45 has a portion covering the insulating surfaces of the plurality of embedded insulators 19 in a region on the bottom wall side of the plurality of trenches 16 with respect to the height position of the first main surface 3.

The source electrode 45 has a portion covering the side walls and the opening ends of the plurality of trenches 16 in the plurality of trenches 16. The source electrode 45 is mechanically and electrically connected to the plurality of source regions 35 and the plurality of contact regions 37 in the portion covering the side walls and the opening ends of the plurality of trenches 16. The source electrode 45 is mechanically and electrically connected to the plurality of source regions 35 and the plurality of contact regions 37 in the portion covering the plurality of mesa portions 20.

The source electrode 45 has a peripheral edge portion opposing the end portions (both end portions) of the plurality of gate structures 15 with the interlayer film 43 interposed therebetween. The peripheral edge portion of the source electrode 45 is led out from the active region 8 to the outer peripheral region 9, and may oppose one or a plurality of gate wirings 42 with the interlayer film 43 interposed therebetween. The peripheral edge portion of the source electrode 45 may oppose the outer well region 40 with the interlayer film 43 interposed therebetween.

In this embodiment, the source electrode 45 has a laminated structure including a lower electrode film 46 and a main electrode film 47 that are laminated in that order from the chip 2 side. In this embodiment, the lower electrode film 46 has a laminated structure including a first electrode film 48 and a second electrode film 49.

In this embodiment, the first electrode film 48 includes a Ti film, and the second electrode film 49 includes a TiN film. The lower electrode film 46 is not necessarily have to have a laminated structure, and may have a single layer structure consisting of one of the first electrode film 48 (Ti film) and the second electrode film 49 (TiN film).

The first electrode film 48 has a thickness less than the thickness of the interlayer film 43. The thickness of the first electrode film 48 may be not less than 10 nm and not more than 100 nm. The thickness of the first electrode film 48 may have a value belonging to at least one range among not less than 10 nm and not more than 25 nm, not less than 25 nm and not more than 50 nm, not less than 50 nm and not more than 75 nm, and not less than 75 nm and not more than 100 nm.

The second electrode film 49 has a thickness less than the thickness of the interlayer film 43. The thickness of the second electrode film 49 is preferably greater than the thickness of the first electrode film 48. The thickness of the second electrode film 49 may be not less than 50 nm and not more than 200 nm. The thickness of the second electrode film 49 may have a value belonging to at least one range among not less than 50 nm and not more than 75 nm, not less than 75 nm and not more than 100 nm, not less than 100 nm and not more than 125 nm, not less than 125 nm and not more than 150 nm, not less than 150 nm and not more than 175 nm, and not less than 175 nm and not more than 200 nm.

The first electrode film 48 collectively covers, in a film shape, a region of the interlayer film 43 in which the source opening 44 is formed, and enters into the source opening 44 from above the interlayer film 43. The first electrode film 48 has a portion covering the insulating main surface of the interlayer film 43 in a film shape, a portion covering a wall surface of the source opening 44 in a film shape, and a portion covering the first main surface 3 in a film shape in the source opening 44.

The first electrode film 48 has a portion covering the plurality of gate structures 15 in the source opening 44 and the portion covering the plurality of mesa portions 20. The first electrode film 48 directly covers the plurality of embedded insulators 19 in a portion covering the plurality of gate structures 15, and is electrically separated from the plurality of embedded electrodes 18 by the plurality of embedded insulators 19.

In this embodiment, the first electrode film 48 enters into the plurality of trenches 16 from above the first main surface 3 and covers the plurality of embedded insulators 19 in the plurality of trenches 16. In this embodiment, the first electrode film 48 has a portion covering the insulating surfaces of the plurality of embedded insulators 19 in a region on the bottom wall side of the plurality of trenches 16 with respect to the height position of the first main surface 3.

The first electrode film 48 has a portion covering the side walls and the opening ends of the plurality of trenches 16 in the plurality of trenches 16. The first electrode film 48 is mechanically and electrically connected to the plurality of source regions 35 and the plurality of contact regions 37 in the portion covering the side walls and the opening ends of the plurality of trenches 16. The first electrode film 48 is mechanically and electrically connected to the plurality of source regions 35 and the plurality of contact regions 37 in the portion covering the plurality of mesa portions 20.

The first electrode film 48 has a peripheral edge portion opposing the end portions (both end portions) of the plurality of gate structures 15 with the interlayer film 43 interposed therebetween. The peripheral edge portion of the first electrode film 48 is led out from the active region 8 to the outer peripheral region 9, and may oppose one or a plurality of gate wirings 42 with the interlayer film 43 interposed therebetween. The peripheral edge portion of the first electrode film 48 may oppose the outer well region 40 with the interlayer film 43 interposed therebetween.

The second electrode film 49 directly covers the first electrode film 48. The second electrode film 49 collectively covers, in a film shape, a region in which the source opening 44 is formed in the interlayer film 43 with the first electrode film 48 interposed therebetween, and enters into the source opening 44 from above the interlayer film 43.

The second electrode film 49 has a portion covering the interlayer film 43 in a film shape with the first electrode film 48 interposed therebetween, a portion covering the wall surface of the source opening 44 in a film shape with the first electrode film 48 interposed therebetween, and a portion covering the first main surface 3 in a film shape with the first electrode film 48 interposed therebetween in the source opening 44. The second electrode film 49 has a portion covering the plurality of gate structures 15 with the first electrode film 48 interposed therebetween in the source opening 44, and a portion covering the plurality of mesa portions 20 with the first electrode film 48 interposed therebetween.

The second electrode film 49 covers the plurality of embedded insulators 19 with the first electrode film 48 interposed therebetween, and is electrically separated from the plurality of embedded electrodes 18. In this embodiment, the second electrode film 49 enters into the plurality of trenches 16 from above the first main surface 3, and covers the plurality of embedded insulators 19 with the first electrode film 48 interposed therebetween in the plurality of trenches 16.

In this embodiment, the second electrode film 49 covers the first electrode film 48 in a region on the bottom wall side of the plurality of trenches 16 with respect to the height position of the first main surface 3. In this embodiment, the second electrode film 49 has a portion covering the side walls and the opening ends of the plurality of trenches 16 with the first electrode film 48 interposed therebetween in the plurality of trenches 16.

The second electrode film 49 is electrically connected to the plurality of source regions 35 and the plurality of contact regions 37 via the first electrode film 48 in the portion covering the side walls and the opening ends of the plurality of trenches 16. The second electrode film 49 may be connected to the first electrode film 48 at a position higher than the first main surface 3. The second electrode film 49 is electrically connected to the plurality of source regions 35 and the plurality of contact regions 37 via the first electrode film 48 in the portion covering the plurality of mesa portions 20.

The main electrode film 47 contains a metal material different from the metal material of the lower electrode film 46 (the first electrode film 48 and the second electrode film 49). The main electrode film 47 may include at least one of an Al film, an Al alloy film, a Cu film, and a Cu alloy film. The Al alloy film (Cu alloy film) may include at least one of an AlSi alloy film, an AlCu alloy film, and an AlSiCu alloy film. The main electrode film 47 has a thickness greater than the thickness (total thickness) of the lower electrode film 46. The thickness of the main electrode film 47 is preferably greater than the thickness of the interlayer film 43.

The thickness of the main electrode film 47 may be not less than 0.5 μm and not more than 5 μm. The thickness of the main electrode film 47 may have a value belonging to at least one range among not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The main electrode film 47 directly covers the lower electrode film 46 (the second electrode film 49). The main electrode film 47 backfills the source opening 44 and collectively covers, in a film shape, the region of the interlayer film 43 in which the source opening 44 is formed. The main electrode film 47 has a portion covering the interlayer film 43 with the lower electrode film 46 interposed therebetween, a portion covering the wall surface of the source opening 44 with the lower electrode film 46 interposed therebetween, and a portion covering the first main surface 3 with the lower electrode film 46 interposed therebetween.

The main electrode film 47 has a portion covering the plurality of gate structures 15 with the lower electrode film 46 interposed therebetween in the source opening 44, and a portion covering the plurality of mesa portions 20 with the lower electrode film 46 interposed therebetween. The main electrode film 47 covers the plurality of embedded insulators 19 with the lower electrode film 46 interposed therebetween, and is electrically separated from the plurality of embedded electrodes 18.

The main electrode film 47 may enter into the plurality of trenches 16 from above the first main surface 3, and cover the plurality of embedded insulators 19 with the lower electrode film 46 interposed therebetween in the plurality of trenches 16. In this case, the main electrode film 47 may have a portion covering the side walls and the opening ends of the plurality of trenches 16 with the lower electrode film 46 interposed therebetween in a region on the bottom wall side of the plurality of trenches 16 with respect to the height position of the first main surface 3.

The main electrode film 47 is electrically connected to the plurality of source regions 35 and the plurality of contact regions 37 via the lower electrode film 46 in the portion covering the side walls and the opening ends of the plurality of trenches 16. The main electrode film 47 is electrically connected to the plurality of source regions 35 and the plurality of contact regions 37 via the lower electrode film 46 in the portion covering the plurality of mesa portions 20.

The semiconductor device 1A includes one or a plurality (a plurality in this embodiment) of gate openings 50 formed in the interlayer film 43. The plurality of gate openings 50 penetrate through the interlayer film 43 and selectively expose the plurality of gate wirings 42. In this embodiment, the plurality of gate openings 50 extend in a band shape in conformance to the extension direction of the plurality of gate wirings 42.

The plurality of gate openings 50 may be formed at an interval along the extension direction of the plurality of gate wirings 42. The plurality of gate openings 50 may be formed in a polygonal shape or a circular shape in plan view. For example, the plurality of gate structures 15 may be formed in a quadrangular shape or a hexagonal shape in plan view.

The plurality of gate openings 50 may have a portion extending in a band shape in the first direction X and a portion extending in a band shape in the second direction Y in plan view. The plurality of gate openings 50 may have an edge portion connecting, in an arcuate shape (preferably, a quarter arcuate shape), a portion extending in the first direction X and a portion extending in the second direction Y in plan view.

The semiconductor device 1A includes a gate electrode 51 arranged on the first main surface 3. The gate electrode 51 may be referred to as a “second main surface electrode,” a “second terminal (electrode),” a “second pad (electrode),” a “gate pad (electrode),” etc. The gate electrode 51 is arranged on the interlayer film 43 at an interval from the source electrode 45.

In this embodiment, the gate electrode 51 is arranged in a region on the third side surface 5C side with respect to the first pad portion 45a, and opposes a central portion of the third side surface 5C and the first pad portion 45a in the first direction X. The gate electrode 51 is interposed in a region between the second pad portion 45b and the third pad portion 45c, and opposes both the second pad portion 45b and the third pad portion 45c in the second direction Y.

The gate electrode 51 is formed in a polygonal shape (a quadrangular shape in this embodiment) having four sides parallel to the peripheral edge of the chip 2 in plan view. The gate electrode 51 has a planar area less than a planar area of the source electrode 45. The gate electrode 51 has a planar area less than the planar area of the first pad portion 45a. The gate electrode 51 may have a planar area less than the planar area of the second pad portion 45b (the third pad portion 45c).

The gate electrode 51 opposes the plurality of gate structures 15 with the interlayer film 43 interposed therebetween. Specifically, the gate electrode 51 is arranged at an interval inward from the both end portions of the plurality of gate structures 15, and opposes the inner portions of the plurality of gate structures 15 with the interlayer film 43 interposed therebetween. The portions of the plurality of gate structures 15 that are positioned at the gate electrode 51 may be removed.

In this case, the gate electrode 51 may oppose at least one of the second semiconductor layer 7, the body region 10, and the outer well region 40 with the main surface insulating film 41 and the interlayer film 43 interposed therebetween. Although not illustrated, as with the source electrode 45, the gate electrode 51 includes the lower electrode film 46 and the main electrode film 47 laminated in that order from the interlayer film 43 side. In this embodiment, the lower electrode film 46 has a laminated structure including the first electrode film 48 and the second electrode film 49.

The semiconductor device 1A includes a gate finger electrode 52 led out from the gate electrode 51 onto the first main surface 3. The gate finger electrode 52 may be referred to as a “gate finger,” etc. The gate finger electrode 52 transmits the gate potential applied to the gate electrode 51 to another region.

The gate finger electrode 52 is led out from the gate electrode 51 onto a portion of the interlayer film 43 covering the plurality of gate wirings 42. The gate finger electrode 52 is routed in a band shape to a region between the peripheral edge of the first main surface 3 and the source electrode 45. The gate finger electrode 52 has a portion extending in a band shape in the first direction X and a portion extending in a band shape in the second direction Y in plan view.

In this embodiment, the gate finger electrode 52 is formed in a band shape with ends having four sides parallel to a peripheral edge of the first main surface 3, and surrounds the source electrode 45. The gate finger electrode 52 is arranged further to the peripheral edge side of the first main surface 3 than the both end portions of the plurality of gate structures 15.

The gate finger electrode 52 enters into the plurality of gate openings 50 from above the interlayer film 43, and is mechanically and electrically connected to the plurality of gate wirings 42 in the plurality of gate openings 50. Thereby, the gate potential applied to the gate electrode 51 is to be applied to the plurality of gate structures 15 via the gate finger electrode 52.

The gate finger electrode 52 is led out from above the plurality of gate wirings 42 toward the peripheral edge side of the first main surface 3, and has a portion opposing the outer well region 40 with the main surface insulating film 41 and the interlayer film 43 interposed therebetween in a region outside the plurality of gate wirings 42. A peripheral edge portion of the gate finger electrode 52 may be positioned further to the peripheral edge side of the first main surface 3 than the outer edge portion of the outer well region 40, or may be positioned further to the plurality of gate wirings 42 than the outer edge portion of the outer well region 40.

In this embodiment, as with the source electrode 45, the gate finger electrode 52 has a laminated structure including the lower electrode film 46 and the main electrode film 47 laminated in that order from the chip 2 side. In this embodiment, the lower electrode film 46 has a laminated structure including the first electrode film 48 and the second electrode film 49.

The first electrode film 48 collectively covers, in a film shape, a region of the interlayer film 43 in which the plurality of gate openings 50 are formed, and enters into the plurality of gate openings 50 from above the interlayer film 43. The first electrode film 48 has a portion covering the insulating main surface of the interlayer film 43 in a film shape, a portion covering the wall surfaces of the plurality of gate openings 50 in a film shape, and a portion covering the plurality of gate wirings 42 in a film shape in the plurality of gate openings 50. The first electrode film 48 is mechanically and electrically connected to the plurality of gate wirings 42 in the plurality of gate openings 50.

The second electrode film 49 directly covers the first electrode film 48. The second electrode film 49 collectively covers, in a film shape, a region in which the plurality of gate openings 50 are formed in the interlayer film 43 with the first electrode film 48 interposed therebetween, and enters into the plurality of gate openings 50 from above the interlayer film 43.

The second electrode film 49 has a portion covering the interlayer film 43 in a film shape with the first electrode film 48 interposed therebetween, a portion covering the wall surfaces of the plurality of gate openings 50 in a film shape with the first electrode film 48 interposed therebetween, and a portion covering the first main surface 3 in a film shape with the first electrode film 48 interposed therebetween in the plurality of gate openings 50. The second electrode film 49 is electrically connected to the plurality of gate wirings 42 with the first electrode film 48 interposed therebetween in the plurality of gate openings 50.

The main electrode film 47 directly covers the lower electrode film 46 (the second electrode film 49). The main electrode film 47 backfills the plurality of gate openings 50 and collectively covers, in a film shape, a region of the interlayer film 43 in which the plurality of gate openings 50 are formed.

The main electrode film 47 has a portion covering the interlayer film 43 with the lower electrode film 46 interposed therebetween, a portion covering the wall surfaces of the plurality of gate openings 50 with the lower electrode film 46 interposed therebetween, and a portion covering the first main surface 3 with the lower electrode film 46 interposed therebetween. The main electrode film 47 is electrically connected to the plurality of gate wirings 42 with the lower electrode film 46 interposed therebetween in the plurality of gate openings 50.

The semiconductor device 1A includes a drain electrode 53 covering the second main surface 4. The drain electrode 53 may be referred to as a “third main surface electrode,” a “third terminal (electrode),” a “third pad (electrode),” a “drain pad (electrode),” etc. The drain electrode 53 is electrically connected to the first semiconductor layer 6. The drain electrode 53 forms an ohmic contact with the first semiconductor layer 6.

The drain electrode 53 may cover an entirety of the second main surface 4 so as to be continuous to the peripheral edges of the second main surface 4 (the first to fourth side surfaces 5A to 5D). The drain electrode 53 may partially cover the second main surface 4 so as to expose a peripheral edge portion of the second main surface 4.

A breakdown voltage applicable between the source electrode 45 and the drain electrode 53 (between the first main surface 3 and the second main surface 4) may be not less than 500 V and not more than 3000 V. The breakdown voltage may have a value belonging to at least one range among not less than 500 V and not more than 750 V, not less than 750 V and not more than 1000 V, not less than 1000 V and not more than 1250 V, not less than 1250 V and not more than 1500 V, not less than 1500 V and not more than 1750 V, not less than 1750 V and not more than 2000 V, not less than 2000 V and not more than 2250 V, not less than 2250 V and not more than 2500 V, and not less than 2500 V and not more than 3000 V.

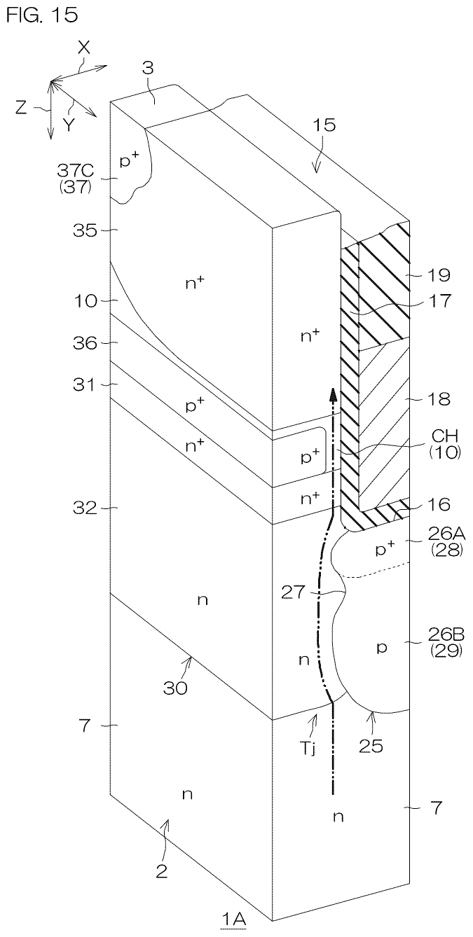

FIG. 15 is a sectional perspective view for describing an operation in a case where a drain-source voltage is applied in an off state of the gate structure 15. In the semiconductor device 1A, when a drain-source voltage is applied between the second semiconductor layer 7 (the drain electrode 53) and the body region 10 (the source electrode 45), a current path via the channel CH is formed in a region between the second semiconductor layer 7 and the body region 10, and a drain-source current is generated. The drain-source voltage is a voltage that sets the second semiconductor layer 7 to a positive potential and the body region 10 to a negative potential.

A device using an SiC monocrystal has a relatively high channel resistance due to a relatively low channel mobility based on physical properties of the SiC monocrystal. Accordingly, in the device using the SiC monocrystal, it is necessary to shorten the channel length and reduce the channel resistance. However, shortening of the channel length may cause an increase in a leakage current (drain leakage current) due to a short channel effect when the drain-source voltage is applied in the off state of the gate structure 15.

The off state of the gate structure 15 is a state where a gate voltage (off signal) less than a gate threshold voltage is applied to the gate structure 15. The short channel effect is a phenomenon in which the gate threshold voltage decreases due to an influence of the drain-source voltage, and control of the gate threshold voltage by the gate structure 15 becomes unstable, resulting in generation of the leakage current via the channel CH.

The semiconductor device 1A includes the well region 25 formed below the gate structure 15. The well region 25 has the bulging region 26 protruding in the horizontal direction along the first main surface 3 with respect to the side wall of the gate structure 15. When the drain-source voltage is applied in the off state of the gate structure 15, the well region 25 reduces an influence of the drain-source voltage on the channel CH by the bulging region 26, and suppresses a decrease in the gate threshold voltage.

Thereby, the leakage current due to the short channel effect is suppressed. Such a configuration is effective in improving the breakdown voltage and shortening the channel length. For example, the channel length after shortening is not more than 300 nm.

The semiconductor device 1A includes the body high concentration region 36 formed at the bottom portion of the body region 10. When the drain-source voltage is applied in the off state of the gate structure 15, the body high concentration region 36 reduces an influence of the drain-source voltage on the channel CH and suppresses a decrease in the gate threshold voltage. Thereby, the leakage current due to the short channel effect is suppressed. Such a configuration is effective in improving the breakdown voltage and shortening the channel length.

The body high concentration region 36 is preferably formed in a portion of the bottom portion of the body region 10. In this case, a formation location of the body high concentration region 36 (a location where a p-type impurity is introduced) with respect to the body region 10 is limited, and therefore an increase in the gate threshold voltage due to a work function of the p-type impurity is suppressed. The structure in which the body high concentration region 36 is separated from the gate structure 15 is effective in suppressing an increase in the channel resistance and an increase in the gate threshold voltage.

The well region 25 forms the JFET region Tj together with the second semiconductor layer 7 in a region below the gate structure 15. In this case, the well region 25 may include the first bulging region 26A and the second bulging region 26B as the plurality of bulging regions 26.

The first bulging region 26A is formed in a portion along the bottom wall of the gate structure 15, and the second bulging region 26B may be formed below the first bulging region 26A. According to this configuration, at the same time as suppressing a decrease in the gate threshold voltage by the first bulging region 26A, the JFET region Tj can be formed by the second bulging region 26B.

The semiconductor device 1A includes the high concentration region 30 on a lateral side of the well region 25. According to this configuration, a JFET resistance is reduced by the high concentration region 30. The well region 25 may include the second well region 29 consisting of a channeling region. According to this configuration, a p-type impurity concentration and a depth of the second well region 29 are appropriately adjusted, and the JFET region Tj is appropriately formed. Accordingly, the breakdown voltage can be appropriately improved by the JFET region Tj.

Similarly, the high concentration region 30 may include the second high concentration region 32 consisting of a channeling region. According to this configuration, an n-type impurity concentration and a depth of the second high concentration region 32 are appropriately adjusted, and the JFET region Tj is appropriately formed. Accordingly, the breakdown voltage can be appropriately improved by the JFET region Tj.

The second well region 29 hardly contains an n-type impurity (pentavalent element) of the second high concentration region 32 and is formed separately from the second high concentration region 32. That is, a p-type impurity concentration of the second well region 29 is hardly affected by an n-type impurity concentration of the second high concentration region 32. Accordingly, an impurity concentration and the depth of the second well region 29 are appropriately adjusted, and the JFET region Tj is appropriately formed.

The second high concentration region 32 hardly contains a p-type impurity (trivalent element) of the second well region 29, and is formed separately from the second well region 29. That is, an n-type impurity concentration of the second high concentration region 32 is hardly affected by a p-type impurity concentration of the second well region 29. Accordingly, an impurity concentration and the depth of the second high concentration region 32 are appropriately adjusted, and the JFET region Tj is appropriately formed.

As described above, the semiconductor device 1A may include the second semiconductor layer 7 of the n-type (the semiconductor layer), the body region 10 of the p-type, the gate structure 15 of the trench type, and the well region 25 of the p-type. The second semiconductor layer 7 may have the first main surface 3. The body region 10 may be formed in the surface layer portion of the first main surface 3.

The gate structure 15 may be formed on the first main surface 3 so as to penetrate through the body region 10. The well region 25 may be formed in a region below the gate structure 15 within the second semiconductor layer 7. The well region 25 may have the bulging region 26 protruding in the horizontal direction along the first main surface 3 with respect to the side wall of the gate structure 15.

According to this configuration, the semiconductor device 1A having a novel layout can be provided. For example, according to the semiconductor device 1A, the electrical stability of the channel CH along the gate structure 15 is enhanced by the bulging region 26 positioned in a region below the gate structure 15, and the decrease in the gate threshold voltage is suppressed. Thereby, the leakage current due to the short channel effect is suppressed.

The second semiconductor layer 7 may contain SiC. According to this configuration, the semiconductor device 1A as an SiC semiconductor device having a novel layout can be provided. According to the semiconductor device 1A, the withstand voltage is further improved by the physical properties of SiC. In particular, in the case of the SiC semiconductor device, since the SiC semiconductor device is used in a relatively high voltage environment, an effect of suppressing the short channel effect by the bulging region 26 is effective.

The bulging region 26 may have an impurity concentration higher than an impurity concentration of the body region 10. According to this configuration, the short channel effect is suppressed by using the bulging region 26 having a relatively high impurity concentration. The bulging region 26 may be connected to the bottom wall of the gate structure 15. According to this configuration, the short channel effect is suppressed by the bulging region 26 connected to the bottom wall of the gate structure 15. The bulging region 26 may protrude in an arc shape. According to this configuration, the short channel effect is suppressed by the bulging region 26 protruding in an arc shape.

The well region 25 may have a constricted region 27 that is recessed, below the bulging region 26, in the horizontal direction along the first main surface 3 with respect to the bulging region 26. According to this configuration, the bulging region 26 is appropriately demarcated by the constricted region 27. Thereby, the short channel effect is appropriately suppressed. The constricted region 27 may have a portion positioned further inward than the side walls of the gate structure 15. According to this configuration, the bulging region 26 is appropriately demarcated by the constricted region 27.

The bulging region 26 may protrude in the horizontal direction along the first main surface 3 with respect to both side walls of the gate structure 15. According to this configuration, the short channel effect is suppressed by the bulging region 26 in regions on the both side wall sides of the gate structure 15. The well region 25 may include a plurality of bulging regions 26 formed at different depth positions.

The well region 25 may include the first well region 28 of the p-type and the second well region 29 of the p-type. The first well region 28 may be formed below the bottom wall of the gate structure 15. The second well region 29 may be formed below the first well region 28. In this case, the bulging region 26 may be formed by the first well region 28. According to this configuration, the bulging region 26 is appropriately formed by using the first well region 28.

The second well region 29 may have a p-type impurity concentration lower than a p-type impurity concentration of the first well region 28. According to this configuration, electrical response characteristics of the second well region 29 can be improved by the first well region 28.

The second well region 29 may form the JFET region Tj with the second semiconductor layer 7. According to this configuration, the breakdown voltage can be improved by the JFET region Tj. The second well region 29 may have a thickness greater than a thickness of the first well region 28. According to this configuration, the JFET region Tj can be appropriately formed by the relatively thick second well region 29.

The gate structure 15 may include the trench 16 formed in the first main surface 3, the insulating film 17 covering the wall surface of the trench 16, and the embedded electrode 18 embedded in the trench 16 via the insulating film 17. The embedded electrode 18 may be embedded at an interval toward the bottom wall side of the trench 16 from the height position of the first main surface 3.

The gate structure 15 may include the embedded insulator 19 embedded in the trench 16 at an interval toward the bottom wall side of the trench 16 from the height position of the first main surface 3 so as to cover the embedded electrode 18. According to this configuration, an insulation withstand voltage on an opening side of the gate structure 15 is improved by the embedded insulator 19. Also, since a covering area of an insulating structure with respect to the first main surface 3 is reduced, an electrical contact location with respect to the first main surface 3 can be appropriately secured.

The semiconductor device 1A may include the contact region 37 of the p-type. The contact region 37 extends along the side wall of the gate structure 15 and may electrically connect the bulging region 26 to the body region 10. According to this configuration, the bulging region 26 is suppressed from becoming an electrically floating state, and electrical response characteristics of the bulging region 26 are improved. The contact region 37 may have a p-type impurity concentration higher than a p-type impurity concentration of the body region 10.

The semiconductor device 1A may include the source region 35 of the n-type. The source region 35 may be formed in the surface layer portion of the body region 10. According to this configuration, the channel CH is formed in a region between the bottom portion of the body region 10 and the bottom portion of the source region 35 along the gate structure 15. In this case, the channel length can be appropriately shortened by an effect of suppressing the short channel effect by the bulging region 26. For example, the channel length may be not more than 300 nm.

The semiconductor device 1A may include the high concentration region 30 of the n-type. The high concentration region 30 may be formed within the second semiconductor layer 7 in a thickness range between the bottom portion of the body region 10 and the bottom wall of the gate structure 15. The high concentration region 30 may have an n-type impurity concentration higher than an n-type impurity concentration of the second semiconductor layer 7.

According to this configuration, the high concentration region 30 cancels an undesired p-type impurity introduced to a lateral side of the gate structure 15 due to a process error, etc. Thereby, integration of the bulging region 26 with the body region 10 is appropriately suppressed, and fluctuation of the gate threshold voltage due to the undesired p-type impurity is suppressed. Also, the high concentration region 30 reduces a resistance value below the body region 10. Such a configuration is effective in reducing an on-resistance and a JFET resistance.

The semiconductor device 1A may include the source electrode 45. The source electrode 45 may be electrically connected to the body region 10 on the first main surface 3 and may be electrically separated from the gate structure 15.

From another perspective, the semiconductor device 1A may include the second semiconductor layer 7 of the n-type (the semiconductor layer), the body region 10 of the p-type, the gate structure 15 of the trench type, and the body high concentration region 36 of the p-type. The second semiconductor layer 7 may have the first main surface 3. The body region 10 may be formed in the surface layer portion of the first main surface 3.

The gate structure 15 may be formed on the first main surface 3 so as to penetrate through the body region 10. The body high concentration region 36 may be formed at the bottom portion of the body region 10. The body high concentration region 36 may have a p-type impurity concentration higher than a p-type impurity concentration of the body region 10.

According to this configuration, the semiconductor device 1A having a novel layout can be provided. For example, according to this semiconductor device 1A, electrical stability of the channel CH along the gate structure 15 is enhanced by the body high concentration region 36, and a decrease in the gate threshold voltage is suppressed. Thereby, the leakage current caused by a short channel effect is suppressed, and a breakdown voltage is improved. Such a configuration is also effective in shortening the channel length.

The second semiconductor layer 7 may contain SiC. According to this configuration, the semiconductor device 1A as an SiC semiconductor device having a novel layout can be provided. According to the semiconductor device 1A, the withstand voltage is further improved by the physical properties of SiC. In particular, in the case of the SiC semiconductor device, since the SiC semiconductor device is used in a relatively high voltage environment, an effect of suppressing the short channel effect by the body high concentration region 36 is effective.

The body high concentration region 36 may be formed at an interval from the gate structure 15. According to this configuration, a high concentration location of the body region 10 becomes limited. Thereby, an increase in the gate threshold voltage due to a work function of the body high concentration region 36 is suppressed. In this case, the body high concentration region 36 may oppose the gate structure 15 with a portion of the body region 10 interposed therebetween. According to this configuration, the channel CH is appropriately formed in the body region 10 of relatively low concentration.

The body high concentration region 36 may extend along the extension direction of the gate structure 15. According to this configuration, an effect of suppressing the short channel effect by the body high concentration region 36 is exhibited in conformance to the extension direction of the gate structure 15. The body high concentration region 36 may extend in a band shape along the gate structure 15, or may be formed at an interval along the gate structure 15.

The gate structure 15 may include the trench 16 formed in the first main surface 3, the insulating film 17 covering the wall surface of the trench 16, and the embedded electrode 18 embedded in the trench 16 via the insulating film 17. The embedded electrode 18 may be embedded at an interval toward the bottom wall side of the trench 16 from the height position of the first main surface 3.

The gate structure 15 may include the embedded insulator 19 embedded in the trench 16 at an interval toward the bottom wall side of the trench 16 from the height position of the first main surface 3 so as to cover the embedded electrode 18. According to this configuration, since a hidden area of the first main surface 3 caused by the insulating structure with respect to the gate structure 15 is reduced, the electrical contact location with respect to the first main surface 3 can be appropriately secured.

The semiconductor device 1A may include the source region 35 of the n-type. The source region 35 may be formed in the surface layer portion of the body region 10. According to this configuration, the channel CH is formed in a region between the bottom portion of the body region 10 and the bottom portion of the source region 35 along the gate structure 15. In this case, the channel length can be appropriately shortened by an effect of suppressing the short channel effect by the body high concentration region 36. For example, the channel length may be not more than 300 nm.

The body high concentration region 36 may be formed in a thickness range between the bottom portion of the body region 10 and the bottom portion of the source region 35. According to this configuration, at the same time as appropriately suppressing the short channel effect, the channel length can be appropriately shortened. In this case, the body high concentration region 36 may be formed at an interval toward the bottom portion side of the body region 10 from the bottom portion of the source region 35, and may oppose the source region 35 with a portion of the body region 10 interposed therebetween.

The semiconductor device 1A may include the contact region 37 of the p-type. The contact region 37 may be formed along the gate structure 15 in the surface layer portion of the body region 10. The contact region 37 may have a p-type impurity concentration higher than a p-type impurity concentration of the body region 10. According to this configuration, the electrical response characteristics of the body region 10 can be improved by the contact region 37.

The contact region 37 may be electrically connected to the body high concentration region 36 in the body region 10. According to this configuration, the electrical response characteristics of the body high concentration region 36 can be improved by the contact region 37. The contact region 37 may have a portion connected to the body high concentration region 36 in the body region 10. According to this configuration, the electrical response characteristics of the body high concentration region 36 can be appropriately improved.

The semiconductor device 1A may include the well region 25 of the p-type. The well region 25 may be formed within the second semiconductor layer 7 at an interval from the bottom portion of the body region 10 in the region below the gate structure 15. According to this configuration, the JFET region Tj including the second semiconductor layer 7 and the well region 25 can be formed in a region below the gate structure 15. Thereby, the breakdown voltage can be improved by the JFET region Tj.

The well region 25 may be formed at an interval from the bottom portion of the body high concentration region 36. According to this configuration, integration of the well region 25 with the body high concentration region 36 is thereby suppressed. Thereby, fluctuation of the gate threshold voltage due to an undesired p-type impurity is suppressed.

The well region 25 may include the first well region 28 of the p-type and the second well region 29 of the p-type. The first well region 28 may be formed below the bottom wall of the gate structure 15. The second well region 29 may be formed below the first well region 28.

The second well region 29 may have a p-type impurity concentration lower than a p-type impurity concentration of the first well region 28. According to this configuration, electrical response characteristics of the second well region 29 can be improved by the first well region 28.

The second well region 29 may form the JFET region Tj with the second semiconductor layer 7. According to this configuration, the breakdown voltage can be improved by the JFET region Tj. The second well region 29 may have a thickness greater than a thickness of the first well region 28. According to this configuration, the JFET region Tj can be appropriately formed by the relatively thick second well region 29.

The semiconductor device 1A may include the contact region 37 of the p-type. The contact region 37 may extend along the side wall of the gate structure 15 and electrically connect the well region 25 to the body high concentration region 36. According to this configuration, the well region 25 is suppressed from becoming an electrically floating state, and the electrical response characteristics of the well region 25 are improved. The contact region 37 may have a p-type impurity concentration higher than a p-type impurity concentration of the second well region 29.

The semiconductor device 1A may include the high concentration region 30 of the n-type. The high concentration region 30 may be formed within the second semiconductor layer 7 in a thickness range between the bottom portion of the body high concentration region 36 and the bottom wall of the gate structure 15. The high concentration region 30 may have an n-type impurity concentration higher than an n-type impurity concentration of the second semiconductor layer 7.

According to this configuration, the high concentration region 30 cancels an undesired p-type impurity introduced to a lateral side of the gate structure 15 due to a process error, etc. Thereby, fluctuation of the gate threshold voltage due to an undesired p-type impurity is suppressed. Also, the high concentration region 30 reduces a resistance value below the body high concentration region 36. Such a configuration is effective in reducing an on-resistance and a JFET resistance.

The semiconductor device 1A may include the source electrode 45. The source electrode 45 may be electrically connected to the body region 10 on the first main surface 3 and may be electrically separated from the gate structure 15.

From another perspective, the semiconductor device 1A may include the second semiconductor layer 7 of the n-type (the semiconductor layer), the gate structure 15 of the trench type, and the second well region 29 of the p-type (the well region 25). The second semiconductor layer 7 may have an SiC monocrystal and may have the first main surface 3. The gate structure 15 may be formed in the first main surface 3. The second well region 29 may be formed in a region below the gate structure 15 within the second semiconductor layer 7. The second well region 29 may extend longitudinally along the axis channel of the SiC monocrystal.

According to this configuration, the semiconductor device 1A having a novel layout can be provided. For example, according to this semiconductor device 1A, a p-type impurity concentration and the depth of the second well region 29 are appropriately adjusted, and the JFET region Tj is appropriately formed. Accordingly, the breakdown voltage can be appropriately improved by the JFET region Tj.

The second well region 29 may have an impurity concentration higher than the impurity concentration of the second semiconductor layer 7, and replace the conductivity type of the second semiconductor layer 7 from the n-type to the p-type. According to this configuration, the JFET region Tj can be appropriately formed.

The second well region 29 may have a concentration gradient decreasing in a thickness direction. According to this configuration, the JFET region Tj can be appropriately formed by the second well region 29 having the concentration gradient decreasing in the thickness direction.

On a basis of the bottom wall of the gate structure 15, the second well region 29 may have a depth of not less than 0.5 μm and not more than 5 μm. In this case, the second well region 29 may include the gently sloping portion 29A having a concentration decrease rate of not more than 50% in a depth range of at least 0.25 μm. According to this configuration, since a concentration change rate of the second well region 29 becomes gentle, the JFET region Tj can be appropriately formed.

On a basis of the bottom wall of the gate structure 15, the second well region 29 may have the depth smaller than the depth of the gate structure 15 on a basis of the first main surface 3. On a basis of the bottom wall of the gate structure 15, the second well region 29 may have the depth greater than a depth of the gate structure 15 on the basis of the first main surface 3. The depth of the second well region 29 is adjusted as appropriate in accordance with the JFET region Tj to be achieved.

The second well region 29 may be formed in a shape tapering toward a bottom portion in sectional view. The second well region 29 may protrude in the horizontal direction along the first main surface 3 with respect to the side wall of the gate structure 15 in sectional view.

The semiconductor device 1A may include the high concentration region 30 of the n-type. The high concentration region 30 may be formed in a region lateral to the second well region 29 within the second semiconductor layer 7. The high concentration region 30 may have an n-type impurity concentration higher than an n-type impurity concentration of the second semiconductor layer 7. According to this configuration, the high concentration region 30 forms the JFET region Tj with the second well region 29. Thereby, a JFET resistance is reduced by the high concentration region 30.

The high concentration region 30 may extend along the axis channel of the SiC monocrystal. According to this configuration, an n-type impurity concentration and a depth of the high concentration region 30 are appropriately adjusted, and the JFET region Tj is appropriately formed. Accordingly, the breakdown voltage can be appropriately improved by the JFET region Tj.

The high concentration region 30 may have a bottom portion positioned further to the first main surface 3 side than the bottom portion of the second well region 29. The high concentration region 30 may have a bottom positioned lower than the bottom portion of the second well region 29. The depth of the high concentration region 30 is adjusted as appropriate in accordance with the JFET region Tj to be achieved.

The high concentration region 30 may have a concentration gradient decreasing in a thickness direction. According to this configuration, the JFET region Tj can be appropriately formed by the high concentration region 30 having the concentration gradient decreasing in the thickness direction.

The high concentration region 30 may include the first high concentration region 31 and the second high concentration region 32. The first high concentration region 31 may be positioned above the depth position of the bottom wall of the gate structure 15. The second high concentration region 32 may be positioned below the depth position of the bottom wall of the gate structure 15.

According to this configuration, the first high concentration region 31 cancels an undesired p-type impurity introduced to a lateral side of the gate structure 15 due to a process error, etc. Thereby, fluctuation of the gate threshold voltage due to an undesired p-type impurity is suppressed. Also, the first high concentration region 31 reduces a resistance value below the body region 10. Such a configuration is effective in reducing an on-resistance and a JFET resistance.

The second high concentration region 32 may form the JFET region Tj with the second well region 29. Thereby, a JFET resistance is reduced by the high concentration region 30. The second high concentration region 32 may have a concentration gradient monotonically decreasing in a thickness direction. According to this configuration, the JFET region Tj can be appropriately formed by the second high concentration region 32 having the concentration gradient controlled to be monotonically decreasing.

On a basis of the bottom wall of the gate structure 15, the second high concentration region 32 may have a depth of not less than 0.5 μm and not more than 5 μm. In this case, the second high concentration region 32 may include the gently sloping portion 32A having the concentration decrease rate of not more than 50% in a depth range of at least 0.25 μm. According to this configuration, since a concentration change rate of the second high concentration region 32 becomes gentle, the JFET region Tj can be appropriately formed.

The semiconductor device 1A may include the first well region 28 of the p-type (the well high concentration region). The first well region 28 may be formed below the bottom wall of the gate structure 15 within the second semiconductor layer 7. In this case, the second well region 29 may be formed below the first well region 28.

The second well region 29 may have a p-type impurity concentration lower than a p-type impurity concentration of the first well region 28. According to this configuration, electrical response characteristics of the second well region 29 can be improved by the first well region 28. The second well region 29 may have a thickness greater than a thickness of the first well region 28. According to this configuration, the JFET region Tj is appropriately formed by the second well region 29 thicker than the first well region 28.

The second well region 29 may have a concentration gradient different from the concentration gradient of the first well region 28. According to this configuration, an electrical influence of the p-type impurity concentration of the first well region 28 on the JFET region Tj can be suppressed. The first well region 28 may have a concentration gradient that increases/decreases from the bottom wall side of the gate structure 15.

The semiconductor device 1A may include the body region 10 of the p-type. The body region 10 may be formed in the surface layer portion of the first main surface 3. In this case, the gate structure 15 may penetrate through the body region 10. According to this configuration, the second well region 29 can be appropriately provided below the body region 10.

The second well region 29 may be formed at an interval from the bottom portion of the body region 10. According to this configuration, integration of the second well region 29 with the body region 10 is appropriately suppressed, and fluctuation of the gate threshold voltage due to the undesired p-type impurity is suppressed.

The semiconductor device 1A may include the contact region 37 of the p-type. The contact region 37 may extend along the side wall of the gate structure 15 and electrically connect the second well region 29 to the body region 10. According to this configuration, the second well region 29 is suppressed from becoming an electrically floating state, and the electrical response characteristics of the second well region 29 are improved.

The contact region 37 may have a p-type impurity concentration higher than a p-type impurity concentration of the second well region 29. The contact region 37 may have a p-type impurity concentration higher than a p-type impurity concentration of the body region 10.

The semiconductor device 1A may include the source region 35 of the n-type. The source region 35 may be formed in the surface layer portion of the body region 10. According to this configuration, the source region 35 demarcates the channel CH at the bottom portion of the body region 10. The semiconductor device 1A may include the source electrode 45. The source electrode 45 may be electrically connected to the first main surface 3 and may be electrically separated from the gate structure 15.

From another perspective, the semiconductor device 1A may include the second semiconductor layer 7 of the n-type (the semiconductor layer), the second well region 29 of the p-type (the well region 25), and the second high concentration region 32 of the n-type (the high concentration region 30). The second well region 29 may be formed to be of a higher concentration than the second semiconductor layer 7 within the second semiconductor layer 7. The second high concentration region 32 may be formed to be of a higher concentration than the second semiconductor layer 7 within the second semiconductor layer 7. The second high concentration region 32 may form a pn-junction portion with the second well region 29.

According to this configuration, the semiconductor device 1A having a novel layout can be provided. For example, according to this semiconductor device 1A, the second high concentration region 32 forms the JFET region Tj together with the second well region 29. Accordingly, the breakdown voltage can be appropriately improved by the JFET region Tj.

The second semiconductor layer 7 may contain SiC. According to this configuration, the semiconductor device 1A as an SiC semiconductor device having a novel layout can be provided. According to the semiconductor device 1A, the withstand voltage is further improved by the physical properties of SiC. In particular, in the case of the SiC semiconductor device, since the SiC semiconductor device is used in a relatively high voltage environment, an effect of improving a breakdown voltage by the JFET region Tj including the second well region 29 and the second high concentration region 32 is effective.

The second well region 29 may have a p-type impurity concentration separated from an n-type impurity concentration of the second high concentration region 32. According to this configuration, a p-type impurity concentration of the second well region 29 is appropriately adjusted, and the JFET region Tj is appropriately formed. Accordingly, the breakdown voltage can be appropriately improved by the JFET region Tj.

The second high concentration region 32 may have an impurity concentration separated from an impurity concentration of the second well region 29. According to this configuration, an n-type impurity concentration of the second high concentration region 32 is appropriately adjusted, and the JFET region Tj is appropriately formed. Accordingly, the breakdown voltage can be appropriately improved by the JFET region Tj.

The second semiconductor layer 7 may be adjusted in concentration by the first element consisting of the pentavalent element. The second well region 29 may be adjusted in concentration by the third element consisting of the trivalent element in addition to the first element. The second high concentration region 32 may be adjusted in concentration by the fifth element consisting of the pentavalent element in addition to the first element.

A concentration of the fifth element in the second well region 29 may be less than a concentration of the fifth element in the second high concentration region 32. According to this configuration, the p-type impurity concentration of the second well region 29 can be appropriately separated from the n-type impurity concentration of the second high concentration region 32. In this case, the inner portion of the second well region 29 does not have to contain the fifth element.

The concentration of the third element in the second high concentration region 32 may be less than the concentration of the third element in the second well region 29. According to this configuration, the n-type impurity concentration of the second high concentration region 32 can be appropriately separated from the p-type impurity concentration of the second well region 29. In this case, an inner portion of the second high concentration region 32 does not have to contain the third element.

The first element may include at least one type among nitrogen, phosphorus, and arsenic. The first element may consist of a single pentavalent element. The first element may be nitrogen.

The third element may include at least one type among boron and aluminum. The third element may consist of a single trivalent element. The third element may be aluminum.

The fifth element may include at least one type among nitrogen, phosphorus, and arsenic. The fifth element may be the same type as the first element. The fifth element may be a different type from the first element. The fifth element may consist of a single pentavalent element. The fifth element may be nitrogen.

The second high concentration region 32 may have a bottom portion positioned higher than a depth position of the bottom portion of the second well region 29. The second high concentration region 32 may have a bottom portion positioned lower than the bottom portion of the second well region 29. The depth of the second high concentration region 32 is adjusted as appropriate in accordance with the JFET region Tj to be achieved.

The second high concentration region 32 may form a super junction structure with the second well region 29. According to this configuration, a breakdown voltage can be appropriately improved by the super junction structure.

The semiconductor device 1A may include the gate structure 15 of the trench type. The gate structure 15 may be formed in the second semiconductor layer 7. In this case, the second well region 29 may be formed below the gate structure 15. The second high concentration region 32 may be formed at a position lower than the depth position of the bottom wall of the gate structure 15.

According to this configuration, the second high concentration region 32 forms the JFET region Tj together with the second well region 29 in a region lower than the gate structure 15. Accordingly, in a configuration including the gate structure 15 of the trench type, the breakdown voltage can be appropriately improved by the JFET region Tj.

The semiconductor device 1A may include the first well region 28 of the p-type (the well high concentration region). The first well region 28 may be formed below the bottom wall of the gate structure 15. In this case, the second well region 29 may be formed to be of a lower concentration than the first well region 28 in a region below the first well region 28. According to this configuration, the electrical response characteristics of the second well region 29 are enhanced by the first well region 28.

The semiconductor device 1A may include the first high concentration region 31 of the n-type (the upper high concentration region). The first high concentration region 31 may be formed at a position higher than the depth position of the bottom wall of the gate structure 15. In this case, the second high concentration region 32 may be formed to be of a lower concentration than the first high concentration region 31 in a region below the first high concentration region 31.

According to this configuration, the first high concentration region 31 cancels an undesired p-type impurity introduced to a lateral side of the gate structure 15 due to a process error, etc. Thereby, fluctuation of the gate threshold voltage due to an undesired p-type impurity is suppressed. Also, the first high concentration region 31 reduces a resistance value at a lateral side of the gate structure 15. Such a configuration is effective in reducing an on-resistance and a JFET resistance.

The semiconductor device 1A may include the body region 10 of the p-type. The body region 10 may be formed in the second semiconductor layer 7. In this case, the gate structure 15 may penetrate through the body region 10. According to this configuration, the second well region 29 can be appropriately provided below the body region 10.

The second well region 29 may be formed at an interval from the bottom portion of the body region 10. According to this configuration, integration of the second well region 29 with the body region 10 is appropriately suppressed, and fluctuation of the gate threshold voltage due to the undesired p-type impurity is suppressed.

The semiconductor device 1A may include the contact region 37 of the p-type. The contact region 37 may extend along the side wall of the gate structure 15. The contact region 37 may electrically connect the second well region 29 to the body region 10. According to this configuration, the second well region 29 is suppressed from becoming an electrically floating state, and the electrical response characteristics of the second well region 29 are improved.

The contact region 37 may have a p-type impurity concentration higher than a p-type impurity concentration of the second well region 29. The contact region 37 may have a p-type impurity concentration higher than a p-type impurity concentration of the body region 10.

The semiconductor device 1A may include the source region 35 of the n-type. The source region 35 may be formed in the surface layer portion of the body region 10. According to this configuration, the source region 35 demarcates the channel CH at the bottom portion of the body region 10. The semiconductor device 1A may include the source electrode 45. The source electrode 45 may be electrically connected to the first main surface 3 and may be electrically separated from the gate structure 15.

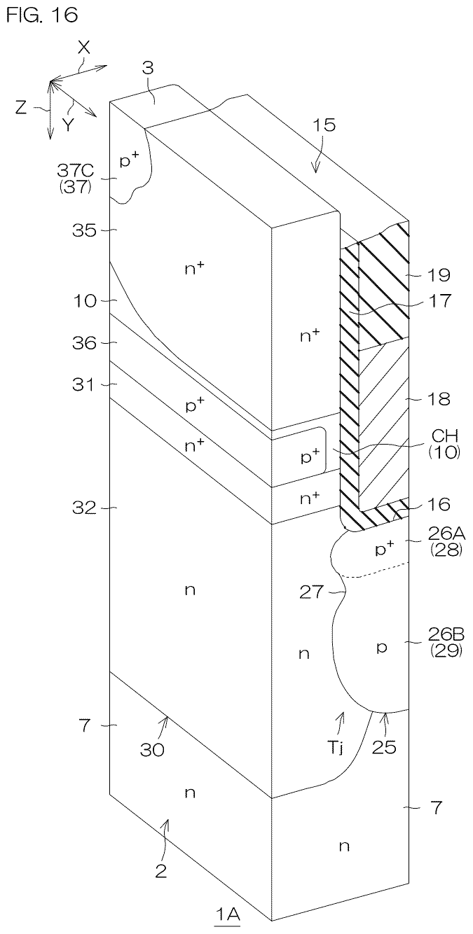

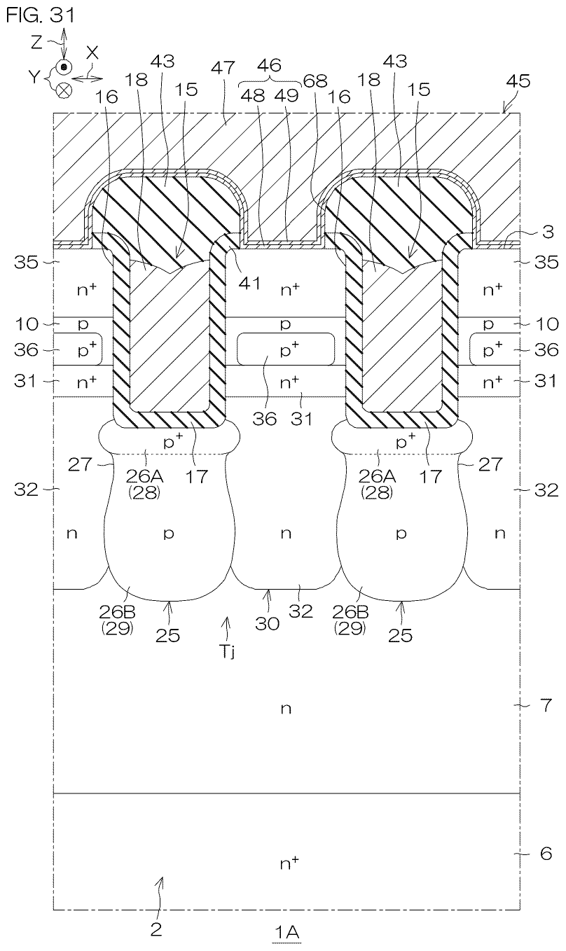

Hereinafter, modification examples applied to the semiconductor device 1A shall be described. FIGS. 16 to 30 are sectional perspective views illustrating first to fifteenth modification examples of the semiconductor device 1A. FIG. 31 is a sectional view illustrating a sixteenth modification example of the semiconductor device 1A.

The semiconductor device 1A may include any one of the features of the first to sixteenth modification examples. The first to sixteenth modification examples can be combined as appropriate with each other. Accordingly, the semiconductor device 1A can include at least two of the features of the first to sixteenth modification examples at the same time in the same sectional region or different sectional regions.

With reference to FIG. 16 (first modification example), the semiconductor device 1A may include the plurality of high concentration regions 30 (the second high concentration regions 32) deeper than the plurality of well regions 25 (the second well regions 29). That is, the plurality of high concentration regions 30 (the second high concentration regions 32) may have the bottom portions positioned on the bottom portion side of the second semiconductor layer 7 with respect to the depth positions of bottom portions of the plurality of well regions 25 (the second well regions 29).

In this case, the bottom portions of the plurality of high concentration regions 30 may overlap the bottom portions of the plurality of well regions 25. In this case, the bottom portions of the plurality of high concentration regions 30 preferably partially overlap the bottom portions of the plurality of well regions 25.

That is, the bottom portions of the plurality of high concentration regions 30 are preferably formed at an interval from each other in regions lower than the bottom portions of the plurality of well regions 25, and oppose each other in the horizontal direction with a portion of the second semiconductor layer 7 interposed therebetween. In other words, the bottom portions of the plurality of high concentration regions 30 preferably leave direct connection portions of the plurality of well regions 25 with respect to the second semiconductor layer 7 without overlapping an entirety of the bottom portions of the plurality of well regions 25.

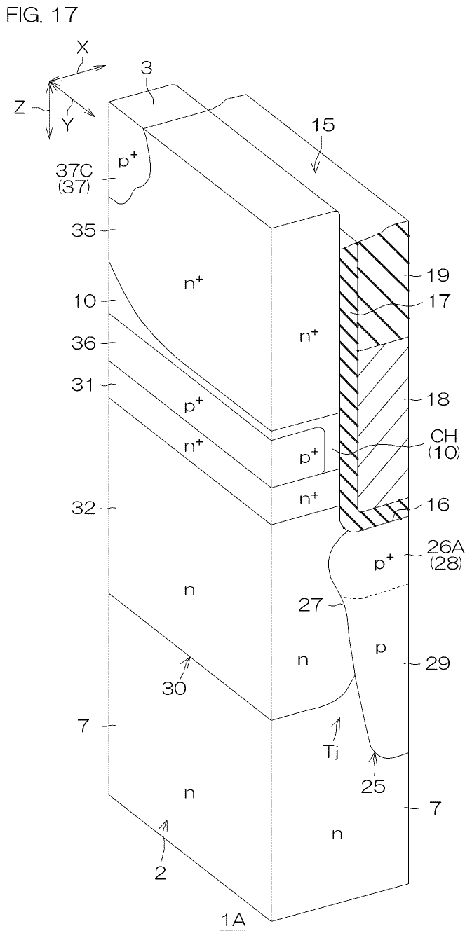

With reference to FIG. 17 (second modification example), the semiconductor device 1A may include the second well region 29 formed in a shape tapering toward a thickness direction. That is, the second well region 29 does not necessarily have to have the second bulging region 26B. As a matter of course, the second well region 29 may extend in the thickness direction with a substantially fixed width.

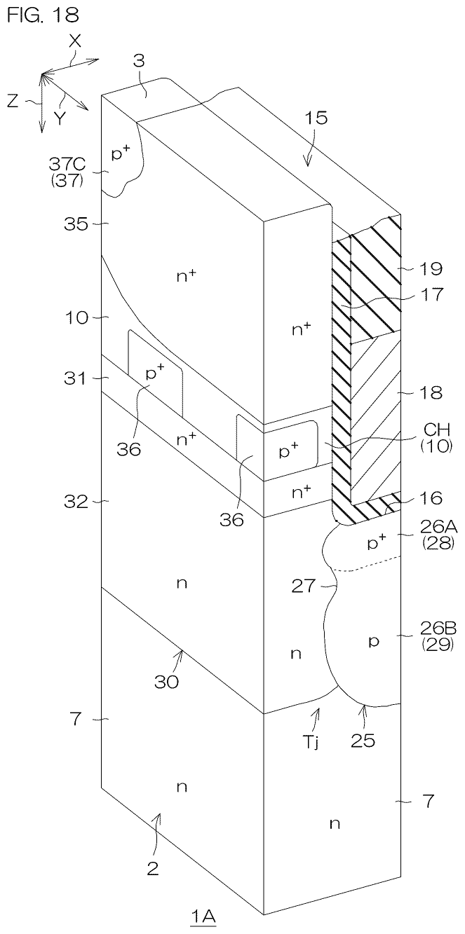

With reference to FIG. 18 (third modification example), the semiconductor device 1A may include the plurality of body high concentration regions 36 formed at an interval in the second direction Y in conformance to the extension direction of the gate structure 15. The plurality of body high concentration regions 36 may each extend in a band shape in the second direction Y.

The lengths of the plurality of body high concentration regions 36 may be greater than the width of the gate structure 15, or may be smaller than the width of the gate structure 15. The lengths of the plurality of body high concentration regions 36 may be greater than the pitch of the plurality of gate structures 15 or may be smaller than the pitch of the plurality of gate structures 15.

The interval between the plurality of body high concentration regions 36 may be greater than the width of the gate structure 15, or may be smaller than the width of the gate structure 15. The interval between the plurality of body high concentration regions 36 may be greater than the pitch of the plurality of gate structures 15 or may be smaller than the pitch of the plurality of gate structures 15.

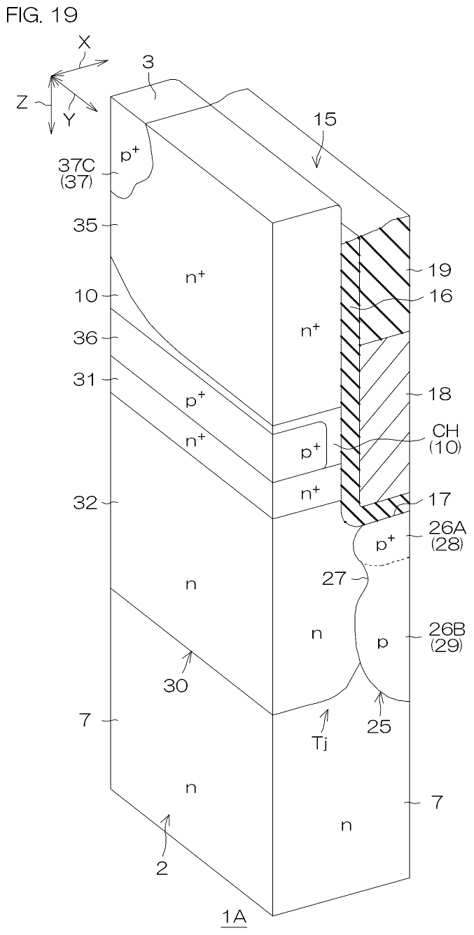

With reference to FIG. 19 (fourth modification example), the semiconductor device 1A may have the first bulging region 26A (the first well region 28), the second bulging region 26B (the second well region 29), and the constricted region 27 positioned further inward than the side wall of the corresponding gate structure 15.

While the first bulging region 26A is positioned further outward than the side wall of the gate structure 15, the second bulging region 26B may be positioned further inward than the side wall of the gate structure 15. In this case, the constricted region 27 may be positioned further inward than the side wall of the gate structure 15 or may be positioned further outward than the side wall of the gate structure 15.

While the first bulging region 26A is positioned further inward than the side wall of the gate structure 15, the second bulging region 26B may be positioned further outward than the side wall of the gate structure 15. In this case, the constricted region 27 may be positioned further inward than the side wall of the gate structure 15 or may be positioned further outward than the side wall of the gate structure 15.

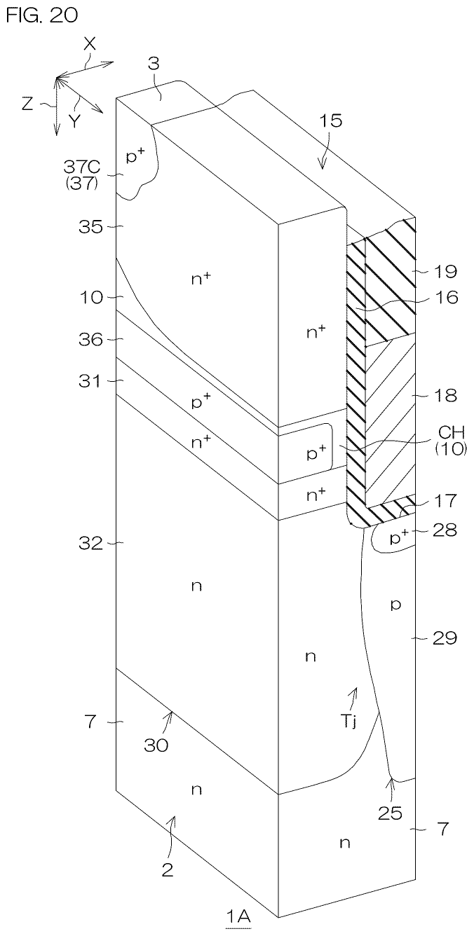

With reference to FIG. 20 (fifth modification example), the semiconductor device 1A may include the first well region 28 having a width smaller than a width of the gate structure 15, and the second well region 29 having a width greater than the width of the first well region 28. The first well region 28 may be formed in a region along the bottom wall of the gate structure 15 at an interval toward an inner side from the side wall of the gate structure 15.

The second well region 29 may have a portion (the upper end portion) connected to the bottom wall of the gate structure 15 in a region further to the side wall of the gate structure 15 than a peripheral edge of the first well region 28. In this embodiment, the second well region 29 does not have the bulging region 26 and is formed in a shape tapering toward a depth direction. As a matter of course, the second well region 29 may extend in the thickness direction with a substantially fixed width. Also, the second well region 29 may have a width greater than the width of the gate structure 15 and may form the bulging region 26.

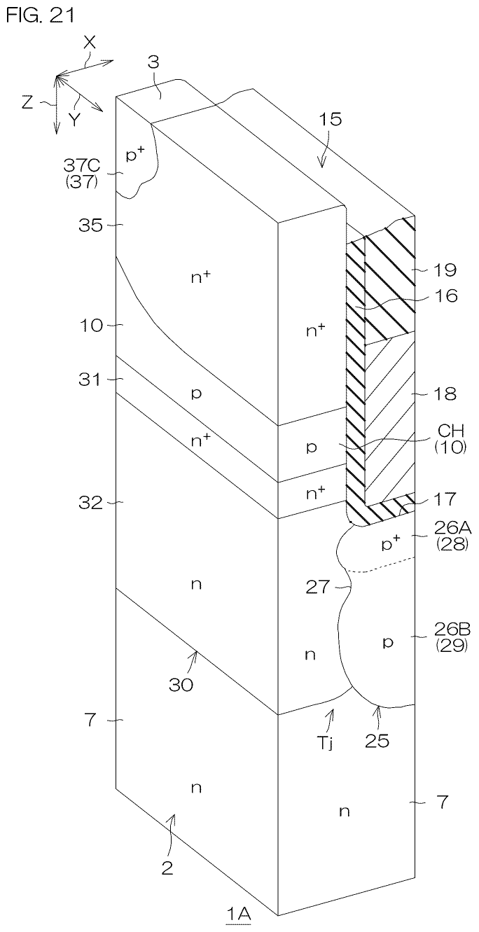

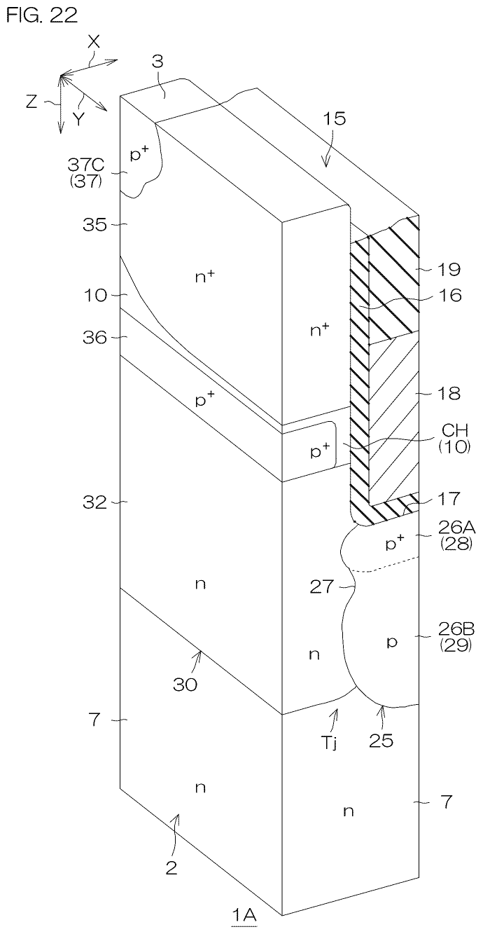

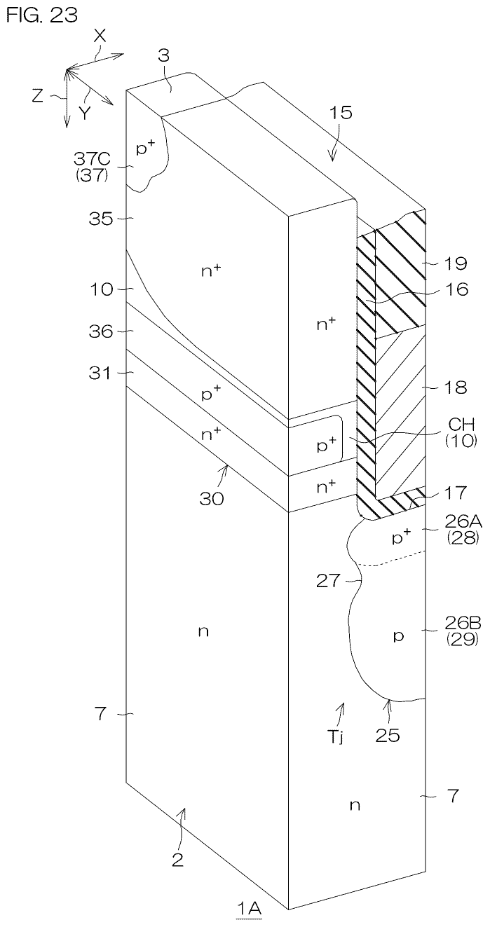

With reference to FIG. 21 (sixth modification example), the semiconductor device 1A does not necessarily have to have the body high concentration region 36. With reference to FIG. 22 (seventh modification example), the semiconductor device 1A does not necessarily have to have the first high concentration region 31. With reference to FIG. 23 (eighth modification example), the semiconductor device 1A does not necessarily have to have the second high concentration region 32.

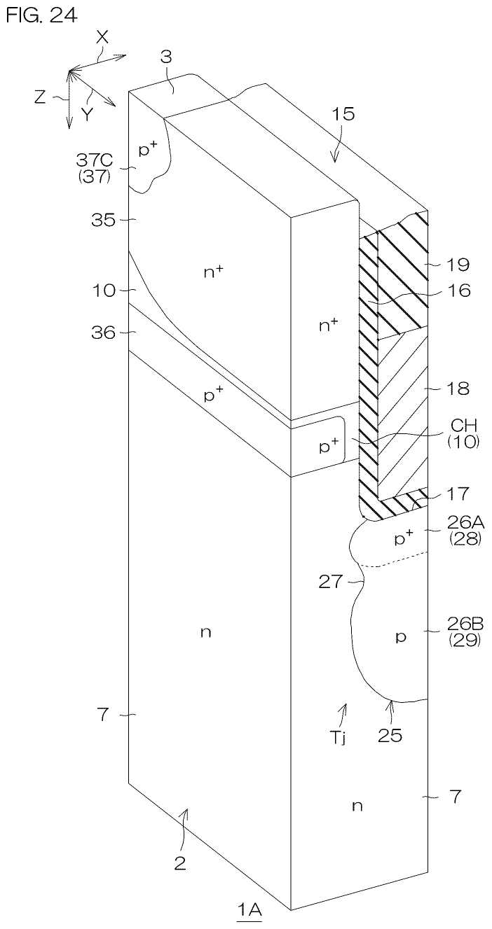

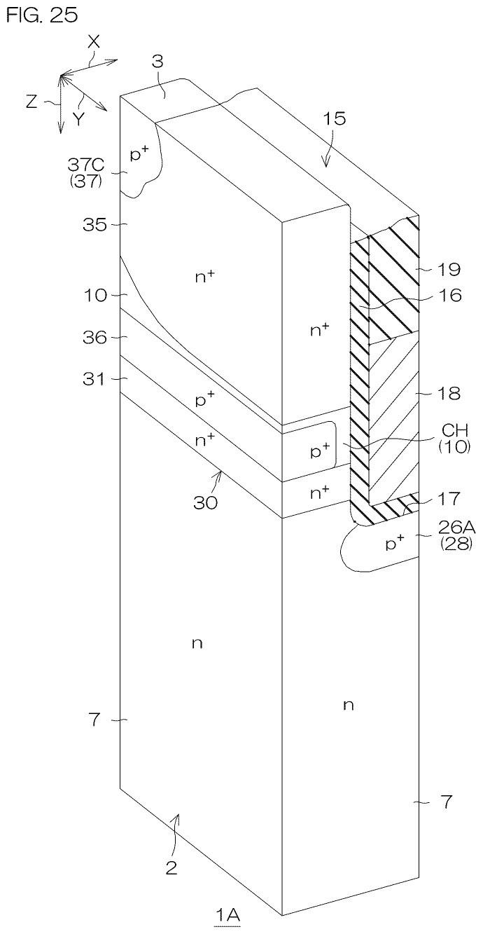

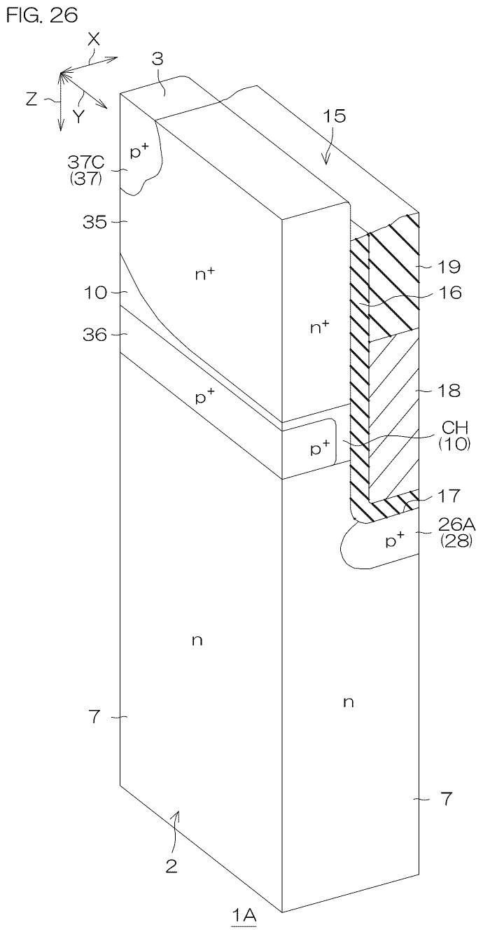

With reference to FIG. 24 (ninth modification example), the semiconductor device 1A does not necessarily have to have the high concentration region 30 (the first high concentration region 31 and the second high concentration region 32). With reference to FIG. 25 (tenth modification example), the semiconductor device 1A does not necessarily have to have the second high concentration region 32 and the second well region 29. With reference to FIG. 26 (eleventh modification example), the semiconductor device 1A does not necessarily have to have the high concentration region 30 (the first high concentration region 31 and the second high concentration region 32) and the second well region 29.

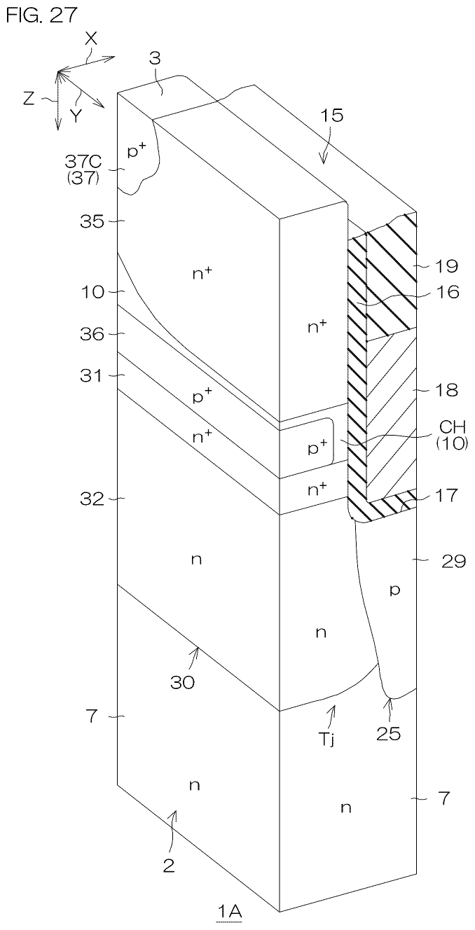

With reference to FIG. 27 (twelfth modification example), the semiconductor device 1A does not necessarily have to have the first well region 28. In this embodiment, the second well region 29 does not have the bulging region 26 and is formed in a shape tapering toward a depth direction. As a matter of course, the second well region 29 may extend in the thickness direction with a substantially fixed width. Also, the second well region 29 may have a width greater than the width of the gate structure 15 and may form the bulging region 26.

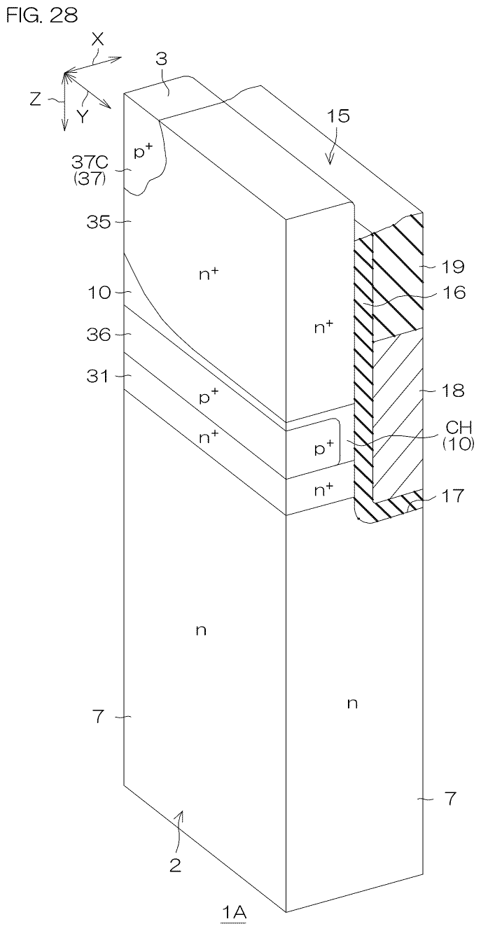

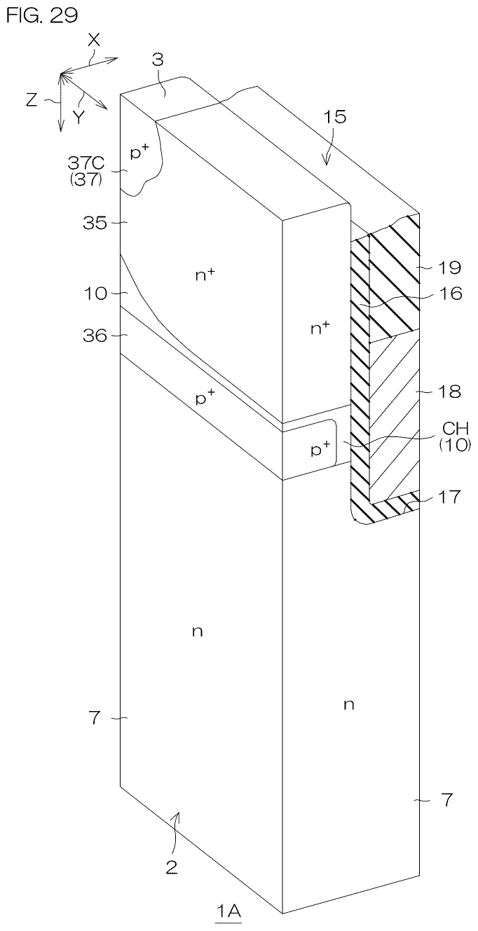

With reference to FIG. 28 (thirteenth modification example), the semiconductor device 1A does not necessarily have to have the second high concentration region 32 and the well region 25 (the first well region 28 and the second well region 29). With reference to FIG. 29 (fourteenth modification example), the semiconductor device 1A does not necessarily have to have the high concentration region 30 (the first high concentration region 31 and the second high concentration region 32) and the well region 25 (the first well region 28 and the second well region 29).

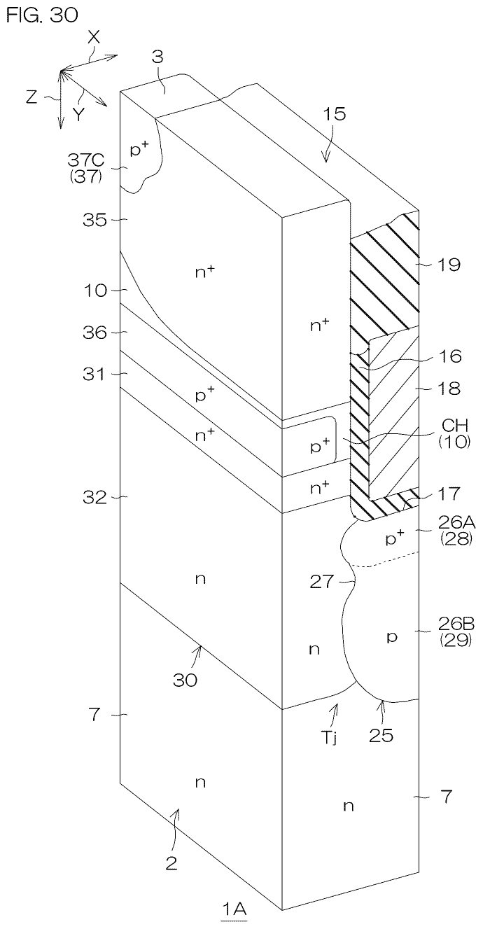

With reference to FIG. 30 (fifteenth modification example), the semiconductor device 1A may include the insulating film 17 having the upper end portion formed at an interval toward a bottom wall side of the trench 16 from a height position of the first main surface 3. The upper end portion of the insulating film 17 may expose the chip 2 from the side wall and the opening end of the trench 16.

The electrode surface of the embedded electrode 18 may project further to the first main surface 3 side than the upper end portion of the insulating film 17. The electrode surface of the embedded electrode 18 may be positioned further to the bottom wall side of the trench 16 than the upper end portion of the insulating film 17. The embedded insulator 19 may be embedded on the upper end portion of the insulating film 17 and the electrode surface of the embedded electrode 18 in the trench 16.

The embedded insulator 19 may cover the upper end portion of the insulating film 17 and the electrode surface of the embedded electrode 18. The embedded insulator 19 may have a portion directly covering the side wall of the trench 16. The body region 10, the source region 35, and the contact region 37 may each have a portion in direct contact with the embedded insulator 19 in a portion along the gate structure 15.

With reference to FIG. 31 (sixteenth modification example), the semiconductor device 1A does not have the embedded insulator 19 in the plurality of gate structures 15. The main surface insulating film 41 selectively covers the first main surface 3 in the active region 8. The main surface insulating film 41 directly covers the first main surface 3 (the plurality of mesa portions 20) in a periphery of the inner portions of the plurality of gate structures 15 and is connected to the plurality of insulating films 17. The main surface insulating film 41 is integrally formed with the plurality of insulating films 17 and is formed as a lead-out portion led out from the plurality of insulating films 17 onto the first main surface 3.

In this embodiment, the interlayer film 43 collectively covers the plurality of gate structures 15 and the main surface insulating film 41 in the active region 8 in a film shape. The interlayer film 43 enters into the trench 16 from above the main surface insulating film 41 and covers the insulating film 17 and the embedded electrode 18 in the trench 16. The interlayer film 43 has a portion covering the plurality of source regions 35 and the plurality of contact regions 37 with the main surface insulating film 41 interposed therebetween.

In this embodiment, the semiconductor device 1A includes a plurality of source openings 44 formed in the interlayer film 43. The plurality of source openings 44 penetrate through the interlayer film 43 and the main surface insulating film 41 and selectively expose the plurality of mesa portions 20. The plurality of source openings 44 may be formed in a one-to-one correspondence with the single mesa portion 20.

In this case, the plurality of source openings 44 are formed in a band shape extending in the second direction Y in conformance to the extension direction of the corresponding mesa portion 20. The plurality of source openings 44 selectively expose the plurality of source regions 35 and the plurality of contact regions 37 from the corresponding mesa portion 20.

As a matter of course, the plurality of source openings 44 may be formed in a multiple-to-one correspondence with the single mesa portion 20. In this case, the plurality of source openings 44 are formed at an interval in conformance to the extension direction of the corresponding mesa portion 20.

The plurality of source openings 44 may be formed in a band shape, a quadrangular shape, a circular shape, etc., extending in the second direction Y. The plurality of source openings 44 selectively expose the plurality of source regions 35 and the plurality of contact regions 37 from the corresponding mesa portion 20.

The source electrode 45 enters into the plurality of source openings 44 from above the interlayer film 43, and is electrically connected to the plurality of source regions 35 and the plurality of contact regions 37 in the plurality of source openings 44.

The source electrode 45 includes the lower electrode film 46 and the main electrode film 47. The lower electrode film 46 has a laminated structure including the first electrode film 48 and the second electrode film 49. As a matter of course, the lower electrode film 46 may have a single layer structure consisting of the first electrode film 48.

The first electrode film 48 collectively covers, in a film shape, a region of the interlayer film 43 in which the plurality of source openings 44 are formed, and enters into the plurality of source openings 44 from above the interlayer film 43. The first electrode film 48 has a portion covering the insulating surface of the interlayer film 43 in a film shape, a portion covering the wall surfaces of the plurality of source openings 44 in a film shape, and a portion covering the first main surface 3 in a film shape in the plurality of source openings 44. The first electrode film 48 is mechanically and electrically connected to the plurality of source regions 35 and the plurality of contact regions 37.

The second electrode film 49 directly covers the first electrode film 48. The second electrode film 49 collectively covers, in a film shape, a region in which the plurality of source openings 44 are formed in the interlayer film 43 with the first electrode film 48 interposed therebetween, and enters into the plurality of source openings 44 from above the interlayer film 43.

The second electrode film 49 has a portion covering the insulating surface of the interlayer film 43 in a film shape with the first electrode film 48 interposed therebetween, a portion covering the wall surfaces of the plurality of source openings 44 in a film shape with the first electrode film 48 interposed therebetween, and a portion covering the first main surface 3 in a film shape with the first electrode film 48 interposed therebetween in the plurality of source openings 44. The second electrode film 49 is electrically connected to the plurality of source regions 35 and the plurality of contact regions 37 via the first electrode film 48 in the source opening 44.

The main electrode film 47 directly covers the lower electrode film 46 (the second electrode film 49). The main electrode film 47 collectively covers, in a film shape, a region of the interlayer film 43 in which the plurality of source openings 44 are formed, and backfills the plurality of source openings 44.

The main electrode film 47 has a portion covering the insulating surface of the interlayer film 43 with the lower electrode film 46 interposed therebetween, a portion covering the wall surfaces of the plurality of source openings 44 with the lower electrode film 46 interposed therebetween, and a portion covering the first main surface 3 with the lower electrode film 46 interposed therebetween. The main electrode film 47 is electrically connected to the plurality of source regions 35 and the plurality of contact regions 37 via the lower electrode film 46 in the plurality of source openings 44.

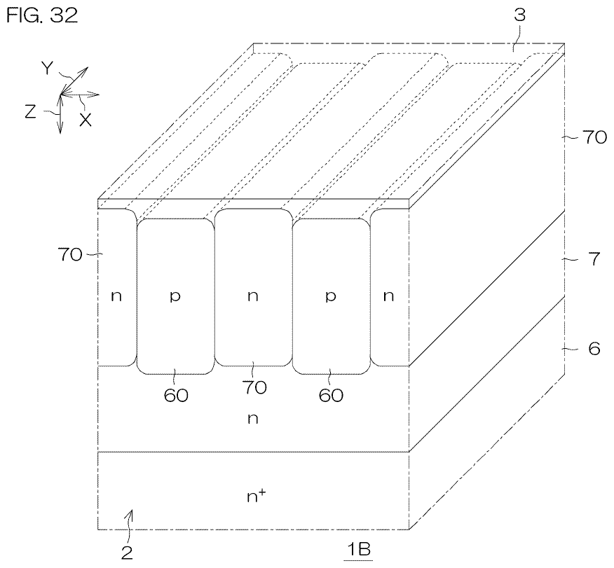

The structure (technical idea) in which the above-described second well region 29 and second high concentration region 32 are formed separately is also applied to other embodiments. Hereinafter, a configuration in which the technical idea of the second well region 29 and the second high concentration region 32 is adopted shall be described as a semiconductor device 1B according to a second embodiment. FIG. 32 is a sectional perspective view illustrating the semiconductor device 1B according to the second embodiment.

In FIG. 32, the semiconductor device 1B may include various device structures. The semiconductor device 1B may have one or a plurality of device structures. The device structure may include at least one among a semiconductor switching device, a semiconductor rectifying device, and a semiconductor passive device. A plurality of device structures may constitute an LSI (large scale integration).

The semiconductor switching device may include at least one among a MISFET (metal insulator semiconductor field effect transistor), a BJT (bipolar junction transistor), an IGBT (insulated gate bipolar junction transistor), and a JFET (junction field effect transistor).

The semiconductor rectifying device may include at least one among a pn-junction diode, a pin-junction diode, a Zener diode, a Schottky barrier diode, and a fast recovery diode. The semiconductor passive device may include at least one among a resistor, a capacitor, an inductor, and a fuse.

As in the case of the semiconductor device 1A, the semiconductor device 1B includes the chip 2, the first semiconductor layer 6, the second semiconductor layer 7, the active region 8, and the outer peripheral region 9. In FIG. 32, a sectional perspective view of a main part of the active region 8 is illustrated. The first semiconductor layer 6 is adjusted in concentration by a base element, and the second semiconductor layer 7 is adjusted in concentration by a first element (nitrogen in this embodiment).

The semiconductor device 1B includes a plurality of well regions 60 of the p-type formed in the chip 2 (the second semiconductor layer 7). The well region 60 is a region corresponding to the above-described second well region 29 (the well region 25). The plurality of well regions 60 have a p-type impurity concentration higher than the n-type impurity concentration of the second semiconductor layer 7, and replace the conductivity type of the second semiconductor layer 7 from the n-type to the p-type.

The plurality of well regions 60 are formed within the second semiconductor layer 7 at intervals from each other in the horizontal direction (the first direction X). The plurality of well regions 60 each extend in a band shape in the second direction Y in plan view. That is, the plurality of well regions 60 are aligned in a stripe shape extending in the second direction Y in plan view.

An extension direction of the plurality of well regions 60 coincides with the off direction of the SiC monocrystal. The plurality of well regions 60 may extend in the first direction X. In this case, the plurality of well regions 60 intersect (specifically, are orthogonal to) the off direction.

The plurality of well regions 60 are formed at an interval toward the first main surface 3 side from the bottom portion of the second semiconductor layer 7, and oppose the first semiconductor layer 6 with a portion of the second semiconductor layer 7 interposed therebetween. The plurality of well regions 60 each has an upper end portion positioned on the first main surface 3 side, and a bottom portion (lower end portion) positioned on the bottom portion side of the second semiconductor layer 7.

In this embodiment, the upper end portions of the plurality of well regions 60 are formed at an interval toward the bottom portion side of the second semiconductor layer 7 from the first main surface 3. The upper end portions of the plurality of well regions 60 may be exposed from the first main surface 3. The upper end portions of the plurality of well regions 60 are positioned on the first main surface 3 side with respect to the depth position of the intermediate portion of the second semiconductor layer 7.

The bottom portions of the plurality of well regions 60 may be positioned on the bottom portion side of the second semiconductor layer 7 (the second main surface 4 side) with respect to the depth position of the intermediate portion of the second semiconductor layer 7, or may be positioned on the first main surface 3 side with respect to the depth position of the intermediate portion of the second semiconductor layer 7. The bottom portions of the plurality of well regions 60 are directly connected to the second semiconductor layer 7. The plurality of well regions 60 form the JFET region Tj together with the second semiconductor layer 7.

The well region 60 may have a depth of not less than 0.5 μm and not more than 5 μm. The depth of the well region 60 may have a value belonging to at least one range among not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The well region 60 may have a width of not less than 0.1 μm and not more than 10 μm. The width of the well region 60 may have a value belonging to at least one range among not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, not less than 4.5 μm and not more than 5 μm, not less than 5 μm and not more than 6 μm, not less than 6 μm and not more than 7 μm, not less than 7 μm and not more than 8 μm, not less than 8 μm and not more than 9 μm, and not less than 9 μm and not more than 10 μm.

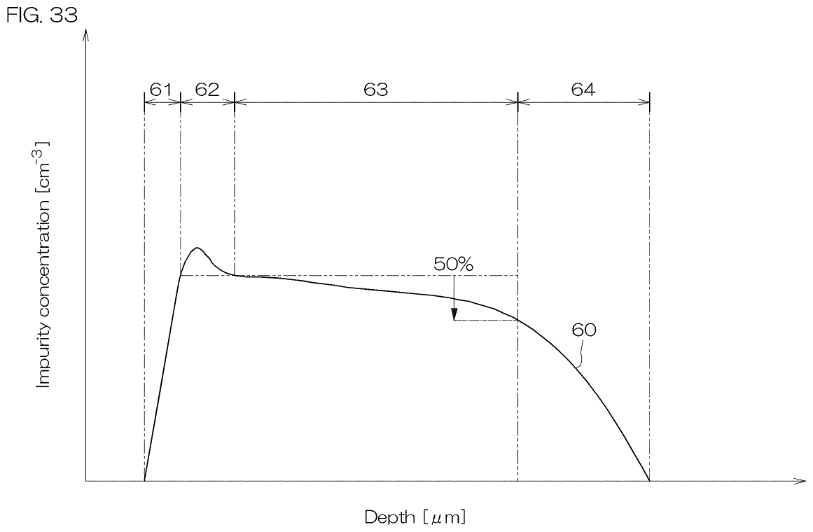

Hereinafter, a concentration gradient of the well region 60 shall be described with reference to FIG. 33. FIG. 33 is a graph illustrating an impurity concentration of the well region 60. In FIG. 33, the ordinate indicates a p-type impurity concentration of the well region 60, and the abscissa indicates a depth.

The well region 60 is formed by introducing a p-type impurity (trivalent element) into the second semiconductor layer 7. The well region 60 has a p-type impurity concentration higher than the n-type impurity concentration of the second semiconductor layer 7, and replaces the conductivity type of the second semiconductor layer 7 from the n-type to the p-type. The well region 60 contains the second element consisting of a trivalent element in addition to a pentavalent element (that is, the first element, nitrogen in this embodiment) of the second semiconductor layer 7.

The second element may include at least one type among boron and aluminum. The well region 60 is preferably adjusted in concentration by a single second element. The second element is preferably aluminum.

The well region 60 has a concentration gradient different from the concentration gradient of the second semiconductor layer 7. The well region 60 is consisting of a channeling region in which a large amount of the trivalent element is dispersed along an axis channel of an SiC monocrystal (the second semiconductor layer 7). That is, in this embodiment, the well region 60 extends along a c-axis of the SiC monocrystal and is inclined at the above-described off direction and off angle.

The concentration gradient of the well region 60 includes, from an upper end portion toward a bottom portion, a first increasing portion 61, a first peak portion 62, a first gently sloping portion 63, and a first decreasing portion 64. The first increasing portion 61 forms the upper end portion of the well region 60 and is a region in which the p-type impurity concentration gradually increases steeply toward the bottom portion.

The first peak portion 62 is consisting of a concentration transition region in which the p-type impurity concentration changes from increase to decrease, and has the maximum value of the p-type impurity concentration. The first peak portion 62 is formed in a region on the upper end portion side of the well region 60 with respect to a depth position of an intermediate portion of the well region 60.

The first gently sloping portion 63 has a concentration decrease rate smaller than a concentration decrease rate of the first peak portion 62 (decrease region), and is a portion that maintains a fixed p-type impurity concentration of a fixed depth range. The first gently sloping portion 63 forms the intermediate portion of the well region 60 as a main body portion of the well region 60.

The p-type impurity concentration of the first gently sloping portion 63 gradually decreases gently (monotonically decreases in this embodiment) in a concentration range lower than the p-type impurity concentration of the first peak portion 62. That is, the first gently sloping portion 63 does not have a concentration gradient that steeply increases with the first peak portion 62 as a starting point as a starting point.

The first gently sloping portion 63 may have a concentration decrease rate of not more than 50% over a depth range of at least 0.25 μm. The first gently sloping portion 63 may have a concentration decrease rate of not more than 50% over a depth range of at least 0.5 μm. The first gently sloping portion 63 may have a concentration decrease rate of not more than 50% over a thickness range of 25% of the well region 60. The first gently sloping portion 63 may have a concentration decrease rate of not more than 50% over a thickness range of 50% of the well region 60.

The first decreasing portion 64 forms the bottom portion of the well region 60 and is a region in which the p-type impurity concentration gradually decreases steeply (monotonically decreases in this embodiment) from the first gently sloping portion 63 toward the bottom portion. The first decreasing portion 64 has a concentration decrease rate greater than a concentration decrease rate of the first gently sloping portion 63. The concentration decrease rate per unit depth of the first decreasing portion 64 is greater than a concentration decrease rate per unit depth of the first gently sloping portion 63. The first decreasing portion 64, which has the lowest p-type impurity concentration of the well region 60, is directly connected to the second semiconductor layer 7.

The semiconductor device 1B includes a plurality of high concentration regions 70 of the n-type formed in the chip 2 (the second semiconductor layer 7). The high concentration regions 70 correspond to the above-described second high concentration region 32 (the high concentration region 30). The plurality of high concentration regions 70 have an n-type impurity concentration higher than the n-type impurity concentration of the second semiconductor layer 7, and increase the n-type impurity concentration of the second semiconductor layer 7.

The plurality of high concentration regions 70 may be regarded as high concentration portions of the second semiconductor layer 7. The n-type impurity concentration of the plurality of high concentration regions 70 may be appropriately compared by comparison with the n-type impurity concentration on the bottom portion side of the second semiconductor layer 7. The high concentration regions 70 may be referred to as “high concentration drift regions.”

The plurality of high concentration regions 70 are formed within the second semiconductor layer 7 at intervals from each other in the horizontal direction (the first direction X). The plurality of high concentration regions 70 each extend in a band shape in the second direction Y in plan view. That is, the plurality of high concentration regions 70 are aligned in a stripe shape extending in the second direction Y in plan view.

An extension direction of the plurality of high concentration regions 70 coincides with the off direction of the SiC monocrystal. The plurality of high concentration regions 70 may extend in the first direction X. In this case, the plurality of high concentration regions 70 intersect (specifically, are orthogonal to) the off direction.

The plurality of high concentration regions 70 are respectively formed in regions between the plurality of well regions 60 and are electrically connected to the plurality of well regions 60 positioned on both sides, respectively. The plurality of high concentration regions 70 are formed at an interval toward the first main surface 3 side from the bottom portion of the second semiconductor layer 7, and oppose the first semiconductor layer 6 with a portion of the second semiconductor layer 7 interposed therebetween.

The plurality of high concentration regions 70 each has an upper end portion positioned on the first main surface 3 side, and a bottom portion (lower end portion) positioned on the bottom portion side of the second semiconductor layer 7. In this embodiment, the upper end portions of the plurality of high concentration regions 70 are formed at an interval toward the bottom portion side of the second semiconductor layer 7 from the first main surface 3.

The upper end portions of the plurality of high concentration regions 70 may be positioned on the first main surface 3 side with respect to depth position of the upper end portions of the plurality of well regions 60, or may be positioned on the bottom portion side of the second semiconductor layer 7 with respect to the depths position of the upper end portions of the plurality of well regions 60. The upper end portions of the plurality of high concentration regions 70 may be exposed from the first main surface 3. The upper end portions of the plurality of high concentration regions 70 are positioned on the first main surface 3 side with respect to the depth position of the intermediate portion of the second semiconductor layer 7.

The bottom portions of the plurality of high concentration regions 70 may be positioned on the bottom portion side of the second semiconductor layer 7 (the second main surface 4 side) with respect to the depth position of the intermediate portion of the second semiconductor layer 7, or may be positioned on the first main surface 3 side with respect to the depth position of the intermediate portion of the second semiconductor layer 7.

In this embodiment, the bottom portions of the plurality of high concentration regions 70 are positioned on the first main surface 3 side with respect to depth positions of the bottom portions of the plurality of well regions 60. That is, the bottom portions of the plurality of high concentration regions 70 are formed at an interval toward the first main surface 3 side from the bottom portions of the well regions 60, and maintain a configuration in which the well regions 60 are directly connected to the second semiconductor layer 7. The bottom portions of the plurality of high concentration regions 70 are connected to the well regions 60 in regions on the bottom portion side with respect to the depth positions of the intermediate portions of the plurality of well regions 60.

The plurality of high concentration regions 70 may be formed deeper than the plurality of well regions 60 (see also FIG. 16). That is, the bottom portions of the plurality of high concentration regions 70 may be positioned on the bottom portion side of the second semiconductor layer 7 with respect to the depth positions of the bottom portions of the plurality of well regions 60. In this case, the bottom portions of the plurality of high concentration regions 70 may overlap the bottom portions of the plurality of well regions 60. In this case, the bottom portions of the plurality of high concentration regions 70 preferably partially overlap bottom portions of the plurality of well regions 60.

That is, the bottom portions of the plurality of high concentration regions 70 are preferably formed at intervals from each other in regions below the bottom portions of the plurality of well regions 60, and oppose each other in the horizontal direction with a portion of the second semiconductor layer 7 interposed therebetween. In other words, the bottom portions of the plurality of high concentration regions 70 preferably leave direct connection portions of the plurality of well regions 60 with respect to the second semiconductor layer 7 without overlapping an entirety of the bottom portions of the plurality of well regions 60.

The high concentration region 70 may have a width substantially equal to a width of the well region 60. The width of the high concentration region 70 may be smaller than the width of the well region 60. The width of the high concentration region 70 may be greater than the width of the well region 60.

The width of the high concentration region 70 may be not less than 0.1 μm and not more than 5 μm. The width of the high concentration region 70 may have a value belonging to at least one range among not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The high concentration region 70 may have a depth substantially equal to a depth of the well region 60. The depth of the high concentration region 70 may be smaller than the depth of the well region 60. The depth of the high concentration region 70 may be greater than the depth of the well region 60.

The depth of the high concentration region 70 may be not less than 0.1 μm and not more than 10 μm. The depth of the high concentration region 70 may have a value belonging to at least one range among not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, not less than 4.5 μm and not more than 5 μm, not less than 5 μm and not more than 6 μm, not less than 6 μm and not more than 7 μm, not less than 7 μm and not more than 8 μm, not less than 8 μm and not more than 9 μm, and not less than 9 μm and not more than 10 μm.

The plurality of high concentration regions 70 respectively form pn-junction portions with the plurality of well regions 60. The bottom portions of the plurality of high concentration regions 70 form the JFET region Tj together with the plurality of well regions 60. The plurality of high concentration regions 70 may form a charge balance with the plurality of well regions 60.

According to this configuration, the plurality of high concentration regions 70 constitute a super junction structure together with the plurality of well regions 60. The plurality of high concentration regions 70 do not necessarily have to constitute a super junction structure with the plurality of well regions 60 and may suffice to form a body diode structure.

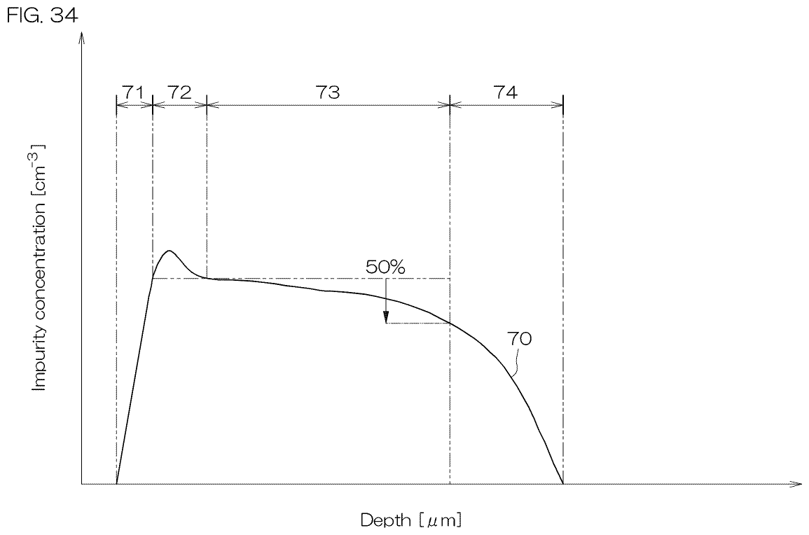

Hereinafter, a concentration gradient of the high concentration region 70 shall be described with reference to FIG. 34. FIG. 34 is a graph illustrating an impurity concentration of the high concentration regions 70. In FIG. 34, the ordinate indicates an n-type impurity concentration of the high concentration regions 70, and the abscissa indicates a depth.

The high concentration region 70 is formed by introducing an n-type impurity (pentavalent element) into the second semiconductor layer 7. The n-type impurity concentration of the high concentration region 70 may be higher than the p-type impurity concentration of the well region 60 or may be lower than the p-type impurity concentration of the well region 60.

The high concentration region 70 contains the third element consisting of a pentavalent element in addition to a pentavalent element (that is, a first element, nitrogen in this embodiment) of the second semiconductor layer 7. The third element is an additional pentavalent element with respect to the first element of the second semiconductor layer 7. The third element may include at least one type among nitrogen, phosphorus, and arsenic.

The third element of the high concentration region 70 may be of the same type as the first element of the second semiconductor layer 7 or may be of a different type from the first element of the second semiconductor layer 7. The third element is preferably different from the first element. That is, the high concentration region 70 preferably contains a plurality of types of pentavalent elements. The high concentration region 70 is preferably adjusted in concentration by a single third element. The third element is preferably phosphorus. That is, the high concentration region 70 is preferably adjusted in concentration by nitrogen and phosphorus.

An impurity concentration of the high concentration region 70 is separated from the impurity concentration of the well region 60. The concentration of the second element (trivalent element) of the well region 60 in the high concentration region 70 is lower than the concentration of the second element in the well region 60. The high concentration region 70 does not contain the second element of the well region 60. The expression “the high concentration region 70 does not contain the second element” means that a concentration of the second element in an inner portion of the high concentration region 70 is lower than a detection limit and is at a noise level even if detected.

Similarly, a concentration of the third element of the high concentration region 70 in the well region 60 is lower than a concentration of the third element in the high concentration region 70. The well region 60 does not contain the third element of the high concentration region 70. The expression “the well region 60 does not contain the third element” means that a concentration of the third element in an inner portion of the well region 60 is lower than a detection limit and is at a noise level even if detected.

The high concentration region 70 has a concentration gradient different from the concentration gradient of the second semiconductor layer 7. The high concentration region 70 is consisting of a channeling region in which a large amount of the pentavalent element is dispersed along the axis channel of an SiC monocrystal (the second semiconductor layer 7). That is, in this embodiment, the high concentration region 70 extends along a c-axis of the SiC monocrystal and is inclined at the above-described off direction and off angle.

The concentration gradient of the high concentration region 70 includes, from an upper end portion toward a bottom portion, a second increasing portion 71, a second peak portion 72, a second gently sloping portion 73, and a second decreasing portion 74. The second increasing portion 71 forms the upper end portion of the high concentration region 70 and is a region in which the n-type impurity concentration gradually increases steeply toward the bottom portion.

The second increasing portion 71 may be connected to the first increasing portion 61 of the well region 60. The second increasing portion 71 may be formed at a depth position substantially equal to the first increasing portion 61. The second increasing portion 71 may be positioned on the first main surface 3 side with respect to a depth position of the first increasing portion 61, or may be positioned on the bottom portion side of the second semiconductor layer 7.

The second peak portion 72 is consisting of a concentration transition region in which the n-type impurity concentration changes from increase to decrease, and has the maximum value of the n-type impurity concentration. The second peak portion 72 is formed in a region on the upper end portion side of the high concentration region 70 with respect to a depth position of an intermediate portion of the high concentration region 70.

The second peak portion 72 may be connected to the first peak portion 62 of the well region 60. The second peak portion 72 may be formed at a depth position substantially equal to the first peak portion 62. The second peak portion 72 may be positioned on the first main surface 3 side with respect to a depth position of the first peak portion 62, or may be positioned on the bottom portion side of the second semiconductor layer 7.

The second gently sloping portion 73 has a concentration decrease rate smaller than the concentration decrease rate of the second peak portion 72 (decrease region), and is a portion that maintains a fixed n-type impurity concentration of a fixed depth range. The second gently sloping portion 73 forms the intermediate portion of the high concentration region 70 as a main body portion of the high concentration region 70.

The n-type impurity concentration of the second gently sloping portion 73 gradually decreases gently (monotonically decreases in this embodiment) in a concentration range lower than the n-type impurity concentration of the second peak portion 72. That is, the second gently sloping portion 73 does not have a concentration gradient that steeply increases with the second peak portion 72 as a starting point.

The second gently sloping portion 73 may have a concentration decrease rate of not more than 50% over a depth range of at least 0.25 μm. The second gently sloping portion 73 may have a concentration decrease rate of not more than 50% over a depth range of at least 0.5 μm. The second gently sloping portion 73 may have a concentration decrease rate of not more than 50% over a thickness range of 25% of the high concentration region 70. The second gently sloping portion 73 may have a concentration decrease rate of not more than 50% over a thickness range of 50% of the high concentration region 70.

The second gently sloping portion 73 may be connected to the first gently sloping portion 63 of the well region 60. The second gently sloping portion 73 may be formed at a depth position substantially equal to the first gently sloping portion 63. The second gently sloping portion 73 may be positioned on the first main surface 3 side with respect to a depth position of the first gently sloping portion 63, or may be positioned on the bottom portion side of the second semiconductor layer 7.

The second decreasing portion 74 forms the bottom portion of the high concentration region 70 and is a region in which the n-type impurity concentration gradually decreases steeply (monotonically decreases in this embodiment) from the second gently sloping portion 73 toward the bottom portion. The second decreasing portion 74 has a concentration decrease rate greater than the concentration decrease rate of the second gently sloping portion 73. The concentration decrease rate per unit depth of the second decreasing portion 74 is greater than a concentration decrease rate per unit depth of the second gently sloping portion 73. The second decreasing portion 74, which has the lowest n-type impurity concentration of the high concentration region 70, is directly connected to the second semiconductor layer 7.

The second decreasing portion 74 may be connected to the first decreasing portion 64 of the well region 60. The second decreasing portion 74 may be formed at a depth position substantially equal to the first decreasing portion 64. The second decreasing portion 74 may be positioned on the first main surface 3 side with respect to a depth position of the first decreasing portion 64, or may be positioned on the bottom portion side of the second semiconductor layer 7.

As described above, the semiconductor device 1B may include the second semiconductor layer 7 of the n-type (the semiconductor layer), the well region 60 of the p-type (the well region 60), and the high concentration region 70 of the n-type. The well region 60 may be formed to be of a higher concentration than the second semiconductor layer 7 within the second semiconductor layer 7. The high concentration region 70 may be formed to be of a higher concentration than the second semiconductor layer 7 within the second semiconductor layer 7. The high concentration region 70 may form a pn-junction portion with the well region 60.

According to this configuration, the semiconductor device 1B having a novel layout can be provided. For example, according to this semiconductor device 1B, the high concentration region 70 forms the JFET region Tj together with the well region 60. Accordingly, the breakdown voltage can be appropriately improved by the JFET region Tj.

The second semiconductor layer 7 may contain SiC. According to this configuration, the semiconductor device 1B as an SiC semiconductor device having a novel layout can be provided. According to the semiconductor device 1B, the withstand voltage is further improved by the physical properties of SiC. In particular, in the case of the SiC semiconductor device, since the SiC semiconductor device is used in a relatively high voltage environment, an effect of improving a breakdown voltage by the JFET region Tj including the well region 60 and the high concentration region 70 is effective.

The well region 60 may have a p-type impurity concentration separated from an n-type impurity concentration of the high concentration region 70. According to this configuration, the p-type impurity concentration of the well region 60 is appropriately adjusted, and the JFET region Tj is appropriately formed. Accordingly, the breakdown voltage can be appropriately improved by the JFET region Tj.

The high concentration region 70 may have an impurity concentration separated from an impurity concentration of the well region 60. According to this configuration, the n-type impurity concentration of the high concentration region 70 is appropriately adjusted, and the JFET region Tj is appropriately formed. Accordingly, the breakdown voltage can be appropriately improved by the JFET region Tj.

The second semiconductor layer 7 may be adjusted in concentration by the first element consisting of the pentavalent element. The well region 60 may be adjusted in concentration by the second element consisting of the trivalent element in addition to the first element. The high concentration region 70 may be adjusted in concentration by the third element consisting of the pentavalent element in addition to the first element.

The concentration of the third element in the well region 60 may be less than the concentration of the third element in the high concentration region 70. According to this configuration, the p-type impurity concentration of the well region 60 can be appropriately separated from the n-type impurity concentration of the high concentration region 70. In this case, the inner portion of the well region 60 does not have to contain the third element.

The concentration of the second element in the high concentration region 70 may be less than the concentration of the second element in the well region 60. According to this configuration, the n-type impurity concentration of the high concentration region 70 can be appropriately separated from the p-type impurity concentration of the well region 60. In this case, the inner portion of the high concentration region 70 does not have to contain the second element.

The first element may include at least one type among nitrogen, phosphorus, and arsenic. The first element may consist of a single pentavalent element. The first element may be nitrogen.

The third element may include at least one type among boron and aluminum. The third element may consist of a single trivalent element. The third element may be aluminum.

The fifth element may include at least one type among nitrogen, phosphorus, and arsenic. The fifth element may be the same type as the first element. The fifth element may be a different type from the first element. The fifth element may consist of a single pentavalent element. The fifth element may be phosphorus.

The high concentration region 70 may have a bottom portion positioned higher than the depth position of the bottom portion of the well region 60. The high concentration region 70 may have a bottom portion positioned lower than the bottom portion of the well region 60. The depth of the high concentration region 70 is adjusted as appropriate in accordance with the JFET region Tj to be achieved.

The high concentration region 70 may form a super junction structure with the well region 60. According to this configuration, a breakdown voltage can be appropriately improved by the super junction structure.

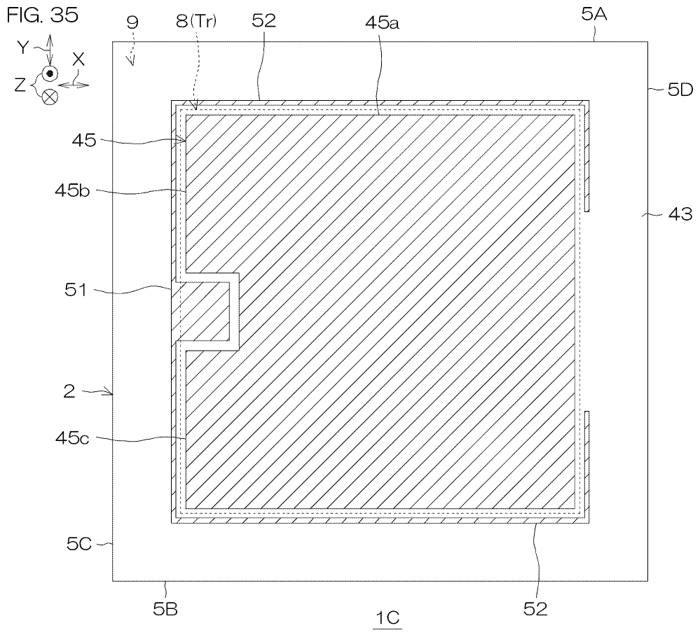

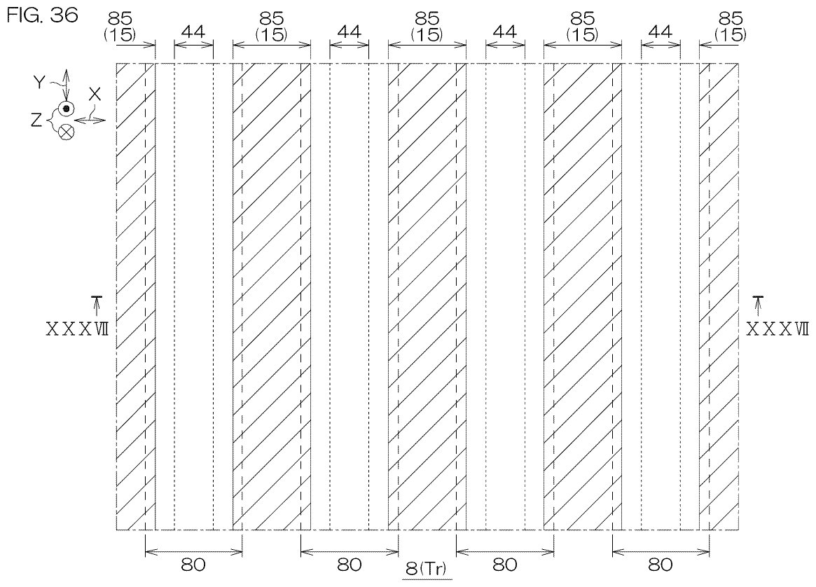

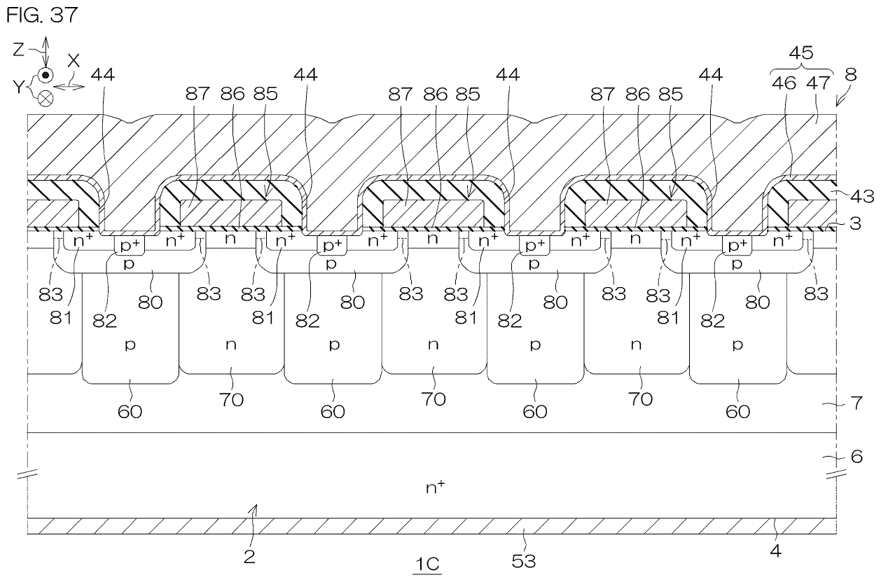

FIG. 35 is a plan view illustrating a semiconductor device 1C according to a third embodiment. FIG. 36 is an enlarged plan view illustrating one main portion of the active region 8 illustrated in FIG. 35. FIG. 37 is a sectional view taken along line XXXVII-XXXVII illustrated in FIG. 36.

The semiconductor device 1C has a form in which a configuration of the semiconductor device 1B (the well region 60 and the high concentration region 70) is combined with a planar gate structure in a transistor structure Tr of a planar gate type as an example of a device structure. As in the case of the semiconductor device 1A, the semiconductor device 1C includes the chip 2, the first semiconductor layer 6, the second semiconductor layer 7, the active region 8, and the outer peripheral region 9.

The semiconductor device 1C includes a plurality of body regions 80 of the p-type formed in the surface layer portion of the first main surface 3 in the active region 8. The plurality of body regions 80 are aligned at intervals in the first direction X and respectively extend in a band shape in the second direction Y. That is, the plurality of body regions 80 are aligned in a stripe shape extending in the second direction Y. An extension direction of the plurality of body regions 80 coincides with the off direction of the SiC monocrystal.

As a matter of course, the plurality of body regions 80 may be aligned at intervals in the second direction Y and respectively extend in a band shape in the first direction X. In this case, the extension direction of the plurality of body regions 80 intersects (is orthogonal to) the off direction of the SiC monocrystal.

The plurality of body regions 80 are formed at an interval toward the first main surface 3 side from the bottom portion of the second semiconductor layer 7, and oppose the first semiconductor layer 6 with a portion of the second semiconductor layer 7 interposed therebetween. The plurality of body regions 80 are preferably formed at an interval toward the first main surface 3 side from a depth position of the intermediate portion of the second semiconductor layer 7. The plurality of body regions 80 are exposed from the first main surface 3.

The semiconductor device 1C includes a plurality of source regions 81 (impurity regions) of the n-type respectively formed in surface layer portions of the plurality of body regions 80. The plurality of source regions 81 respectively have an n-type impurity concentration higher than a p-type impurity concentration of the plurality of body regions 80 and replace a conductivity type of the corresponding body regions 80 from p-type to n-type. The n-type impurity concentration of the plurality of source regions 81 is higher than an n-type impurity concentration of the second semiconductor layer 7.

In this embodiment, the plurality of source regions 81 are respectively formed in a one-to-one correspondence with the plurality of body regions 80. The plurality of source regions 81 are formed at an interval inward from both sides in the first direction X of the corresponding body regions 80 and extend in a band shape along an extension direction (the second direction Y) of the corresponding body regions 80. As a matter of course, when the extension direction of the plurality of body regions 80 is the first direction X, the plurality of source regions 81 may respectively extend in a band shape in the first direction X.

The plurality of source regions 81 are formed at an interval toward the first main surface 3 side from bottom portions of the corresponding body regions 80, and oppose the second semiconductor layer 7 in a thickness direction with a portion of the corresponding body regions 80 interposed therebetween. The plurality of source regions 81 are exposed from the first main surface 3.

The semiconductor device 1C includes a plurality of contact regions 82 of the p-type respectively formed in the surface layer portions of the plurality of body regions 80. The contact regions 82 have a p-type impurity concentration higher than the p-type impurity concentration of the body region 80.

In this embodiment, the plurality of contact regions 82 are respectively formed in a one-to-one correspondence with the plurality of body regions 80. The plurality of contact regions 82 are formed at an interval inward from both sides in the first direction X of the corresponding body regions 80 and extend in a band shape along an extension direction (the second direction Y) of the corresponding body regions 80. As a matter of course, when the extension direction of the plurality of body regions 80 is the first direction X, the plurality of source regions 81 may respectively extend in a band shape in the first direction X.

The plurality of contact regions 82 are formed in the surface layer portions of the corresponding body regions 80 so as to penetrate through inner portions (central portions in this embodiment) of the corresponding source regions 81. The plurality of contact regions 82 each has a depth greater than a depth of the source regions 81 and are directly connected to the corresponding body regions 80.

The plurality of contact regions 82 are formed at an interval toward the first main surface 3 side from the bottom portions of the corresponding body regions 80, and oppose the second semiconductor layer 7 in a thickness direction with a portion of the corresponding body regions 80 interposed therebetween. The plurality of contact regions 82 are exposed from the first main surface 3.

The semiconductor device 1C includes the plurality of well regions 60 of the p-type formed in the chip 2 (the second semiconductor layer 7). The plurality of well regions 60 are respectively formed in regions below (specifically, directly below) the plurality of body regions 80 at intervals therebetween in the horizontal direction (the first direction X) within the second semiconductor layer 7.

The plurality of well regions 60 are respectively formed in a thickness range between the bottom portion of the second semiconductor layer 7 and the bottom portions of the plurality of body regions 80, and overlap the plurality of body regions 80 in a one-to-one correspondence in the thickness direction.

The plurality of well regions 60 each extends in a band shape in the second direction Y in conformance to the extension direction of the corresponding body region 80 in plan view. That is, the plurality of well regions 60 are aligned in a stripe shape extending in the second direction Y in plan view. The extension direction of the plurality of well regions 60 coincides with the off direction of the SiC monocrystal. The plurality of well regions 60 may extend in the first direction X in accordance with the extension direction of the plurality of body regions 80. In this case, the plurality of body regions 80 intersect (specifically, are orthogonal to) the off direction.

The plurality of well regions 60 are formed at an interval toward the first main surface 3 side from the bottom portion of the second semiconductor layer 7, and oppose the first semiconductor layer 6 with a portion of the second semiconductor layer 7 interposed therebetween. The plurality of well regions 60 each has an upper end portion positioned on the first main surface 3 side, and the bottom portion (the lower end portion) positioned on the bottom portion side of the second semiconductor layer 7.

In this embodiment, the upper end portions of the plurality of well regions 60 are connected to the corresponding body regions 80. The bottom portions of the plurality of well regions 60 may be positioned on the bottom portion side of the second semiconductor layer 7 (the second main surface 4 side) with respect to the depth position of the intermediate portion of the second semiconductor layer 7, or may be positioned on the first main surface 3 side with respect to the depth position of the intermediate portion of the second semiconductor layer 7. The bottom portions of the plurality of well regions 60 are directly connected to the second semiconductor layer 7. The plurality of well regions 60 form the JFET region Tj together with the second semiconductor layer 7 in regions below the body regions 80.

The semiconductor device 1C includes the plurality of high concentration regions 70 of the n-type formed in the chip 2 (the second semiconductor layer 7). The plurality of high concentration regions 70 are respectively formed in regions between the plurality of well regions 60 at intervals from each other in the horizontal direction (the first direction X) within the second semiconductor layer 7. The plurality of high concentration regions 70 are respectively formed in a thickness range between a bottom portion of the second semiconductor layer 7 and the bottom portions of the plurality of body regions 80.

The plurality of high concentration regions 70 each extend in a band shape in the second direction Y in conformance to the extension direction of the plurality of well regions 60 in plan view. That is, the plurality of high concentration regions 70 are aligned in a stripe shape extending in the second direction Y in plan view. The extension direction of the plurality of high concentration regions 70 coincides with the off direction of the SiC monocrystal. The plurality of high concentration regions 70 may extend in the first direction X in accordance with the extension direction of the plurality of well regions 60. In this case, the plurality of high concentration regions 70 intersect (specifically, are orthogonal to) the off direction.

The plurality of high concentration regions 70 are electrically connected to the plurality of well regions 60 positioned on both sides, respectively. The plurality of high concentration regions 70 are formed at an interval toward the first main surface 3 side from the bottom portion of the second semiconductor layer 7, and oppose the first semiconductor layer 6 with a portion of the second semiconductor layer 7 interposed therebetween. The plurality of high concentration regions 70 each has an upper end portion positioned on the first main surface 3 side, and the bottom portion (the lower end portion) positioned on the bottom portion side of the second semiconductor layer 7.

In this embodiment, the upper end portions of the plurality of high concentration regions 70 are formed at an interval toward the bottom portion side of the second semiconductor layer 7 from the first main surface 3. The upper end portions of the plurality of high concentration regions 70 may be positioned on the first main surface 3 side with respect to the depth position of the bottom portions of the plurality of body regions 80, or may be positioned on the bottom portion side of the second semiconductor layer 7 with respect to the depth position of the bottom portions of the plurality of body regions 80. The upper end portions of the plurality of high concentration regions 70 may be exposed from the first main surface 3.

The bottom portions of the plurality of high concentration regions 70 may be positioned on the bottom portion side of the second semiconductor layer 7 (the second main surface 4 side) with respect to the depth position of the intermediate portion of the second semiconductor layer 7, or may be positioned on the first main surface 3 side with respect to the depth position of the intermediate portion of the second semiconductor layer 7.

In this embodiment, the bottom portions of the plurality of high concentration regions 70 are positioned on the first main surface 3 side with respect to the depth positions of the bottom portions of the plurality of well regions 60. That is, the bottom portions of the plurality of high concentration regions 70 are formed at an interval toward the first main surface 3 side from the bottom portions of the well regions 60, and maintain a configuration in which the well regions 60 are directly connected to the second semiconductor layer 7. The bottom portions of the plurality of high concentration regions 70 are connected to the well regions 60 in regions on the bottom portion side with respect to the depth positions of the intermediate portions of the plurality of well regions 60.

The plurality of high concentration regions 70 may be formed deeper than the plurality of well regions 60 (see also FIG. 16). That is, the bottom portions of the plurality of high concentration regions 70 may be positioned on the bottom portion side of the second semiconductor layer 7 with respect to the depth positions of the bottom portions of the plurality of well regions 60. In this case, the bottom portions of the plurality of high concentration regions 70 may overlap the bottom portions of the plurality of well regions 60. In this case, the bottom portions of the plurality of high concentration regions 70 preferably partially overlap bottom portions of the plurality of well regions 60.

That is, the bottom portions of the plurality of high concentration regions 70 are preferably formed at intervals from each other in regions lower than the bottom portions of the plurality of well regions 60, and oppose each other in the horizontal direction with a portion of the second semiconductor layer 7 interposed therebetween. In other words, the bottom portions of the plurality of high concentration regions 70 preferably leave direct connection portions of the plurality of well regions 60 with respect to the second semiconductor layer 7 without overlapping an entirety of the bottom portions of the plurality of well regions 60.

The plurality of high concentration regions 70 respectively form pn-junction portions with the plurality of well regions 60. The bottom portions of the plurality of high concentration regions 70 form the JFET region Tj together with the plurality of well regions 60. The plurality of high concentration regions 70 may form a charge balance with the plurality of well regions 60.

According to this configuration, the plurality of high concentration regions 70 constitute a super junction structure together with the plurality of well regions 60. The plurality of high concentration regions 70 do not necessarily have to constitute a super junction structure with the plurality of well regions 60 and may suffice to form a body diode structure.

The semiconductor device 1C includes a plurality of channel regions 83 of the p-type that are demarcated in the surface layer portions of the plurality of body regions 80. The plurality of channel regions 83 are demarcated in regions between the plurality of source regions 81 and the second semiconductor layer 7 (the high concentration regions 70) in the surface layer portions of the plurality of body regions 80. The plurality of channel regions 83 form current paths extending in the horizontal direction along the first main surface 3.

The semiconductor device 1C includes a plurality of gate structures 85 of a planar type arranged on the first main surface 3 in the active region 8. The plurality of gate structures 85 are respectively arranged on both sides of the plurality of body regions 80 on the first main surface 3 and oppose the plurality of high concentration regions 70 in a thickness direction.

The plurality of gate structures 85 are aligned at intervals in the first direction X, and respectively formed in a band shape extending in the second direction Y. That is, the plurality of gate structures 85 are aligned in a stripe shape extending in the second direction Y. Also, an extension direction of the plurality of gate structures 85 coincides with the off direction of the SiC monocrystal. As a matter of course, when the extension direction of the plurality of body regions 80 is the first direction X, the plurality of gate structures 85 may respectively extend in a band shape in the first direction X.

The plurality of gate structures 85 each cover the at least one channel region 83 (a peripheral edge portion of the body region 80). The plurality of gate structures 85 are positioned on the at least one channel region 83 and respectively cover the peripheral edge portion of the at least one body region 80, the at least one source region 81, and the single high concentration region 70.

In this embodiment, the plurality of gate structures 85 cross the single high concentration region 70 in the first direction X and extend across the peripheral edge portions of the two adjacent body regions 80. Specifically, the plurality of gate structures 85 extend across a peripheral edge portion of the source region 81 of the body region 80 on one side and a peripheral edge portion of the source region 81 of the body region 80 on the other side, and respectively cover the two source regions 81, the single high concentration region 70, and the two channel regions 83. The plurality of gate structures 85 expose the plurality of source regions 81 and the plurality of contact regions 82.

The plurality of gate structures 85 each have a laminated structure including an insulating film 86 and a planar electrode 87. The insulating film 86 may be referred to as a “gate insulating film,” and the planar electrode 87 may be referred to as a “gate electrode.”

The plurality of insulating films 86 may include at least one among a silicon oxide film, a silicon nitride film, and a silicon oxynitride film. In this embodiment, the plurality of insulating films 86 have a single layer structure consisting of a silicon oxide film. The plurality of insulating films 86 preferably include the silicon oxide film consisting of the oxide of the chip 2.

The plurality of insulating films 86 are respectively arranged on both sides of the plurality of body regions 80 on the first main surface 3 and cover the first main surface 3 in a film shape. The plurality of insulating films 86 are aligned at intervals in the first direction X and are respectively formed in a band shape extending in the second direction Y along the body regions 80. That is, the plurality of insulating films 86 are aligned in a stripe shape extending in the second direction Y. Also, an extension direction of the plurality of insulating films 86 coincides with the off direction of the SiC monocrystal.

The plurality of insulating films 86 each cover the at least one channel region 83 (the peripheral edge portion of the body region 80). The plurality of insulating films 86 are positioned on the at least one channel region 83 and respectively cover the peripheral edge portion of the at least one body region 80, the at least one source region 81, and the single high concentration region 70.

In this embodiment, the plurality of insulating films 86 cross the single high concentration region 70 and respectively extend across peripheral edge portions of the two adjacent body regions 80. Specifically, the plurality of insulating films 86 extend across the peripheral edge portion of the source region 81 of the body region 80 on one side and the peripheral edge portion of the source region 81 of the body region 80 on the other side, and respectively cover the two source regions 81, the single high concentration region 70, and the two channel regions 83. The plurality of insulating films 86 expose the plurality of source regions 81 and the plurality of contact regions 82.

The plurality of planar electrodes 87 are respectively arranged in a film shape on the plurality of insulating films 86. The plurality of planar electrodes 87 may contain either or both of a conductive polysilicon of the p-type and a conductive polysilicon of the n-type.

The plurality of planar electrodes 87 are aligned at intervals in the first direction X and are respectively formed in a band shape extending in the second direction Y along the body regions 80. That is, the plurality of planar electrodes 87 are aligned in a stripe shape extending in the second direction Y. An extension direction of the plurality of planar electrodes 87 coincides with the off direction of the SiC monocrystal. In this embodiment, the plurality of planar electrodes 87 are formed at intervals inward from both ends of the corresponding insulating films 86 with respect to the first direction X and expose both end portions of the corresponding insulating films 86.

The plurality of planar electrodes 87 respectively oppose the at least one channel region 83 (the peripheral edge portion of the body region 80) with the corresponding insulating films 86 interposed therebetween. The plurality of planar electrodes 87 respectively cover the peripheral edge portion of the at least one body region 80, the at least one source region 81, and the single high concentration region 70 with the corresponding insulating films 86 interposed therebetween so as to oppose the at least one channel region 83.

In this embodiment, the plurality of planar electrodes 87 cross the single high concentration region 70 and respectively extend across the peripheral edge portions of the two adjacent body regions 80. Specifically, the plurality of planar electrodes 87 respectively extend across the peripheral edge portion of the source region 81 of the body region 80 on one side and the peripheral edge portion of the source region 81 of the body region 80 on the other side, and respectively oppose the two source regions 81, the single high concentration region 70, and the two channel regions 83 with the corresponding insulating films 86 interposed therebetween.

As in the case of the semiconductor device 1A, the semiconductor device 1C includes the interlayer film 43 covering the first main surface 3. The interlayer film 43 covers the plurality of gate structures 85 in the active region 8. The semiconductor device 1C includes the plurality of source openings 44 formed in the interlayer film 43 in the active region 8.

The plurality of source openings 44 are respectively formed at intervals from the plurality of planar electrodes 87 in regions between the plurality of planar electrodes 87 and expose the first main surface 3 (the chip 2). Specifically, the plurality of source openings 44 penetrate through the insulating film 86 and the interlayer film 43 in regions between the plurality of planar electrodes 87, and respectively expose the corresponding source regions 81 and the contact regions 82.

In this embodiment, the plurality of source openings 44 are formed at intervals in the first direction X and are respectively formed in a band shape extending in the second direction Y. That is, the plurality of source openings 44 are formed in a stripe shape extending in the second direction Y. The plurality of source openings 44 have opening ends demarcated by arc-shaped corners of the interlayer film 43.

The plurality of source openings 44 may be formed in regions between the two adjacent gate structures 85 in the first direction X. In this case, the plurality of source openings 44 may be formed at intervals in a single line in the second direction Y. Further, in this case, each source opening 44 may be formed in a rectangular shape (square shape), a rectangular shape extending in the first direction X, a rectangular shape extending in the second direction Y, a hexagonal shape, a circular shape, etc., in plan view.

As in the case of the semiconductor device 1A, the semiconductor device 1C includes the source electrode 45. As in the case of the semiconductor device 1A, the source electrode 45 is arranged in the active region 8 and has the first pad portion 45a, the second pad portion 45b, and the third pad portion 45c. The source electrode 45 enters into the plurality of source openings 44 from above the interlayer film 43 and is electrically connected to the plurality of source regions 81 and the plurality of contact regions 82 in the plurality of source openings 44.

As in the case of the semiconductor device 1A, the source electrode 45 has a laminated structure including the lower electrode film 46 and the main electrode film 47 laminated in that order from the chip 2 side. In this embodiment, the lower electrode film 46 has a laminated structure including the first electrode film 48 and the second electrode film 49.

The first electrode film 48 collectively covers, in a film shape, a region of the interlayer film 43 in which the plurality of source openings 44 are formed, and enters into the plurality of source openings 44 from above the interlayer film 43. The first electrode film 48 has a portion covering the insulating main surface of the interlayer film 43 in a film shape, a portion covering wall surfaces of the plurality of source openings 44 in film shapes, and a portion covering the first main surface 3 inside the plurality of source openings 44 in film shapes. The first electrode film 48 covers the first main surface 3 in the source openings 44 in a film shape and is mechanically and electrically connected to the plurality of source regions 81 and the plurality of contact regions 82.

The second electrode film 49 directly covers the first electrode film 48. The second electrode film 49 collectively covers, in a film shape, a region in which the plurality of source openings 44 are formed in the interlayer film 43 with the first electrode film 48 interposed therebetween, and enters into the plurality of source openings 44 from above the interlayer film 43.

The second electrode film 49 has a portion covering the interlayer film 43 in a film shape with the first electrode film 48 interposed therebetween, a portion covering the wall surfaces of the plurality of source openings 44 in a film shape with the first electrode film 48 interposed therebetween, and a portion covering the first main surface 3 in a film shape with the first electrode film 48 interposed therebetween in the plurality of source openings 44. The second electrode film 49 covers the first main surface 3 in a film shape with the first electrode film 48 interposed therebetween in the source openings 44 and is electrically connected to the plurality of source regions 81 and the plurality of contact regions 82 via the first electrode film 48.

The main electrode film 47 directly covers the lower electrode film 46 (the second electrode film 49). The main electrode film 47 backfills the plurality of source openings 44 and collectively covers, in a film shape, the region of the interlayer film 43 in which the plurality of source openings 44 are formed.

The main electrode film 47 has a portion covering the interlayer film 43 with the lower electrode film 46 interposed therebetween, a portion covering the wall surfaces of the plurality of source openings 44 with the lower electrode film 46 interposed therebetween, and a portion covering the first main surface 3 with the lower electrode film 46 interposed therebetween. The main electrode film 47 is electrically connected to the plurality of source regions 81 and the plurality of contact regions 82 via the lower electrode film 46 in the plurality of source openings 44.

As in the case of the semiconductor device 1A, the semiconductor device 1C includes a gate electrode 51 arranged on the first main surface 3. As with the source electrode 45, the gate electrode 51 includes the lower electrode film 46 and the main electrode film 47 laminated in that order from the chip 2 side.

The gate finger electrode 52 is led out from the gate electrode 51 onto a portion of the interlayer film 43 covering the gate structure 85. The gate finger electrode 52 is routed on the gate structure 85 as a band. The gate finger electrode 52 has a portion extending in a band shape in the first direction X and a portion extending in a band shape in the second direction Y in plan view. In this embodiment, the gate finger electrode 52 is formed in a band shape with ends having four sides parallel to a peripheral edge of the first main surface 3, and surrounds the source electrode 45.

The gate finger electrode 52 enters into the plurality of gate openings 50 (not illustrated) from above the interlayer film 43, and is mechanically and electrically connected to the gate structures 85 within the plurality of gate openings 50. Thereby, the gate potential applied to the gate electrode 51 is to be applied to the plurality of gate structures 85 via the gate structure 85.

As in the case of the semiconductor device 1A, the semiconductor device 1C includes the drain electrode 53 covering the second main surface 4. The drain electrode 53 is electrically connected to the first semiconductor layer 6. The drain electrode 53 may cover an entirety of the second main surface 4 so as to be continuous to the peripheral edges of the second main surface 4 (the first to fourth side surfaces 5A to 5D). The drain electrode 53 may partially cover the second main surface 4 so as to expose a peripheral edge portion of the second main surface 4.

A breakdown voltage applicable between the source electrode 45 and the drain electrode 53 (between the first main surface 3 and the second main surface 4) may be not less than 500 V and not more than 3000 V. The breakdown voltage may have a value belonging to at least one range among not less than 500 V and not more than 750V, not less than 750 V and not more than 1000V, not less than 1000 V and not more than 1250V, not less than 1250 V and not more than 1500V, not less than 1500 V and not more than 1750V, not less than 1750 V and not more than 2000V, not less than 2000 V and not more than 2250V, not less than 2250 V and not more than 2500V, not less than 2500 V and not more than 2750V, and not less than 2750 V and not more than 3000V.

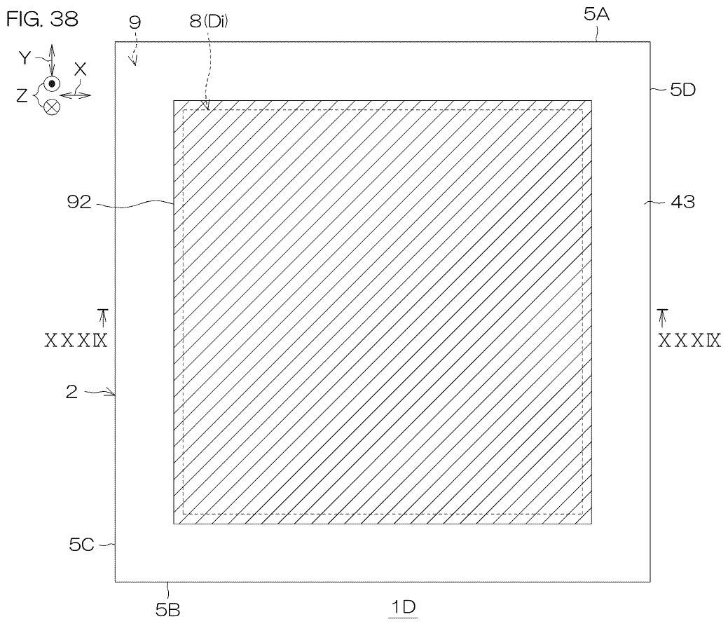

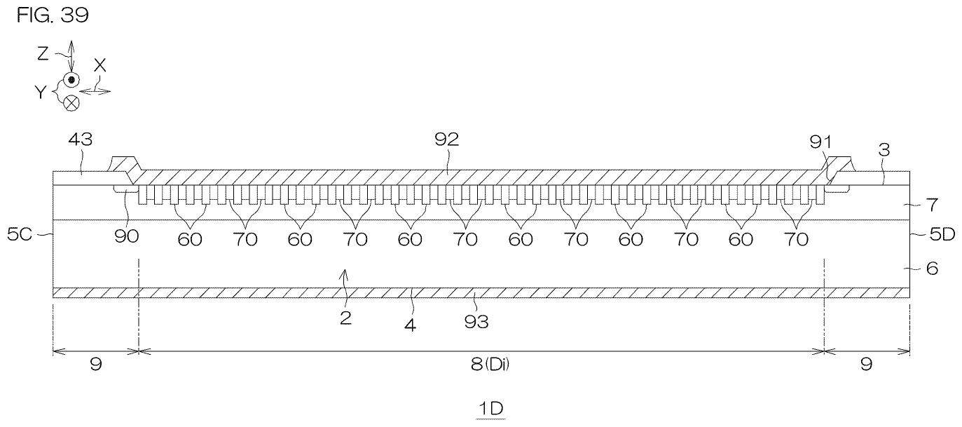

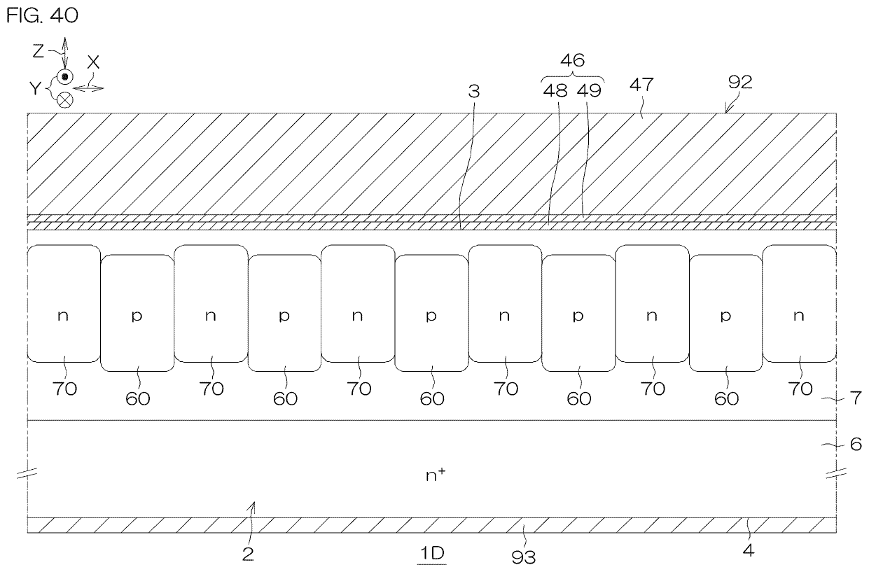

FIG. 38 is a plan view illustrating a semiconductor device 1D according to a fourth embodiment. FIG. 39 is a sectional view taken along line XXXIX-XXXIX illustrated in FIG. 38. FIG. 40 is an enlarged sectional view illustrating one main portion of the active region 8 illustrated in FIG. 39.

The semiconductor device 1D has a configuration in which the configuration of the semiconductor device 1B (the well region 60 and the high concentration region 70) is combined with a Schottky barrier diode structure Di as an example of a device structure. As in the case of the semiconductor device 1A, the semiconductor device 1D includes the chip 2, the first semiconductor layer 6, the second semiconductor layer 7, the active region 8, and the outer peripheral region 9.

The semiconductor device 1D includes a guard region 90 of the p-type formed in the surface layer portion of the first main surface 3 in the outer peripheral region 9. The guard region 90 has a p-type impurity concentration higher than the n-type impurity concentration of the second semiconductor layer 7.

The guard region 90 is formed in the surface layer portion of the second semiconductor layer 7. The guard region 90 extends in a layer shape along the first main surface 3. The guard region 90 is formed at an interval toward the inner side of the first main surface 3 (the active region 8 side) from a peripheral edge (the first to fourth side surfaces 5A to 5D) of the first main surface 3. The guard region 90 extends in a band shape along the peripheral edge of the first main surface 3 (the peripheral edge of the active region 8) in plan view.

In this embodiment, the guard region 90 is formed in a polygonal annular shape (a quadrilateral annular shape in this embodiment) having four sides parallel to the peripheral edge of the chip 2 and surrounds the inner portion (the active region 8) of the first main surface 3 in plan view. The guard region 90 has an inner edge portion that demarcates the active region 8 and an outer edge portion that defines the outer peripheral region 9. The guard region 90 may have an edge portion connecting, in an arcuate shape (preferably, a quarter arcuate shape), a portion extending in the first direction X and a portion extending in the second direction Y.

The semiconductor device 1D includes the plurality of well regions 60 of the p-type formed in the surface layer portion of the first main surface 3 in the active region 8. For the well region 60, the description of the well region 60 according to the semiconductor device 1B shall apply. The semiconductor device 1D includes the plurality of high concentration regions 70 of the p-type formed in the surface layer portion of the first main surface 3 in the active region 8. For the high concentration region 70, the description of the high concentration region 70 according to the semiconductor device 1B shall apply.

The semiconductor device 1D includes the interlayer film 43 with an insulating property that selectively covers the first main surface 3 in the active region 8 and the outer peripheral region 9. The interlayer film 43 may have a single layer structure or a laminated structure including at least one among a silicon oxide film, a silicon nitride film, and a silicon oxynitride film. In this embodiment, the interlayer film 43 has a single layer structure including a silicon oxide film.

The interlayer film 43 covers the guard region 90 in the outer peripheral region 9. In this embodiment, the interlayer film 43 is continuous to the peripheral edge (the first to fourth side surfaces 5A to 5D) of the first main surface 3. As a matter of course, the interlayer film 43 may be formed at an interval inward from the peripheral edge of the first main surface 3, and may expose the second semiconductor layer 7 from the peripheral edge portion of the first main surface 3.

The interlayer film 43 has an opening 91 that exposes the first main surface 3 in the active region 8. In this embodiment, the opening 91 has an open wall surface positioned on the guard region 90, and exposes the inner edge portion of the guard region 90.

The semiconductor device 1D includes an anode electrode 92 covering the first main surface 3 in the active region 8. The anode electrode 92 may be referred to as a “first main surface electrode,” a “first terminal (electrode),” a “first pad (electrode),” etc. The anode electrode 92 is arranged at an interval inward from the peripheral edge of the chip 2. The anode electrode 92 is formed in a polygonal shape (a quadrangular shape in this embodiment) along the peripheral edge of the chip 2 in plan view.

The anode electrode 92 enters into the opening 91 from above the interlayer film 43, and is electrically connected to the first main surface 3 and the guard region 90 within the opening 91. The anode electrode 92 forms a Schottky junction with the first main surface 3. Thereby, the Schottky barrier diode structure Di is formed.

In this embodiment, both the well region 60 and the high concentration region 70 are formed at an interval toward the bottom portion side of the second semiconductor layer 7 from the first main surface 3. Accordingly, an anode region forms a Schottky junction with the second semiconductor layer 7. In a case where the well region 60 is exposed from the first main surface 3, the anode electrode 92 is mechanically and electrically connected to the well region 60. In a case where the high concentration region 70 is exposed from the first main surface 3, the anode electrode 92 forms a Schottky junction with the high concentration region 70.

The semiconductor device 1D includes a cathode electrode 93 covering the second main surface 4. The cathode electrode 93 may be referred to as a “second main surface electrode,” a “second terminal (electrode),” a “second pad (electrode),” etc. The cathode electrode 93 is electrically connected to the first semiconductor layer 6. The cathode electrode 93 forms an ohmic contact with the first semiconductor layer 6.

The cathode electrode 93 may cover an entirety of the second main surface 4 so as to be continuous to the peripheral edges of the second main surface 4 (the first to fourth side surfaces 5A to 5D). The cathode electrode 93 may partially cover the second main surface 4 so as to expose the peripheral edge portion of the second main surface 4.

A breakdown voltage applicable between the anode electrode 92 and the cathode electrode 93 (between the first main surface 3 and the second main surface 4) may be not less than 500 V and not more than 3000 V. The breakdown voltage may have a value belonging to at least one range among not less than 500 V and not more than 750 V, not less than 750 V and not more than 1000 V, not less than 1000 V and not more than 1250 V, not less than 1250 V and not more than 1500 V, not less than 1500 V and not more than 1750 V, not less than 1750 V and not more than 2000 V, not less than 2000 V and not more than 2250 V, not less than 2250 V and not more than 2500 V, and not less than 2500 V and not more than 3000 V.

Each of the embodiments described above (including modification examples) can be implemented in yet other embodiments. For example, the above-described first to fourth embodiments can be combined as appropriate with each other. Also, the semiconductor devices 1A to 1D that include at least two configurations among the first to fourth embodiments at the same time may be adopted.

In each embodiment described above, the chip 2 including the SiC monocrystal is adopted. However, the chip 2 may include a silicon monocrystal instead. The first semiconductor layer 6 may include a silicon monocrystal. The second semiconductor layer 7 may include a silicon monocrystal.

In each of the embodiments described above, a structure in which the conductivity type of a semiconductor region of the “n-type” is inverted to the “p-type” and the conductivity type of a semiconductor region of the “p-type” is inverted to the “n-type” may be adopted. The specific configuration in this case is obtained by replacing “n-type” with “p-type” and replacing “p-type” with “n-type” at the same time in the above description and attached drawings.

In each of the embodiments described above, a collector region of the p-type may be formed in the surface layer portion of the second main surface 4 of the chip 2. In this case, the transistor structure Tr includes an IGBT (insulated gate bipolar transistor) structure in place of the MISFET structure. The specific configuration in this case is obtained by replacing the “source” of the MISFET structure with an “emitter” of the IGBT structure and replacing the “drain” of the MISFET structure with a “collector” of the IGBT structure in the above description. In this case, the chip 2 may have a single layer structure consisting of a semiconductor substrate of the n-type.

Hereinafter, examples of features extracted from the present description and the drawings shall be indicated below. Hereinafter, the alphanumeric characters, etc., in parentheses represent the corresponding constituent elements, etc., in the embodiment described above, but are not intended to limit the scope of each Clause to the embodiment. The “semiconductor device” in the following Clauses may be replaced with an “SiC semiconductor device,” a “wide bandgap semiconductor device,” a “semiconductor switching device,” a “MISFET device,” an “IGBT device,” a “semiconductor rectifier,” etc., as needed.
[A1] A semiconductor device (1A) comprising: a semiconductor layer (2, 7) of a first conductivity type (an n-type) having a main surface (3); a body region (10) of a second conductivity type (a p-type) formed in a surface layer portion of the main surface (3); a gate structure (15) of a trench type formed in the main surface (3) so as to penetrate through the body region (10); and a well region (25) of the second conductivity type (the p-type) formed in a region below the gate structure (15) in the semiconductor layer (2, 7), the well region (25) having a bulging region (26, 26A, 26B, 28, 29) protruding in a horizontal direction along the main surface (3) with respect to a side wall of the gate structure (15).
[A2] The semiconductor device (1A) according to A1, wherein the semiconductor layer (2, 7) contains SiC.
[A3] The semiconductor device (1A) according to A1 or A2, wherein the bulging region (26, 26A, 26B, 28, 29) has an impurity concentration higher than an impurity concentration of the body region (10).
[A4] The semiconductor device (1A) according to any one of A1 to A3, wherein the bulging region (26, 26A, 26B, 28, 29) is connected to a bottom wall of the gate structure (15).
[A5] The semiconductor device (1A) according to any one of A1 to A4, wherein the bulging region (26, 26A, 26B, 28, 29) protrudes in an arc shape.
[A6] The semiconductor device (1A) according to any one of A1 to A5, wherein the well region (25) has a constricted region (27) recessed in a horizontal direction along the main surface (3) with respect to the bulging region (26, 26A, 26B, 28, 29) below the bulging region (26, 26A, 26B, 28, 29).
[A7] The semiconductor device (1A) according to A6, wherein the constricted region (27) has a portion positioned further inward than a side wall of the gate structure (15).
[A8] The semiconductor device (1A) according to any one of A1 to A7, wherein the bulging region (26, 26A, 26B, 28, 29) protrudes in a horizontal direction along the main surface (3) with respect to both side walls of the gate structure (15).
[A9] The semiconductor device (1A) according to any one of A1 to A8, wherein the well region (25) includes the bulging regions (26, 26A, 26B, 28, 29) formed at different depth positions.
[A10] The semiconductor device (1A) according to any one of A1 to A9, wherein the well region (25) includes a first well region (28) of the second conductivity type (the p-type) formed below the gate structure (15) and a second well region (29) of the second conductivity type (the p-type) formed below the first well region (28), and the bulging region (26, 26A, 26B, 28, 29) is formed by the first well region (28).
[A11] The semiconductor device (1A) according to A10, wherein the second well region (29) has an impurity concentration lower than an impurity concentration of the first well region (28).
[A12] The semiconductor device (1A) according to A10 or A11, wherein the second well region (29) has a thickness greater than a thickness of the first well region (28).
[A13] The semiconductor device (1A) according to any one of A1 to A12, wherein the gate structure (15) includes a trench (16) formed in the main surface (3), an insulating film (17) covering a wall surface of the trench (16), and an embedded electrode (18) embedded in the trench (16) via the insulating film (17).
[A14] The semiconductor device (1A) according to A13, wherein the embedded electrode (18) is embedded at an interval toward a bottom wall side of the trench (16) from a height position of the main surface (3).
[A15] The semiconductor device (1A) according to A14, wherein the gate structure (15) includes an embedded insulator (19) embedded in the trench (16) at an interval toward a bottom wall side of the trench (16) from a height position of the main surface (3) so as to cover the embedded electrode (18).
[A16] The semiconductor device (1A) according to any one of A1 to A15, further comprising: a contact region (37) of the second conductivity type (the p-type) extending along a side wall of the gate structure (15) and electrically connecting the bulging region (26, 26A, 26B, 28, 29) to the body region (10).
[A17] The semiconductor device (1A) according to A16, wherein the contact region (37) has an impurity concentration higher than an impurity concentration of the body region (10).
[A18] The semiconductor device (1A) according to any one of A1 to A17, further comprising: a source region (35) of the first conductivity type (the n-type) formed in a surface layer portion of the body region (10).
[A19] The semiconductor device (1A) according to any one of A1 to A18, further comprising: a high concentration region (30) of the first conductivity type (the n-type) formed in the semiconductor layer (2, 7) in a thickness range between a bottom portion of the body region (10) and a bottom wall of the gate structure (15) and having an impurity concentration higher than an impurity concentration of the semiconductor layer (2, 7).
[A20] The semiconductor device (1A) according to any one of A1 to A19, further comprising: a main surface electrode (45) electrically connected to the body region (10) on the main surface (3) and electrically separated from the gate structure (15).
[B1] A semiconductor device (1A) comprising: a semiconductor layer (2, 7) of a first conductivity type (an n-type) having a main surface (3); a body region (10) of a second conductivity type (a p-type) formed in a surface layer portion of the main surface (3); a gate structure (15) of a trench type formed in the main surface (3) so as to penetrate through the body region (10); and a body high concentration region (36) formed at a bottom portion of the body region (10) and having an impurity concentration higher than an impurity concentration of the body region (10).
[B2] The semiconductor device (1A) according to B1, wherein the semiconductor layer (2, 7) contains SiC.
[B3] The semiconductor device (1A) according to B1 or B2, wherein the body high concentration region (36) is partially formed at a bottom portion of the body region (10).
[B4] The semiconductor device (1A) according to B3, wherein the body high concentration region (36) is formed at an interval from the gate structure (15) and opposes the gate structure (15) with a portion of the body region (10) interposed therebetween.
[B5] The semiconductor device (1A) according to any one of B1 to B4, wherein the body high concentration region (36) extends along an extension direction of the gate structure (15).
[B6] The semiconductor device (1A) according to any one of B1 to B5, wherein the body high concentration regions (36) are formed at an interval along the gate structure (15).
[B7] The semiconductor device (1A) according to any one of B1 to B6, wherein the gate structure (15) includes a trench (16) formed in the main surface (3), an insulating film (17) covering a wall surface of the trench (16), and an embedded electrode (18) embedded in the trench (16) via the insulating film (17).
[B8] The semiconductor device (1A) according to B7, wherein the embedded electrode (18) is embedded at an interval toward a bottom wall side of the trench (16) from a height position of the main surface (3).
[B9] The semiconductor device (1A) according to B8, wherein the gate structure (15) includes an embedded insulator (19) embedded in the trench (16) at an interval toward a bottom wall side of the trench (16) from a height position of the main surface (3) so as to cover the embedded electrode (18).
[B10] The semiconductor device (1A) according to any one of B1 to B9, further comprising: a source region (35) of the first conductivity type (the n-type) formed in a surface layer portion of the body region (10); and wherein the body high concentration region (36) is formed in a thickness range between a bottom portion of the body region (10) and a bottom portion of the source region (35).
[B11] The semiconductor device (1A) according to any one of B1 to B10, further comprising: a contact region (37) of the second conductivity type (the p-type) formed along the gate structure (15) in a surface layer portion of the body region (10) and having an impurity concentration higher than an impurity concentration of the body region (10).
[B12] The semiconductor device (1A) according to B11, wherein the contact region (37) is electrically connected to the body high concentration region (36) in the body region (10).
[B13] The semiconductor device (1A) according to B11 or B12, wherein the contact region (37) has a portion connected to the body high concentration region (36) in the body region (10).
[B14] The semiconductor device (1A) according to any one of B1 to B10, further comprising: a well region (25) of the second conductivity type (the p-type) formed in a region below the gate structure (15) in the semiconductor layer (2, 7) at an interval from a bottom portion of the body high concentration region (36).
[B15] The semiconductor device (1A) according to B14, wherein the well region (25) is formed at an interval from a bottom portion of the body region (10).
[B16] The semiconductor device (1A) according to B14 or B15, wherein the well region (25) includes a first well region (28) of the second conductivity type (the p-type) formed below the gate structure (15) and a second well region (29) of the second conductivity type (the p-type) having an impurity concentration lower than an impurity concentration of the first well region (28) and formed below the first well region (28).
[B17] The semiconductor device (1A) according to B16, wherein the second well region (29) has a thickness greater than a thickness of the first well region (28). [B18] The semiconductor device (1A) according to any one of B14 to B17, further comprising: a contact region (37) of the second conductivity type (the p-type) extending along a side wall of the gate structure (15) and electrically connecting the well region (25) to the body region (10).
[B19] The semiconductor device (1A) according to any one of B1 to B18, further comprising: a high concentration region (30) of the first conductivity type (the n-type) formed in the semiconductor layer (2, 7) in a thickness range between a bottom portion of the body region (10) and a bottom wall of the gate structure (15) and having an impurity concentration higher than an impurity concentration of the semiconductor layer (2, 7).
[B20] The semiconductor device (1A) according to any one of B1 to B19, further comprising: a main surface electrode (45) electrically connected to the body region (10) on the main surface (3) and electrically separated from the gate structure (15).
[C1] A semiconductor device (1A) comprising: a semiconductor layer (2, 7) of a first conductivity type (an n-type) including an SiC monocrystal and having a main surface (3); a gate structure (15) of a trench type formed in the main surface (3); and a well region (25, 29) of a second conductivity type (a p-type) formed in a region below the gate structure (15) in the semiconductor layer (2, 7) and extending along an axis channel of the SiC monocrystal.
[C2] The semiconductor device (1A) according to C1, wherein the well region (25, 29) has an impurity concentration higher than an impurity concentration of the semiconductor layer (2, 7), and a conductivity type of the semiconductor layer (2, 7) is replaced from the first conductivity type (the n-type) to the second conductivity type (the p-type).
[C3] The semiconductor device (1A) according to C1 or C2, wherein the well region (25, 29) has a concentration gradient monotonically decreasing in a depth direction.
[C4] The semiconductor device (1A) according to any one of C1 to C3, wherein, on a basis of a bottom wall of the gate structure (15), the well region (25, 29) has a depth of not less than 0.5 μm and not more than 5 μm.
[C5] The semiconductor device (1A) according to any one of C1 to C4, wherein, on a basis of a bottom wall of the gate structure (15), the well region (25, 29) has a depth smaller than a depth of the gate structure (15) on a basis of the main surface (3).
[C6] The semiconductor device (1A) according to any one of C1 to C5, wherein the well region (25, 29) is formed in a shape tapering toward a bottom portion in sectional view.
[C7] The semiconductor device (1A) according to any one of C1 to C6, further comprising: a high concentration region (30) of the first conductivity type (the n-type) formed in the semiconductor layer (2, 7) in a region lateral to the well region (25, 29) and having an impurity concentration higher than an impurity concentration of the semiconductor layer (2, 7).
[C8] The semiconductor device (1A) according to C7, wherein the high concentration region (30) extends along the axis channel of the SiC monocrystal.
[C9] The semiconductor device (1A) according to C7 or C8, wherein the high concentration region (30) has a bottom portion positioned further to the main surface (3) side than a bottom portion of the well region (25, 29).
[C10] The semiconductor device (1A) according to any one of C7 to C9, wherein the high concentration region (30) has a concentration gradient decreasing in a thickness direction.
[C11] The semiconductor device (1A) according to any one of C7 to C10, wherein the high concentration region (30) has a first region (31) positioned above a depth position of a bottom wall of the gate structure (15), and a second region (32) positioned below a depth position of the bottom wall of the gate structure (15).
[C12] The semiconductor device (1A) according to C11, wherein the second region (32) has a concentration gradient monotonically decreasing in a thickness direction.
[C13] The semiconductor device (1A) according to C11 or C12, wherein, on a basis of a depth position of a bottom wall of the gate structure (15), the second region (32) has a depth of not less than 0.5 μm and not more than 5 μm.
[C14] The semiconductor device (1A) according to any one of C1 to C13, further comprising: a well high concentration region (25, 28) of the second conductivity type (the p-type) formed below the gate structure (15) in the semiconductor layer (2, 7); and wherein the well region (25, 29) has an impurity concentration lower than an impurity concentration of the well high concentration region (25, 28), and is formed below the well high concentration region (25, 28).
[C15] The semiconductor device (1A) according to C14, wherein the well region (25, 29) has a thickness greater than a thickness of the well high concentration region (25, 28).
[C16] The semiconductor device (1A) according to C14 or C15, wherein the well high concentration region (25, 28) has a concentration gradient increasing and decreasing downward from a bottom wall side of the gate structure (15).
[C17] The semiconductor device (1A) according to any one of C1 to C16, further comprising: a body region (10) of the second conductivity type (the p-type) formed in a surface layer portion of the main surface (3); and wherein the gate structure (15) penetrates through the body region (10).
[C18] The semiconductor device (1A) according to C17, further comprising: a contact region (37) of the second conductivity type (the p-type) extending along a side wall of the gate structure (15) and electrically connecting the well region (25, 29) to the body region (10).
[C19] The semiconductor device (1A) according to C17 or C18, further comprising: a source region (35) of a first conductivity type (the n-type) formed in a surface layer portion of the body region (10).
[C20] The semiconductor device (1A) according to any one of C1 to C19, further comprising: a main surface electrode (45) arranged on the main surface (3).
[D1] A semiconductor device (1A to 1D) comprising: a semiconductor layer (2, 7) of an n-type; a well region (25, 29, 60) of a p-type formed in the semiconductor layer (2, 7) to be of a higher concentration than the semiconductor layer (2, 7); and a high concentration region (30, 32, 70) of the n-type formed in the semiconductor layer (2, 7) to be of a higher concentration than the semiconductor layer (2, 7) and forming a pn-junction portion with the well region (25, 29, 60).
[D2] The semiconductor device (1A to 1D) according to D1, wherein the semiconductor layer (2, 7) contains SiC.
[D3] The semiconductor device (1A to 1D) according to D1 or D2, wherein the well region (25, 29, 60) has an impurity concentration separated from an impurity concentration of the high concentration region (30, 32, 70), and the high concentration region (30, 32, 70) has an impurity concentration separated from an impurity concentration of the well region (25, 29, 60).
[D4] The semiconductor device (1A to 1D) according to any one of D1 to D3, wherein the semiconductor layer (2, 7) is adjusted in concentration by a first element consisting of a pentavalent element, the well region (25, 29, 60) is adjusted in concentration by a second element consisting of a trivalent element in addition to the first element, and the high concentration region (30, 32, 70) is adjusted in concentration by a third element consisting of a pentavalent element in addition to the first element.
[D5] The semiconductor device (1A to 1D) according to D4, wherein a concentration of the third element in the well region (25, 29, 60) is less than a concentration of the third element in the high concentration region (30, 32, 70).
[D6] The semiconductor device (1A to 1D) according to D4 or D5, wherein an inner portion of the well region (25, 29, 60) does not contain the third element.
[D7] The semiconductor device (1A to 1D) according to any one of D4 to D6, wherein a concentration of the second element in the high concentration region (30, 32, 70) is less than a concentration of the second element in the well region (25, 29, 60).
[D8] The semiconductor device (1A to 1D) according to any one of D4 to D7, wherein an inner portion of the high concentration region (30, 32, 70) does not contain the second element.
[D9] The semiconductor device (1A to 1D) according to any one of D4 to D8, wherein the first element includes at least one type among nitrogen, phosphorus, and arsenic, the second element includes at least one type among boron and aluminum, and the third element includes at least one type among nitrogen, phosphorus, and arsenic.
[D10] The semiconductor device (1A to 1D) according to any one of D4 to D9, wherein the semiconductor layer (2, 7) is adjusted in concentration by the first element.
[D11] The semiconductor device (1A to 1D) according to any one of D4 to D10, wherein the third element is different from the first element.
[D12] The semiconductor device (1A to 1D) according to any one of D1 to D11, wherein the high concentration region (30, 32, 70) has a bottom portion positioned higher than a depth position of a bottom portion of the well region (25, 29, 60).
[D13] The semiconductor device (1A to 1D) according to any one of D1 to D12, wherein the high concentration region (30, 32, 70) forms a super junction structure with the well region (25, 29, 60).
[D14] The semiconductor device (1A to 1D) according to any one of D1 to D13, further comprising: a gate structure (15) of a trench type formed in the semiconductor layer (2, 7); and wherein the well region (25, 29, 60) is formed below the gate structure (15), and the high concentration region (30, 32, 70) is formed lower than a depth position of a bottom wall of the gate structure (15).
[D15] The semiconductor device (1A to 1D) according to D14, further comprising: a well high concentration region (28) of the p-type formed below the gate structure (15); and wherein the well region (25, 29, 60) is formed to be of a lower concentration than the well high concentration region (28) in a region below the well high concentration region (28).
[D16] The semiconductor device (1A to 1D) according to D14 or D15, further comprising: an upper high concentration region (31) of the n-type formed above a depth position of a bottom wall of the gate structure (15); and wherein the high concentration region (30, 32, 70) is formed to be of a lower concentration than the upper high concentration region (31) in a region below the upper high concentration region (31).
[D17] The semiconductor device (1A to 1D) according to any one of D14 to D16, further comprising: a body region (10) of the p-type formed in the semiconductor layer (2, 7); and wherein the gate structure (15) penetrates through the body region (10).
[D18] The semiconductor device (1A to 1D) according to D17, further comprising: a contact region (37) of the p-type extending along a side wall of the gate structure (15).
[D19] The semiconductor device (1A to 1D) according to D17 or D18, further comprising: a source region (35) of the n-type formed in a surface layer portion of the body region (10).
[D20] The semiconductor device (1A to 1D) according to any one of D1 to D19, further comprising: a main surface electrode (45) arranged on the semiconductor layer (2, 7).

The features according to [A1] to [A20], the features according to [B1] to [B20], the features according to [C1] to [C20], and the features according to [D1] to [D20] can be combined as appropriate with each other.

While a specific embodiment of the present invention has been described in detail above, this is merely a specific example used to clarify the technical contents. The various technical ideas extracted from this description can be combined as appropriate with each other without being limited by the order of description, the order of configuration examples, the order of modification examples, etc., in this description.

What is claimed is:

1. A semiconductor device comprising:
a semiconductor layer of a first conductivity type including an SiC monocrystal and having a main surface;
a gate structure of a trench type formed in the main surface; and
a well region of a second conductivity type formed in a region below the gate structure in the semiconductor layer and extending along an axis channel of the SiC monocrystal.

2. The semiconductor device according to claim 1,
wherein the well region has an impurity concentration higher than an impurity concentration of the semiconductor layer, and
a conductivity type of the semiconductor layer is replaced from the first conductivity type to the second conductivity type.

3. The semiconductor device according to claim 1,
wherein the well region has a concentration gradient decreasing in a thickness direction.

4. The semiconductor device according to claim 1,
wherein, on a basis of a bottom wall of the gate structure, the well region has a depth of not less than 0.5 μm and not more than 5 μm.

5. The semiconductor device according to claim 1,
wherein, on a basis of a bottom wall of the gate structure, the well region has a depth smaller than a depth of the gate structure on a basis of the main surface.

6. The semiconductor device according to claim 1,
wherein the well region is formed in a shape tapering toward a bottom portion in sectional view.

7. The semiconductor device according to claim 1, further comprising:
a high concentration region of the first conductivity type formed in the semiconductor layer in a region lateral to the well region and having an impurity concentration higher than an impurity concentration of the semiconductor layer.

8. The semiconductor device according to claim 7,
wherein the high concentration region extends along the axis channel of the SiC monocrystal.

9. The semiconductor device according to claim 7,
wherein the high concentration region has a bottom portion positioned further to the main surface side than a bottom portion of the well region.

10. The semiconductor device according to claim 7,
wherein the high concentration region has a concentration gradient decreasing in a thickness direction.

11. The semiconductor device according to claim 7,
wherein the high concentration region has a first region positioned above a depth position of a bottom wall of the gate structure, and a second region positioned below a depth position of the bottom wall of the gate structure.

12. The semiconductor device according to claim 11,
wherein the second region has a concentration gradient monotonically decreasing in a thickness direction.

13. The semiconductor device according to claim 11,
wherein, on a basis of a depth position of a bottom wall of the gate structure, the second region has a depth of not less than 0.5 μm and not more than 5 μm.

14. The semiconductor device according to claim 1, further comprising:
a well high concentration region of the second conductivity type formed below the gate structure in the semiconductor layer; and
wherein the well region has an impurity concentration lower than an impurity concentration of the well high concentration region, and is formed below the well high concentration region.

15. The semiconductor device according to claim 14,
wherein the well region has a thickness greater than a thickness of the well high concentration region.

16. The semiconductor device according to claim 14,
wherein the well high concentration region has a concentration gradient increasing and decreasing downward from a bottom wall side of the gate structure.

17. The semiconductor device according to claim 1, further comprising:
a body region of the second conductivity type formed in a surface layer portion of the main surface; and
wherein the gate structure penetrates through the body region.

18. The semiconductor device according to claim 17, further comprising:
a contact region of the second conductivity type extending along a side wall of the gate structure and electrically connecting the well region to the body region.

19. The semiconductor device according to claim 17, further comprising:
a source region of the first conductivity type formed in a surface layer portion of the body region.

20. The semiconductor device according to claim 1, further comprising:
a main surface electrode arranged on the main surface.
